(19) United States
(12) Patent Application Publication
(10) Pub. No.: US 2026/0362908 A1
(43) Pub. Date: Nov. 12, 2026

(54) DISPLAY DEVICE

(71) Applicant: SEMICONDUCTOR ENERGY LABORATORY CO., LTD., Atsugi-shi (JP)

(72) Inventors: Yasutaka NAKAZAWA, Tochigi (JP); Rai SATO, Tochigi (JP); Satoru IDOJIRI, Tochigi (JP); Kenichi OKAZAKI, Kanagawa (JP)

(21) Appl. No.: 19/667,094

(22) Filed: May 4, 2026

(30) Foreign Application Priority Data
May 9, 2025 (JP) 2025-078913
Feb. 11, 2026 (JP) 2026-020545

(51) Int. Cl. H10K 59/122

(52) U.S. Cl. CPC H10K 59/122

(57) ABSTRACT

Provided is a display device that can easily achieve higher resolution, a display device having high display quality and high resolution, a display device with high contrast, or a highly reliable display device. The display device includes a pixel electrode, a first insulating layer including a region covering an end portion of the pixel electrode, a partition over the first insulating layer, an organic compound layer including a region over the pixel electrode, and an upper electrode including a region over the organic compound layer. The organic compound layer includes a light-emitting compound. The partition has an inverse tapered shape in a cross-sectional view. The partition includes a second insulating layer in contact with the first insulating layer and a first conductive layer over the second insulating layer. The upper electrode includes a region in contact with a side surface of the first conductive layer and a region in contact with a top surface of the organic compound layer.

### BACKGROUND OF THE INVENTION

### 1. Field of the Invention

One embodiment of the present invention relates to a display device. One embodiment of the present invention relates to a method for manufacturing a display device.

One embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device generally means a device that can function by utilizing semiconductor characteristics.

### 2. Description of the Related Art

In recent years, higher-resolution display panels have been required. Examples of devices that require high-resolution display panels include a smartphone, a tablet terminal, and a notebook computer. Furthermore, higher resolution has been required for a stationary display device such as a television device or a monitor device along with an increase in definition. An example of a device absolutely required to have the highest resolution display panel is a device for virtual reality (VR) or augmented reality (AR).

Typical examples of the display device that can be used for a display panel include a liquid crystal display device, a light-emitting apparatus including a light-emitting element such as an organic electroluminescent (EL) element or a light-emitting diode (LED), and electronic paper performing display by an electrophoretic method or the like.

An organic EL element generally has a structure in which, for example, a layer containing a light-emitting organic compound is provided between a pair of electrodes. By voltage application to this element, light emission can be obtained from the light-emitting organic compound. A display device using such an organic EL element does not need a backlight that is necessary for a liquid crystal display device or the like; thus, a thin, lightweight, high-contrast, and low-power-consumption display device can be achieved. Patent Document 1, for example, discloses an example of a display device using an organic EL element.

A method using a metal mask is known as a method for separately forming organic EL elements but has problems with an aperture ratio, a resolution, and an increase in the substrate area, and the like. Patent Document 2 discloses a method for separately forming organic EL elements by a photolithography method without using a metal mask.

### REFERENCES

[Patent Document 1] Japanese Published Patent Application No. 2002-324673
[Patent Document 2] PCT International Publication No. 2023/285907

### SUMMARY OF THE INVENTION

An object of one embodiment of the present invention is to provide a display device that can easily achieve higher resolution and a method for manufacturing the display device. An object of one embodiment of the present invention is to provide a display device having both high display quality and high resolution. An object of one embodiment of the present invention is to provide a display device with high contrast. An object of one embodiment of the present invention is to provide a highly reliable display device.

An object of one embodiment of the present invention is to provide a display device having a novel structure or a method for manufacturing the display device. An object of one embodiment of the present invention is to provide a method for manufacturing the above display device with high yield. An object of one embodiment of the present invention is to at least alleviate at least one of problems in the conventional art.

Note that the description of these objects does not preclude the existence of other objects. One embodiment of the present invention does not need to achieve all of these objects. Objects other than the above objects can be derived by those skilled in the art from the description of the specification and like.

One embodiment of the present invention is a display device including a pixel electrode, a first insulating layer including a region covering an end portion of the pixel electrode, a partition over the first insulating layer, an organic compound layer including a region over the pixel electrode, and an upper electrode including a region over the organic compound layer. The organic compound layer includes a light-emitting compound. The partition has an inverse tapered shape in a cross-sectional view. The partition includes a second insulating layer in contact with the first insulating layer and a first conductive layer over the second insulating layer. The upper electrode includes a region in contact with a side surface of the first conductive layer and a region in contact with a top surface of the organic compound layer.

In the above structure, it is preferable that the display device include a first film over the partition and the first film contain the light-emitting compound.

In the above structure, it is preferable that the first insulating layer include an inorganic insulating film and the second insulating layer contain aluminum and oxygen.

In the above structure, it is preferable that the first conductive layer contain molybdenum.

In the above structure, it is preferable that an angle between a bottom surface of the first conductive layer and the side surface of the first conductive layer be greater than or equal to 100° and less than or equal to 135°.

In the above structure, it is preferable that the organic compound layer be in contact with the second insulating layer and not be in contact with the first conductive layer.

In the above structure, it is preferable that the organic compound layer not be in contact with the partition.

In the above structure, it is preferable that the upper electrode include a region in contact with a top surface of the partition.

In the above structure, it is preferable that the upper electrode not be in contact with a top surface of the partition.

According to one embodiment of the present invention, a display device that can easily achieve higher resolution and a method for manufacturing the display device can be provided. According to one embodiment of the present invention, a display device having both high display quality and high resolution can be provided. According to one embodiment of the present invention, a display device with high contrast can be provided. According to one embodiment of the present invention, a highly reliable display device can be provided.

According to one embodiment of the present invention, a display device having a novel structure or a method for manufacturing the display device can be provided. According to one embodiment of the present invention, a method for manufacturing the above display device with high yield can be provided. According to one embodiment of the present invention, at least one of problems in the conventional art can be at least alleviated.

Note that the description of these effects does not preclude the existence of other effects. One embodiment of the present invention does not necessarily have all these effects. Effects other than these can be derived from the description of the specification, the drawings, the claims, and the like.

### BRIEF DESCRIPTION OF THE DRAWINGS

FIGS. 1A to 1C illustrate structure examples of a display device.

FIGS. 2A to 2C illustrate a structure example of a display device.

FIG. 3 illustrates a structure example of a display device.

FIGS. 4A to 4D illustrate structure examples of a display device.

FIGS. 5A and 5B illustrate structure examples of a display device.

FIGS. 6A to 6G illustrate structure examples of a display device.

FIGS. 7A to 7C illustrate structure examples of a display device.

FIGS. 8A and 8B illustrate structure examples of a display device.

FIGS. 9A to 9C illustrate structure examples of a display device.

FIGS. 10A and 10B illustrate a structure example of a display device.

FIGS. 11A to 11D illustrate an example of a method for manufacturing a display device.

FIGS. 12A to 12D illustrate an example of a method for manufacturing a display device.

FIGS. 13A to 13D illustrate an example of a method for manufacturing a display device.

FIGS. 14A and 14B illustrate an example of a method for manufacturing a display device.

FIGS. 15A to 15E illustrate examples of a method for manufacturing a display device.

FIGS. 16A and 16B illustrate structure examples of a manufacturing apparatus for a display device.

FIG. 17 illustrates a structure example of a manufacturing apparatus for a display device.

FIGS. 18A to 18C illustrate structure examples of a manufacturing apparatus for a display device.

FIGS. 19A and 19B illustrate structure examples of a manufacturing apparatus for a display device.

FIG. 20 illustrates a structure example of a display device.

FIG. 21 illustrates a structure example of a display device.

FIGS. 22A to 22D illustrate structure examples of a display device.

FIGS. 23A and 23B illustrate a structure example of a display device.

FIGS. 24A and 24B illustrate a structure example of a display device.

FIGS. 25A to 25E are circuit diagrams of pixel circuits.

FIGS. 26A and 26B are circuit diagrams of pixel circuits.

FIG. 27 illustrates a structure example of a display device.

FIG. 28 illustrates a structure example of a display device.

FIG. 29 illustrates a structure example of a display device.

FIGS. 30A to 30F illustrate structure examples of a light-emitting device.

FIGS. 31A to 31C illustrate structure examples of a light-emitting device.

FIGS. 32A to 32D illustrate structure examples of electronic devices.

FIGS. 33A to 33F illustrate structure examples of electronic devices.

FIGS. 34A to 34G illustrate structure examples of electronic devices.

FIGS. 35A and 35B illustrate a structure example of an electronic device, and FIG. 35C illustrates a state where the electronic device is used.

FIGS. 36A to 36F illustrate structures of samples.

FIGS. 37A to 37C show cross sections observed by STEM.

### DETAILED DESCRIPTION OF THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Thus, the present invention should not be construed as being limited to the description of the embodiments below.

In structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

In each drawing described in this specification, the size, the layer thickness, or the region of each component is exaggerated for clarity in some cases. Thus, the size, the layer thickness, or the region is not limited to the illustrated scale.

In this specification and the like, ordinal numbers such as “first” and “second” are used in order to avoid confusion among components and do not limit the number of components.

In this specification and the like, the expression “having substantially the same top surface shapes” means that the outlines of stacked layers at least partly overlap with each other. For example, the case of patterning an upper layer and a lower layer with the use of the same mask pattern or mask patterns that are partly the same is included. The expression “having substantially the same top surface shapes” also sometimes includes the case where the outlines do not strictly overlap with each other; for instance, the edge of the upper layer may be positioned on the inner side or the outer side of the edge of the lower layer.

In this specification and the like, a top surface shape of a component means the outline of the component in a plan view. A plan view means a view to observe the component from a normal direction of a surface where the component is formed or from a normal direction of a surface of a support (e.g., a substrate) where the component is formed.

The expressions indicating directions such as “over” and “under” are basically used to correspond to the directions of drawings. However, in some cases, the term “over” or “under” in the specification indicates a direction that does not correspond to the apparent direction in the drawings, for the purpose of easy description or the like. For example, in the description of the stacked order (or the formation order) of a stacked body or the like, even in the case where a surface on which the stacked body is provided (e.g., a formation surface, a support surface, a bonding surface, or a planarization surface) is located over the stacked body in the drawings, the following expressions are used in some cases: the formation surface side is under the stacked body or the stacked body side is over the formation surface side.

In this specification and the like, the terms “film” and “layer” can be interchanged with each other. For example, in some cases, the term “insulating layer” can be interchanged with the term “insulating film”.

In this specification and the like, silicon oxynitride is a material that contains more oxygen than nitrogen in its composition. Silicon nitride oxide is a material that contains more nitrogen than oxygen in its composition.

In this specification and the like, an EL layer means a layer containing at least a light-emitting substance (also referred to as a light-emitting layer) or a stack including the light-emitting layer provided between a pair of electrodes of a light-emitting element.

In this specification and the like, a structure in which a connector such as a flexible printed circuit (FPC) or a tape carrier package (TCP) is attached to a substrate of a display panel, or a structure in which an IC is mounted on the substrate by a chip on glass (COG) method or the like is referred to as a display panel module or a display module, or simply referred to as a display panel or the like in some cases.

### Embodiment 1

In this embodiment, structure examples and manufacturing method examples of a display device of one embodiment of the present invention will be described.

One embodiment of the present invention is a display device including a light-emitting element (also referred to as a light-emitting device). The display device includes at least two light-emitting elements that emit light of different colors. The light-emitting elements each include a pair of electrodes and an EL layer therebetween. The light-emitting elements are preferably organic electroluminescent elements (organic EL elements). The two or more light-emitting elements that emit light of different colors include respective EL layers containing different light-emitting materials. For example, three kinds of light-emitting elements that emit red (R), green (G), and blue (B) light achieves a full-color display device.

As a way of separately forming part or the whole of an EL layer between light-emitting elements of different colors, an evaporation method using a shadow mask such as a metal mask is known. However, this method makes it difficult to achieve high resolution and a high aperture ratio of a display device because in this method, a deviation from the designed shape and position of a film to be formed is caused by various influences such as low accuracy of the metal mask position, positional deviation between the metal mask and a substrate, a warp of the metal mask, and the vapor-scattering-induced expansion of the outline of the film to be formed. Thus, a measure has been taken for a pseudo increase in resolution (also referred to pixel density). As a specific measure, special pixel arrangement such as PenTile arrangement has been employed.

In one embodiment of the present invention, fine patterning of an EL layer is performed by a photolithography method without a shadow mask such as a metal mask. Thus, it is possible to obtain a display device having high resolution and a high aperture ratio, which has been difficult to achieve. Moreover, EL layers can be formed separately, enabling the display device to perform extremely clear display with high contrast and high display quality.

In one embodiment of the present invention, a partition for dividing the EL layers is provided between two adjacent light-emitting elements (a first light-emitting element and a second light-emitting element). The partition has an inverse tapered shape. The partition includes an insulating structure. Alternatively, the partition includes a conductive structure. Alternatively, the partition includes a stacked-layer structure of an insulating structure and a conductive structure. In other words, the partition has a shape in which its upper portion extends in the horizontal direction beyond the lower portion. The partition is formed to be positioned between two adjacent pixel electrodes.

In this specification and the like, disconnection refers to a phenomenon in which a layer, a film, an electrode, or the like is split because of the shape of its formation surface (e.g., a step).

In this specification and the like, film thickness loss refers to a reduction in the thickness of a layer, a film, an electrode, or the like due to a process after the layer, the film, the electrode, or the like is formed (examples of the process include an etching step at the time of forming another layer, another film, another electrode, or the like).

Note that layers other than a light-emitting layer in an EL layer, such as an electron-injection layer, a hole-injection layer, an electron-transport layer, and a hole-transport layer, can be shared by light-emitting elements of different colors in some cases. Thus, these layers may be formed using the same steps in forming a plurality of light-emitting elements.

After the EL layer of each light-emitting element is formed through the above steps, an upper electrode is formed to cover the EL layers and the partition. In this case, the upper electrode is formed by a film formation method that achieves higher step coverage than that for the EL layers. This enables part of the upper electrode to cover end portions of the EL layers and to be in contact with part of the partition.

In this manner, a light-emitting element including a pixel electrode, an island-shaped EL layer, and an upper electrode in contact with the partition is formed in a region surrounded by the partition. In the case where the partition includes a conductive structure, contact between the conductive structure and the upper electrode enables the partition to function as a wiring for supplying a potential to the upper electrode. In that case, a voltage drop in the upper electrode can be inhibited, and thus a display device with high display quality can be provided.

With the use of the above-described method, light-emitting elements can be formed separately by a photolithography method that enables microfabrication without using a metal mask; thus, a display device achieving extremely high resolution and a high aperture ratio can be manufactured.

It is difficult to set the distance between EL layers of different colors to be less than 10μwith a formation method using a metal mask, for example. By contrast, with use of the above method, the distance can be less than or equal to 3 μm, less than or equal to 2 μm, or less than or equal to 1 μm. With the use of a light exposure apparatus for LSI devices, for example, the distance can be less than or equal to 500 nm, less than or equal to 200 nm, less than or equal to 100 nm, or even less than or equal to 50 nm. Accordingly, the area of a non-light-emitting region that may exist between two light-emitting elements can be significantly reduced, and the aperture ratio can be close to 100%. For example, the aperture ratio can be higher than or equal to 50%, higher than or equal to 60%, higher than or equal to 70%, higher than or equal to 80%, or higher than or equal to 90% and lower than 100%.

Furthermore, the size of the EL layer itself can be made much smaller than that of the case of using a metal mask. For example, in the case of using a metal mask for forming EL layers separately, a variation in the thickness occurs between the center and the edge of an island-shaped EL layer. This causes a reduction in an effective area that can be used as a light-emitting region with respect to the area of the entire EL layer. By contrast, in the above manufacturing method, a film formed to have a uniform thickness is processed to form an island-shaped EL layer with a uniform thickness. Thus, even when the EL layer has a minute size, almost the whole area can be used as a light-emitting region. Thus, the above manufacturing method achieves both high resolution and a high aperture ratio.

As described above, with the above manufacturing method, a display device in which minute light-emitting elements are integrated can be obtained. Thus, without employing special pixel arrangement such as PenTile arrangement for a pseudo increase in resolution, the display device can achieve resolution higher than or equal to 500 ppi, higher than or equal to 1000 ppi, higher than or equal to 2000 ppi, higher than or equal to 3000 ppi, higher than or equal to 5000 ppi, or higher than or equal to 8000 ppi while having a structure in which one pixel includes light-emitting elements of three different colors. The use of PenTile arrangement along with the above method can achieve a further pseudo increase in resolution.

More specific examples will be described below with reference to drawings.

### Structure Example

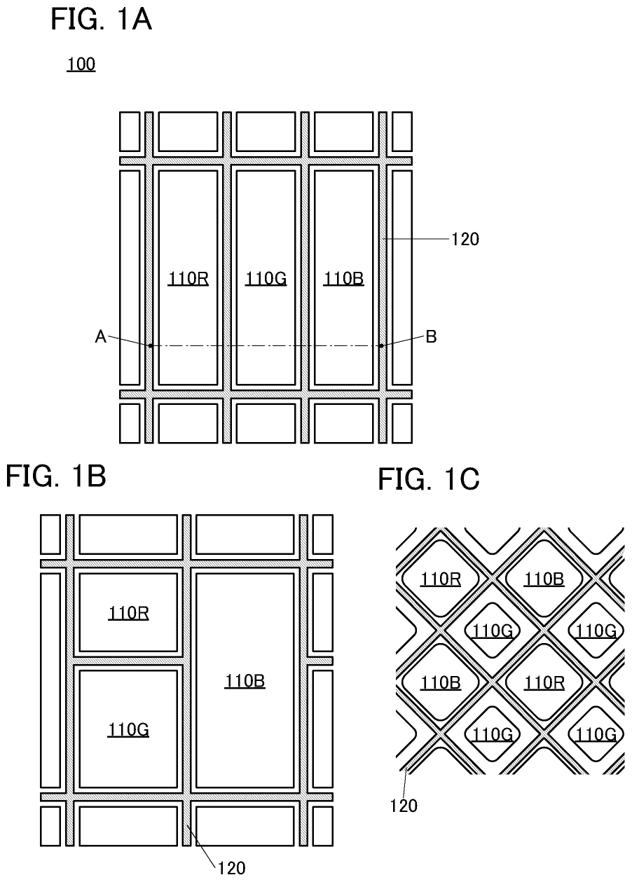

FIG. 1A is a schematic top view of a display device 100. The display device 100 includes a plurality of light-emitting elements 110R exhibiting red, a plurality of light-emitting elements 110G exhibiting green, and a plurality of light-emitting elements 110B exhibiting blue.

The light-emitting elements 110R, 110G, and 110B are arranged in a matrix. FIG. 1A illustrates what is called stripe arrangement, in which light-emitting elements of the same color are arranged in one direction. FIG. 1B illustrates an example in which S-stripe arrangement is employed, and FIG. 1C illustrates an example in which PenTile arrangement is employed. The arrangement of the light-emitting elements is not limited thereto; another arrangement such as delta arrangement or zigzag arrangement may be employed. The use of PenTile arrangement can achieve a further pseudo increase in resolution.

As each of the light-emitting elements 110R, 110G, and 110B, an EL element such as an organic light-emitting diode (OLED) is preferably used. Examples of a light-emitting substance contained in the EL element include a substance that emits fluorescent light (a fluorescent material), a substance that emits phosphorescent light (a phosphorescent material), and a substance that exhibits thermally activated delayed fluorescence (a thermally activated delayed fluorescent (TADF) material). Examples of the light-emitting substance contained in the EL element include not only organic compounds but also inorganic compounds (e.g., quantum dot materials).

In this embodiment, a matter common to components distinguished by alphabet letters or numbers added to a reference numeral (e.g., a first EL layer 112R and a first EL layer 112G) is sometimes described using the reference numeral excluding the alphabet letters or numbers (e.g., a first EL layer 112) without any explanation.

A partition 120 is provided between the light-emitting elements 110. The partition 120 has a lattice-like top-view shape. It can also be said that the light-emitting elements 110 are provided in a region surrounded by the partition 120.

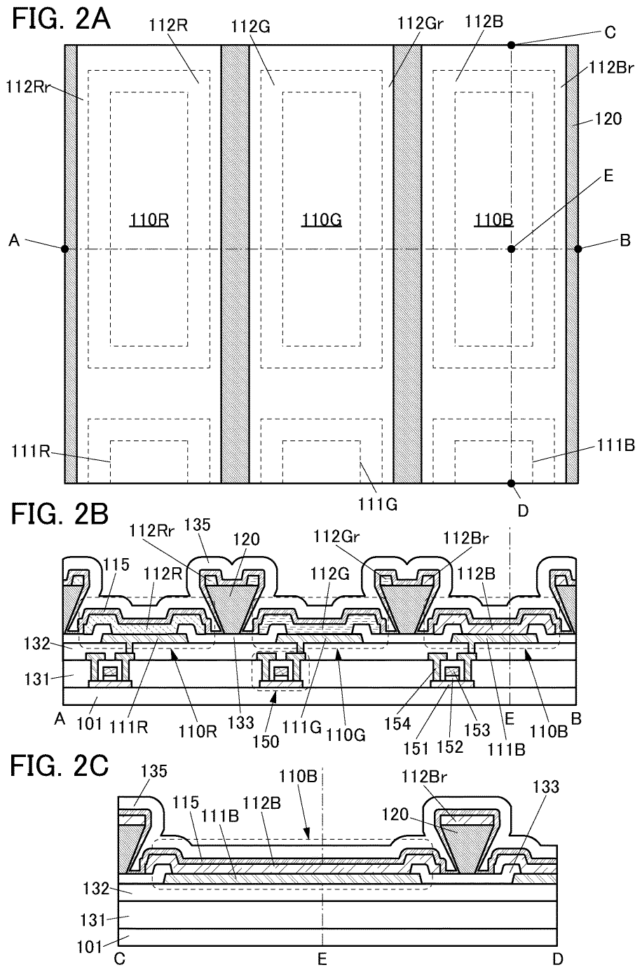

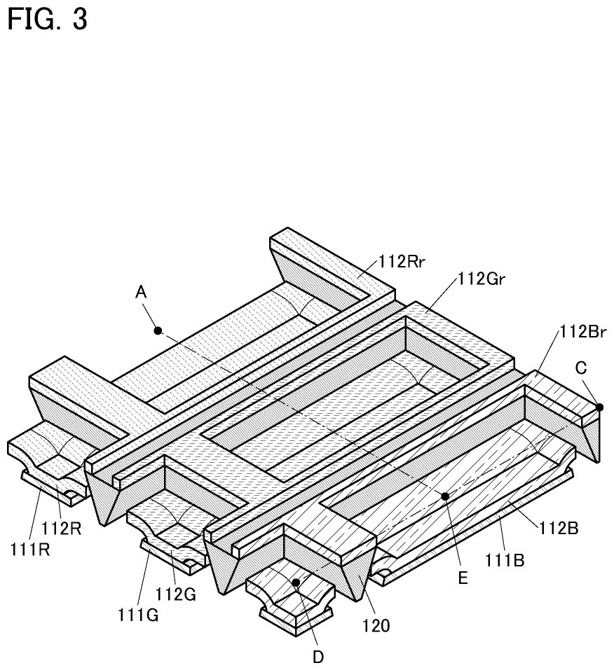

FIG. 2A is an enlarged top view of part of a region illustrated in FIG. 1A. FIG. 2B is a schematic cross-sectional view of the display device 100 taken along line A-B in FIG. 2A, and FIG. 2C is a schematic cross-sectional view of the display device 100 taken along line C-D in FIG. 2A. FIG. 3 is a schematic perspective view corresponding to FIGS. 2A to 2C. The display device 100 includes a plurality of transistors 150, the light-emitting element 110R, the light-emitting element 110G, and the light-emitting element 110B. Note that an upper electrode 115 is not illustrated in FIG. 2A and FIG. 3. Furthermore, some components such as an insulating layer are omitted in FIG. 2A and FIG. 3. Note that a point E is the intersection of the line A-B and the line C-D.

The transistor 150 is provided over a substrate 101. The transistor 150 includes a semiconductor layer 151 where a channel is formed, an insulating layer 152 functioning as a gate insulating layer, a conductive layer 153 functioning as a gate electrode, and a pair of conductive layers 154 that are in contact with the semiconductor layer 151 and function as a source electrode and a drain electrode. The conductive layer 154 is provided over an insulating layer 131 covering the semiconductor layer 151, the insulating layer 152, and the conductive layer 153 and is in contact with the semiconductor layer 151 in an opening portion provided in the insulating layer 131. Note that the transistor 150 is not illustrated in FIG. 2A and FIG. 3.

For the semiconductor layer 151, a metal oxide exhibiting semiconductor characteristics (also referred to as an oxide semiconductor: OS) is preferably used. As the oxide semiconductor, an oxide semiconductor typified by indium oxide or an In—Ga—Zn oxide (IGZO) can be used. Alternatively, the semiconductor layer of the transistor may contain silicon. Examples of silicon include amorphous silicon and crystalline silicon (e.g., low-temperature polysilicon or single crystal silicon).

Other examples of the metal oxide that can be used for the semiconductor layer 151 include tin oxide, zinc oxide, an indium tin oxide (In—Sn oxide), an indium titanium oxide (In—Ti oxide), an indium gallium oxide, an indium tungsten oxide, an indium zinc oxide (In—Zn oxide), an indium gallium aluminum oxide, an indium gallium tin oxide, a gallium zinc oxide, an aluminum zinc oxide, an indium aluminum zinc oxide, an indium tin zinc oxide (In—Sn—Zn oxide), an indium titanium zinc oxide (In—Ti—Zn oxide), an indium gallium zinc oxide (In—Ga—Zn oxide), an indium gallium tin zinc oxide (In—Ga—Sn—Zn oxide), and an indium gallium aluminum zinc oxide. Alternatively, an indium tin oxide containing silicon, a gallium tin oxide, an aluminum tin oxide, or the like can be used.

Although what is called a top-gate transistor in which a gate electrode is positioned above a semiconductor layer is described here as an example of the transistor 150, one embodiment of the present invention is not limited thereto. For example, a bottom-gate transistor in which a gate electrode is positioned below a semiconductor layer can also be used.

An insulating layer 132 is provided to cover the conductive layer 154 and the insulating layer 131, and the light-emitting elements 110R, 110G, and 110B are provided over the insulating layer 132.

The light-emitting element 110R includes an EL layer between a pixel electrode 111R and the upper electrode 115. The light-emitting element 110G includes an EL layer between a pixel electrode 111G and the upper electrode 115. The light-emitting element 110B includes an EL layer between a pixel electrode 111B and the upper electrode 115.

As the EL layer of the light-emitting element 110R, the first EL layer 112R can be used. As the EL layer of the light-emitting element 110G, the first EL layer 112G can be used. As the EL layer of the light-emitting element 110B, a first EL layer 112B can be used.

The upper electrodes 115 of the light-emitting elements 110R, 110G, and 110B are preferably electrically connected to each other. FIGS. 2B and 2C illustrate a structure in which the upper electrode 115 is shared by the light-emitting elements 110R, 110G, and 110B, thereby forming a continuous conductive layer that covers the EL layers of the three light-emitting elements.

Each pixel electrode 111 is provided over the insulating layer 132 and is connected to the conductive layer 154 through an opening portion provided in the insulating layer 132. Accordingly, each pixel electrode 111 is connected to one of the source electrode and the drain electrode of the transistor 150.

The first EL layer 112R included in the light-emitting element 110R contains at least a light-emitting organic compound emitting red light. The first EL layer 112G included in the light-emitting element 110G contains at least a light-emitting organic compound emitting green light. The first EL layer 112B included in the light-emitting element 110B contains at least a light-emitting organic compound emitting blue light. Blue light has an emission peak in the wavelength range greater than or equal to 450 nm and less than or equal to 520 nm, for example. Green light has an emission peak in the wavelength range greater than or equal to 500 nm and less than or equal to 600 nm, for example. Red light has an emission peak in the wavelength range greater than or equal to 600 nm and less than or equal to 700 nm, for example.

The EL layers included in the light-emitting elements 110R, 110G, and 110B may each include one or more of an electron-injection layer, an electron-transport layer, an electron-blocking layer, a hole-injection layer, a hole-transport layer, and a hole-blocking layer in addition to a layer containing a light-emitting substance (a light-emitting layer). Thus, the first EL layers 112R, 112G, and 112B each include one or more of an electron-injection layer, an electron-transport layer, an electron-blocking layer, a hole-injection layer, a hole-transport layer, and a hole-blocking layer in addition to a light-emitting layer, for example. As the light-emitting substance, an organic compound can be used, for example.

The light-emitting element 110 can have a tandem structure, for example. In the tandem structure, a plurality of light-emitting units can be provided between a pixel electrode and an upper electrode, for example. Each light-emitting unit includes one or more light-emitting layers. An intermediate layer such as a charge-generation layer is preferably provided between the light-emitting units. In the case where the light-emitting element 110 has a tandem structure, the EL layer included in the light-emitting element 110 can include a plurality of light-emitting units and an intermediate layer such as a charge-generation layer provided between the light-emitting units.

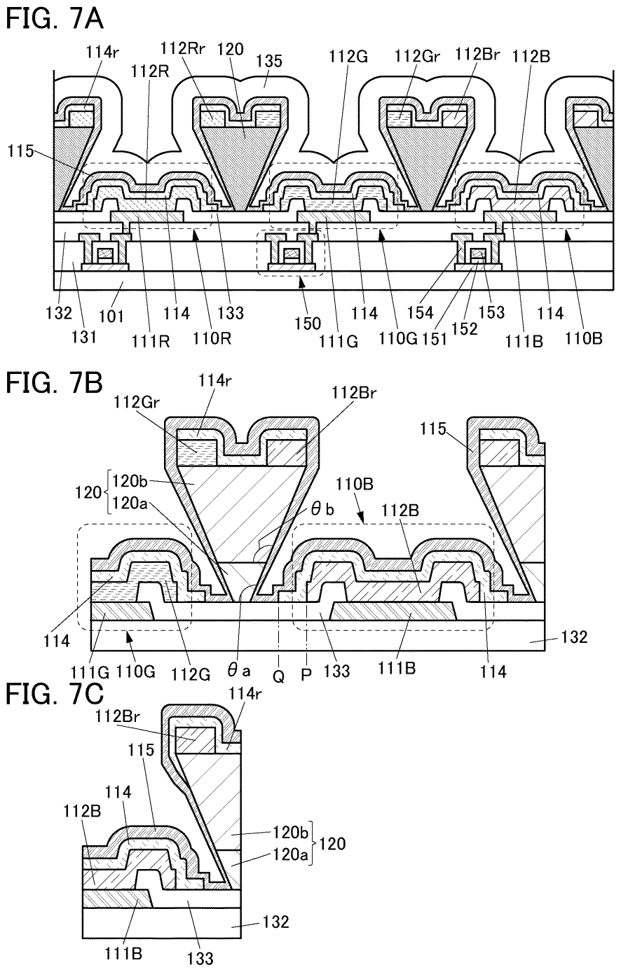

In the case where the light-emitting elements 110R, 110G, and 110B each include the second EL layer 114 as will be described later with reference to FIGS. 7A to 7C, one or more of an electron-injection layer, an electron-transport layer, an electron-blocking layer, a hole-injection layer, a hole-transport layer, and a hole-blocking layer may be included in the second EL layer 114. As the second EL layer 114, a layer containing an organic compound can be used, for example. The second EL layer 114 may contain an inorganic compound.

In the case where the light-emitting element 110R includes the second EL layer 114, for example, a stacked-layer structure of the first EL layer 112R and the second EL layer 114 can function as the EL layer of the light-emitting element 110R. In the case where the light-emitting element 110G includes the second EL layer 114, for example, a stacked-layer structure of the first EL layer 112G and the second EL layer 114 can function as the EL layer of the light-emitting element 110G. In the case where the light-emitting element 110B includes the second EL layer 114, for example, a stacked-layer structure of the first EL layer 112B and the second EL layer 114 can function as the EL layer of the light-emitting element 110B. In each of the structures, the second EL layer 114 includes, for example, an electron-injection layer or a hole-injection layer. Alternatively, the second EL layer 114 may be a stack of an electron-transport layer and an electron-injection layer, or may be a stack of a hole-transport layer and a hole-injection layer.

A conductive film that has a property of transmitting visible light is used for either the respective pixel electrodes 111 or the upper electrode 115, and a reflective conductive film is used for the other. When the pixel electrodes 111 are light-transmitting electrodes and the upper electrode 115 is a reflective electrode, a bottom-emission light-emitting element can be obtained. When the pixel electrodes 111 are reflective electrodes and the upper electrode 115 is a light-transmitting electrode, a top-emission light-emitting element can be obtained. When both the pixel electrodes 111 and the common electrode 115 are light-transmitting electrodes, a dual-emission light-emitting element can be obtained.

A protective layer 135 is provided to cover the upper electrode 115.

The protective layer 135 can have, for example, a single-layer structure or a stacked-layer structure at least including an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as an indium gallium oxide or an indium gallium zinc oxide may be used for the protective layer 135.

As the protective layer 135, a stacked film of an inorganic insulating film and an organic insulating film can also be used. For example, a structure in which an organic insulating film is sandwiched between a pair of inorganic insulating films is preferable.

An insulating layer 133 is provided to cover an end portion of each pixel electrode 111. A portion of each of the pixel electrodes 111 where the insulating layer 133 is not provided functions as a light-emitting region of the light-emitting element 110. An end portion of the insulating layer 133 is preferably tapered. The insulating layer 133 is not necessarily provided when not needed.

In this specification and the like, the expression “an end portion of an object is tapered” indicates that the object has a cross-sectional shape in which an angle formed by a side surface of the object and a contact surface of the object with a formation surface (also referred to as a taper angle) is greater than 0° and less than 90°, and in which the thickness continuously increases from the end portion. Meanwhile, the expression “an object has an inverse tapered shape” indicates that an angle formed by a side surface of the object and a contact surface of the object with a formation surface is greater than 90° and less than 180°. A cross-sectional shape of an object in which the upper base is smaller than the lower base is sometimes referred to as a tapered shape, and a cross-sectional shape of an object in which the upper base is larger than the lower base is sometimes referred to as an inverse tapered shape.

The insulating layer 133 preferably includes an inorganic insulating film. When the insulating layer 133 includes an inorganic insulating film, the etching resistance of the insulating layer 133 can be increased. Accordingly, the film thickness loss of the insulating layer 133 in the manufacturing step or the like after the formation of the insulating layer 133 can be inhibited, so that the manufacturing yield can be improved. The film thickness loss of the insulating layer 133 might occur particularly when processing into the EL layers is performed by etching and the insulating layer 133 has low etching resistance. As a result, disconnection of the upper electrode 115 might occur and the upper electrode 115 might be broken at a portion where the thickness of the insulating layer 133 is reduced. When an inorganic insulating film having high etching resistance is used for the insulating layer 133, the etching rate selectivity of the EL layers with respect to the insulating layer 133 can be high and the film thickness loss of the insulating layer 133 in etching of the EL layers can be inhibited, which is preferable.

The insulating layer 133 can contain an organic resin. The insulating layer 133 containing an organic resin can have high adhesion to the first EL layer 112, and the manufacturing yield can be improved. In the case where processing into the EL layers is performed by etching, in particular, the use of the insulating layer 133 having high adhesion to the EL layers can inhibit a defect such as separation of the EL layers after etching. Furthermore, the insulating layer 133 containing an organic resin can have a flat surface and a gently curved surface. Thus, coverage with a film formed over the insulating layer 133 can be improved.

Examples of the inorganic insulating film that can be used for the insulating layer 133 include a silicon oxynitride film, a silicon oxide film, a silicon nitride film, a silicon nitride oxide film, an aluminum oxide film, and an aluminum nitride film. The examples of the inorganic insulating film may include a hafnium oxide film, an yttrium oxide film, a zirconium oxide film, a gallium oxide film, a tantalum oxide film, a magnesium oxide film, a lanthanum oxide film, a cerium oxide film, and a neodymium oxide film. A stack including two or more of the above inorganic insulating films may also be used.

Examples of the organic resin that can be used for the insulating layer 133 include an acrylic resin, a polyimide resin, an epoxy resin, a polyamide resin, a polyimide-amide resin, a siloxane resin, a benzocyclobutene-based resin, a phenol resin, and precursors of these resins. A stack including two or more of the above organic resins may also be used. In this specification and the like, an acrylic resin refers not only to a polymethacrylic acid ester or a methacrylic resin, but also to all the acrylic polymer in a broad sense in some cases.

A stack including any of the above inorganic insulating films and organic resins may be used as the insulating layer 133. In that case, two or more inorganic insulating films may be stacked or two or more organic resins may be stacked.

The first EL layers 112 each include a region in contact with the top surface of the pixel electrode 111 and a region in contact with a surface of the insulating layer 133. End portions of the first EL layers 112 are positioned over the insulating layer 133.

The partition 120 is provided over the insulating layer 133. The partition 120 has an inverse tapered shape. The partition 120 having an inverse tapered shape can cause disconnection of the EL layer such as the first EL layer 112, resulting in formation of the EL layers such as the first EL layers 112 without using a metal mask or the like for evaporation.

A film 112Rr, a film 112Gr, and a film 112Br are provided over the partition 120. The upper electrode 115 covers the films 112Rr, 112Gr, and 112Br and has a region in contact with the top surface of the partition 120.

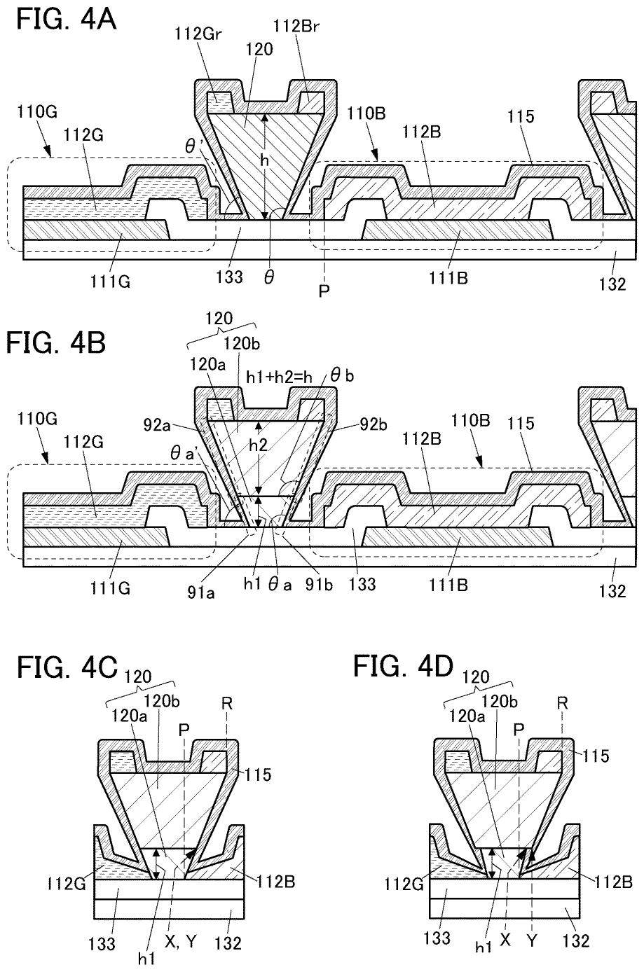

FIG. 4A illustrates an example of an enlarged view of FIG. 2B that illustrates the light-emitting elements 110B and 110G, the partition 120 positioned therebetween, and the vicinity thereof. In FIG. 4A, the dimension ratios between some components, the aspect ratios of some components, and the like are sometimes different from those in FIG. 2B.

The end portions of the first EL layers 112B and 112G are positioned over the insulating layer 133. The upper electrode 115 covers the end portions of the first EL layers 112B and 112G and is in contact with at least part of the top surface of the insulating layer 133 and at least part of a side surface of the partition 120. The upper electrode 115 covers the films 112Br and 112Gr and is in contact with the top surface of the partition 120.

Alternatively, the first EL layers 112B and 112G are in contact with part of the side surface of the partition 120 in some cases, as illustrated in FIGS. 4C and 4D. In that case as well, The upper electrode 115 is preferably in contact with at least part of the side surface of the partition 120.

Although FIGS. 2B and 2C illustrate an example in which the height of the partition 120 is larger than the width thereof, the actual cross-sectional width is larger than the actual height in some cases. FIG. 4A and the like illustrate an example in which the cross-sectional width of the partition 120 is larger than the height thereof. Furthermore, FIG. 4A and the like illustrate an example in which the width of the EL layer is larger than the width of the partition.

Note that the side surface of the partition 120 is referred to as a sidewall in some cases.

The upper electrodes 115 of adjacent light-emitting elements (here, the light-emitting elements 110B and 110G are described as an example) are preferably electrically connected to each other. In the above-described structure, the upper electrode 115 shared by the light-emitting elements 110B and 110G, i.e., a continuous conductive layer, covers the EL layers of the two light-emitting elements. However, the upper electrode 115 may partly disappear on the side surface of the partition 120, and parts of the divided upper electrodes may each be in contact with part of the partition 120. In such a structure, the parts of the divided upper electrodes 115 can be electrically connected to each other through the partition 120.

The partition 120 is provided in a lattice pattern so as to cross between the light-emitting elements 110 as illustrated in FIG. 1A and the like and thus can also function as a wiring for supplying a potential to the upper electrode 115 of each light-emitting element 110.

A taper angle θ of the partition 120 can be greater than 90° and less than 180°. As the taper angle becomes closer to 90°, the partition 120 and the upper electrode 115 become easier to come into contact with each other at the time of forming the upper electrode 115, whereas a gap between the end portion of the first EL layer 112 and the partition 120 becomes smaller. As the taper angle becomes closer to 180°, the first EL layer 112 becomes easier to be disconnected, whereas it becomes more difficult to make the upper electrode 115 and the partition 120 in contact with each other. Thus, the taper angle θ can be, for example, greater than or equal to 95° and less than or equal to 170°, preferably greater than or equal to 95° and less than or equal to 150°, further preferably greater than or equal to 100° and less than or equal to 135°.

When the taper angle θ is increased, for example, the EL layer can be prevented from being in contact with the side surface of the partition 120. Thus, the taper angle θ can be greater than or equal to 105° and less than or equal to 175°, preferably greater than or equal to 120° and less than or equal to 170°, for example.

When the taper angle is 130°or close to 130°, for example, an EL layer formed by an evaporation method or the like can be disconnected by the partition 120, and the upper electrode 115 formed by a method suitable for mass production, such as an evaporation method, a sputtering method, or a chemical vapor deposition (CVD) method, can be easily in contact with the side surface of the partition 120. Here, an angle close to a given angle includes a range within ±10°, preferably ±5°, of the given angle, for example.

In the description of the shape of the partition, the taper angle is the angle between the bottom surface and the side surface of the partition 120; however, the taper angle can be an angle (the supplement θ′ of the taper angle) between the side surface of the partition 120 and the top surface of a base film of the partition 120 (here, the insulating layer 133) that is not in contact with the partition 120 as illustrated in FIG. 4A. In that case, θ′=180°−θ (each of θ and θ′ is greater than or equal to 0° and less than or equal to 180°) is satisfied. Thus, the preferable range of the supplement θ′ of the taper angle can be greater than or equal to 30° and less than or equal to 85°, preferably greater than or equal to 45° and less than or equal to 80°, or greater than or equal to 5° and less than or equal to 75°, preferably greater than or equal to 10° and less than or equal to 60°, further preferably 50° or close to 50°. Which of the taper angle and its supplement to use can be selected depending on which is easier to measure in consideration of the surface shape of the base film (e.g., the insulating layer 133).

With such a structure, EL layers can be formed separately between adjacent light-emitting elements; thus, leakage current through the EL layers can be practically zero, unlike in the case where the EL layers are in contact with each other or a common EL layer is used. This can prevent unintended light emission, so that a display device with high contrast and high display quality can be obtained. That is, a black display portion can be displayed in a deeper black, providing a sense of depth. Furthermore, since the first EL layer 112 is covered with the upper electrode 115 and the protective layer 135 in a region surrounded by the partition 120, diffusion of impurities such as moisture into the first EL layer 112 can be prevented, so that a highly reliable display device can be obtained. In this structure, processing of the first EL layer 112 and the like can be performed by a photolithography method without using a metal mask; hence, higher resolution and a higher aperture ratio can be easily achieved as compared with the case of using a metal mask.

The end portion of the first EL layer 112B can be substantially aligned with an end portion of the top surface of the partition 120.

FIG. 4A illustrates an example in which an end portion P of the first EL layer 112B is aligned with the end portion of the top surface of the partition 120. In the case where the first EL layer 112B is formed by an evaporation method, the first EL layer 112B is preferably deposited by evaporation of a material traveling in a direction perpendicular or substantially perpendicular to a substrate surface from an evaporation source. Here, “a material traveling in a direction perpendicular or substantially perpendicular to a substrate surface” means, for example, that the material travels in a direction at an angle, with respect to the substrate surface, greater than or equal to 75° and less than or equal to 105°, preferably greater than or equal to 80° and less than or equal to 100°, further preferably greater than or equal to 85° and less than or equal to 95°. When the material is controlled to travel in the substantially perpendicular direction from the evaporation source, the first EL layer 112B can be formed such that the end portion P is substantially aligned with the end portion of the top surface of the partition 120.

Hereinafter, symbols R, G, and B are sometimes omitted in the description common to the light-emitting element 110R, the light-emitting element 110G, and the light-emitting element 110B. The symbols R, G, and B are sometimes omitted also in the description common to the first EL layer 112R, the first EL layer 112G, and the first EL layer 112B.

Note that the cross section of the partition 120 may have rounded corners.

The partition 120 illustrated in FIG. 2B and the like has an inverse tapered shape. In the case where the adhesion between a film to be the partition 120 (a film 120f described later) and a mask (e.g., a resist mask) used in forming the partition 120 by processing the film 120f is lower than the adhesion between the insulating layer 133 and the film 120f, it is sometimes difficult to form the inverse tapered shape because the etching rate at the upper portion of the film 120f is higher than that at the lower portion. Thus, the adhesion between the top surface of the film 120f and a mask such as a resist mask is preferably higher than the adhesion between the insulating layer 133 and the film 120f.

The etching rate of the film 120f can be adjusted by changing at least one of the kind of material used for the film 120f and the film quality of the film 120f, for example. The taper angle of the tapered shape can be adjusted by setting the etching rate of the film 120f to a desired value. The etching rate of the film 120f can be adjusted by, for example, selecting materials of the film 120f such that the etching rate of the film 120f differs between the upper portion and the lower portion, or making the density of the lower portion of the film 120f low and making the density of the upper portion of the film 120f high. The film 120f may be formed using a material having crystallinity, such as a metal. In the case where the film 120f is formed using a material having crystallinity and the insulating layer 133 does not have specific crystallinity or has low crystallinity, the crystallinity of the lower portion of the film 120f can be decreased in accordance with the low-crystallinity of the insulating layer 133. Meanwhile, a portion of the film 120f that is away from the insulating layer 133 can have the material's original crystal structure; thus, the upper portion of the film 120f can have higher crystallinity. As a result, the etching rate of the upper portion having higher crystallinity can be lower than that of the lower portion having lower crystallinity in the film 120f. By the above-described means, the etching rates of the upper portion and the lower portion of the film 120f can be adjusted to desired values, and the taper angle θ can be a desired value. In the case where the taper angle θ is set larger than a desired value (or the supplement θ′ of the taper angle is set smaller than a desired value), the etching rate of the upper portion of the film 120f is preferably lower than a desired etching rate and the etching rate of the lower portion of the film 120f is preferably higher than a desired etching rate. As described above, the structure of the partition 120 can be determined by changing the material, the film quality, or the like of the film 120f so that the taper angle has a desired value.

FIG. 4B illustrates a structure example in which the partition 120 has a stacked-layer structure of a layer 120a and a layer 120b over the layer 120a. In the structure example, the layer 120a may include a conductive structure or include an insulating structure. The layer 120b preferably includes a conductive structure. In the case where the layer 120a contains an insulating material, the layer 120a functions as an insulating layer. In the case where the layer 120a and the layer 120b contain a conductive material, the layer 120a and the layer 120b function as conductive layers. When at least the layer 120b functions as a conductive layer, the partition 120 can be used as a wiring for supplying a potential to the upper electrode 115. When the layer 120a functions as an insulating layer, it is preferable that the upper electrode 115 be in contact with a side surface of the layer 120b. When the layer 120b functions as a conductive layer, it is further preferable that the upper electrode 115 be in contact with the top surface and the side surface of the layer 120b. In that case, the contact resistance can be suitably reduced as compared with the case where only the side surface of the layer 120b is in contact with the upper electrode 115. For the layer 120b, a material having high adhesion to a mask at the time of forming the partition 120 is preferably used.

In the case where a conductive material is used for the layer 120a and the layer 120b, the upper electrode 115 is preferably in contact with at least one of a side surface of the layer 120a and the side surface of the layer 120b.

An insulating material can be used for both the layer 120a and the layer 120b. In that case, the layer 120a and the layer 120b do not function as a wiring for supplying a potential to the upper electrode 115. Meanwhile, such a structure can inhibit generation of leakage current between the first EL layer 112B and the first EL layer 112G even when the EL layers are in contact with the layer 120a and the layer 120b.

The layer 120b is a region having an inverse tapered shape. A taper angle of the layer 120b is referred to as a taper angle θb. As for a supplement θb′ of the taper angle θb, θb′=180°−θ is satisfied. The taper angle θb can be formed by the bottom surface of the layer 120b and the side surface of the layer 120b. Alternatively, the taper angle θb can be formed by the bottom surface of the partition 120 and the side surface of the layer 120b. As the preferable range of the taper angle θb of the layer 120b, the preferable range of the taper angle θ of the partition 120 with reference to FIG. 4A can be employed. The taper angle θb of the layer 120b can be greater than 90° and less than 180°. The taper angle θb can be, for example, greater than or equal to 95° and less than or equal to 170°, preferably greater than or equal to 95° and less than or equal to 150°, further preferably greater than or equal to 100° and less than or equal to 135°. The taper angle θb can be greater than or equal to 105° and less than or equal to 175°, preferably greater than or equal to 120° and less than or equal to 170°; e.g., 130° or close to 130°.

The preferable range of the supplement θb′ of the taper angle can be greater than or equal to 30° and less than or equal to 85°, preferably greater than or equal to 45° and less than or equal to 80°, or greater than or equal to 5° and less than or equal to 75°, preferably greater than or equal to 10° and less than or equal to 60°; e.g., 50° or close to 50°.

The layer 120a can be thinner than the layer 120b. In FIG. 4B, the height of the layer 120a is illustrated as a height h1, and the height of the layer 120b is illustrated as a height h2. The sum of the height h1 and the height h2 is a height h. The height h1 can also be expressed as the thickness of the layer 120a. The height h2 can also be expressed as the thickness of the layer 120b.

The height h2 is preferably greater than or equal to 40 nm, further preferably greater than or equal to 300 nm, for example.

A taper angle of the layer 120a is referred to as a taper angle θa. In the case where the thickness of the layer 120a is sufficiently small, that is, in the case where the height h1 is sufficiently small, for example, the EL layer such as the first EL layer 112 can be disconnected even when the layer 120a does not have an inverse tapered shape, specifically, the taper angle θa is less than 90° (a supplement θa′ is greater than or equal to 90°), for example. In that case, the degree of freedom of the taper angle at the side surface of the layer 120a is increased, and the degree of freedom in selecting a method for etching the layer 120a, the etching conditions, and a material of the layer 120b can be increased. In the case where the layer 120a is thicker than the layer 120b and the taper angle θa is less than 90°, on the other hand, coverage with the EL layer on the side surface of the layer 120a is increased, which raises a concern that the EL layer cannot be disconnected.

Thus, the height h1 is preferably less than or equal to 0.5 times, further preferably less than or equal to 0.2 times the height h, for example. The height h1 is preferably less than or equal to 170 nm, further preferably less than or equal to 70 nm, for example.

As illustrated in FIG. 4C, the first EL layer 112B and the first EL layer 112G are in contact with part of the side surface of the partition 120 (the layer 120a here) in some cases. In that case, when the layer 120a is formed using a conductive material, electrical continuity is established between the first EL layer 112B and the first EL layer 112G through the layer 120a and leakage current is generated between the first EL layer 112B and the first EL layer 112G, in some cases. Thus, the layer 120a is preferably formed using an insulating material so that electrical continuity between the first EL layer 112B and the first EL layer 112G is not established. The layer 120b is preferably formed using a conductive material. In that case, an end portion X of the top surface of the layer 120a and an end portion Y of the bottom surface of the layer 120b are preferably substantially aligned with each other. Alternatively, as illustrated in FIG. 4D, the end portion X of the top surface of the layer 120a is preferably positioned inward from the end portion Y of the bottom surface of the layer 120b. The height h1 of the layer 120a is preferably larger than the thickness of the first EL layer 112R, 112G, or the first EL layer 112B in a portion where the first EL layer 112R, 112G, or 112B is in contact with the layer 120a. In that case, the first EL layer 112R, 112G, or 112B can be inhibited from overlapping onto the top surface of the layer 120a and thus can be inhibited from being in contact with the layer 120b having conductivity. As a result, the first EL layer 112R, 112G, or 112B can be in contact with only the layer 120a having an insulating property in the partition 120; thus, generation of leakage current can be inhibited.

For the above reason, in the structure examples illustrated in FIGS. 4C and 4D, the layer 120a is preferably formed using an insulating material so that generation of leakage current can be inhibited. That is, a layer of the partition 120 that is in contact with the insulating layer 133 (the layer 120a here) is formed using an insulating material. The layer 120b is preferably formed using a conductive material. The upper electrode 115 is in contact with the side surface of the layer 120b. In this manner, the upper electrode 115 and the partition 120 can be electrically connected to each other.

As illustrated in FIG. 4B, the layer 120a has a side surface 91a and a side surface 91b, and the layer 120b has a side surface 92a and a side surface 92b. The side surface 91a and the side surface 91b face each other and the side surface 92a and the side surface 92b face each other. The side surfaces 91a and 92a of the partition 120 are on the side where the light-emitting element 110G is positioned, and the side surfaces 91b and 92b are on the side where the light-emitting element 110B is positioned.

FIG. 4B illustrates an example in which the upper electrode 115 is in contact with the side surfaces 91a and 91b and the side surfaces 92a and 92b.

In the upper electrode 115, a region in contact with the side surfaces 91b and 92b is connected to a region positioned over the first EL layer 112B as illustrated in FIG. 4B. Accordingly, in the case where a region of the upper electrode 115 over the first EL layer 112B is electrically connected to the partition 120 and the partition 120 is used as a wiring, a potential supplied to the wiring can be applied to a region of the upper electrode 115 over the first EL layer 112B. Furthermore, in the upper electrode 115, a region in contact with the side surfaces 91a and 92a is connected to a region positioned over the first EL layer 112G. Accordingly, in the case where a region of the upper electrode 115 over the first EL layer 112G is electrically connected to the partition 120 and the partition 120 is used as a wiring, a potential supplied to the wiring can be applied to a region of the upper electrode 115 over the first EL layer 112G.

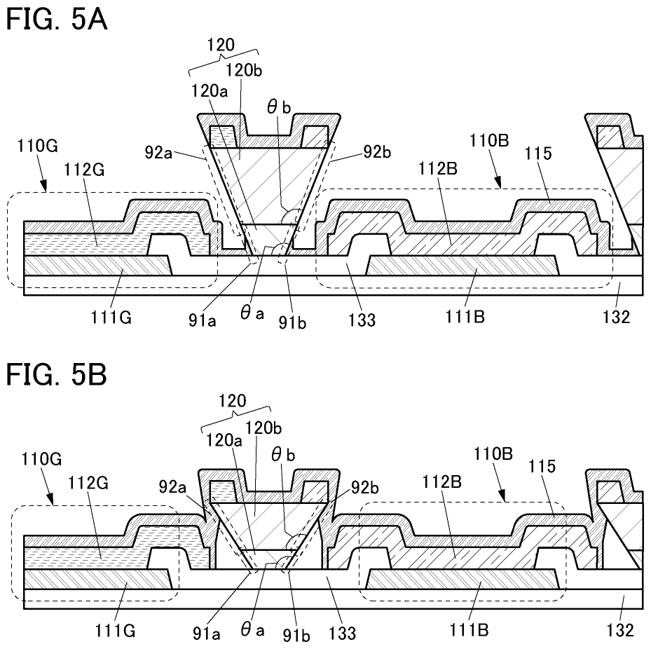

FIG. 5A illustrates an example in which the upper electrode 115 is in contact with the side surfaces 91a and 91b and is not in contact with the side surfaces 92a and 92b. In that case, the layer 120a contains a conductive material and functions as a conductive layer. In the upper electrode 115, a region in contact with the side surface 91b is connected to a region positioned over the first EL layer 112B as illustrated in FIG. 5A. Furthermore, in the upper electrode 115, a region in contact with the side surface 91a is connected to a region positioned over the first EL layer 112G.

FIG. 5B illustrates an example in which the upper electrode 115 is in contact with the side surfaces 92a and 92b and is not in contact with the side surfaces 91a and 91b. A gap is generated in the vicinity of the side surfaces 91a and 91b in some cases. In that case, at least the layer 120b of the layers 120a and 120b contains a conductive material and functions as a conductive layer. In the upper electrode 115, a region in contact with the side surface 92b is connected to a region positioned over the first EL layer 112B as illustrated in FIG. 5B. Furthermore, in the upper electrode 115, a region in contact with the side surface 92a is connected to a region positioned over the first EL layer 112G.

Any of a variety of conductive materials can be used for each layer of the partition 120. For example, a metal, an alloy, an oxide conductive material, or a nitride conductive material can be used. For example, it is possible to use a metal material such as molybdenum, gold, silver, platinum, magnesium, nickel, tungsten, chromium, iron, cobalt, copper, palladium, titanium, aluminum, yttrium, zirconium, or tantalum or an alloy material containing the metal material.

For each layer of the partition 120, an oxide conductive material can be used. For example, an oxide conductive material containing one or more of indium, tin, and zinc can be used.

As an oxide conductive material containing indium, specifically, an indium tin oxide, indium oxide, an indium zinc oxide, an indium titanium oxide, an indium gallium zinc oxide, an indium tin zinc oxide, an indium titanium zinc oxide, or an indium gallium tin zinc oxide can be used, for example. An oxide containing silicon can be used as the oxide conductive material. As the oxide containing silicon, for example, an indium tin oxide containing silicon can be used.

Any of a variety of insulating materials can be used for each layer of the partition 120. As the insulating material, an inorganic insulating material or an organic insulating material can be used.

Examples of the inorganic insulating material aluminum oxide, silicon nitride, silicon oxynitride, silicon oxide, silicon nitride oxide, and aluminum nitride. As the inorganic insulating material, hafnium oxide, yttrium oxide, zirconium oxide, gallium oxide, tantalum oxide, magnesium oxide, lanthanum oxide, cerium oxide, neodymium oxide, or the like may be used. A stack including two or more of the above inorganic insulating materials may also be used.

Examples of the organic insulating material include an acrylic resin, a polyimide resin, an epoxy resin, a polyamide resin, a polyimide-amide resin, a siloxane resin, a benzocyclobutene-based resin, a phenol resin, and precursors of these resins.

A stack including an inorganic insulating material and an organic insulating material can also be used.

In the case where the layer 120a contains a first material, the layer 120b preferably contains a second material that is different from the first material. Any of the above-described materials can be used as the first material and the second material.

The layer 120a and the layer 120b can contain materials with different compositions. Fo example, the layer 120a and the layer 120b can each contain an oxide containing oxygen and a plurality of metals, and the compositions of the metals can differ between the layer 120a and the layer 120b.

For the layer 120a, one or more selected from the above-described materials can be used as a single layer or a stacked-layer structure of two or more layers. For the layer 120b, one or more selected from the above-described materials can be used as a single layer or a stacked-layer structure of two or more layers.

For the layer 120b, an oxide containing indium and tin can be used. An oxide containing indium and tin can be suitably used as a conductive material.

For the layer 120b, an indium tin zinc oxide (In—Sn—Zn oxide) or an indium tin oxide containing silicon (In—Sn—Si oxide, also referred to as ITSO) can be used, for example.

The layer 120b preferably has high adhesion to a resist mask. For the layer 120b, any of a variety of materials such as a conductive material, an inorganic insulating material, and an organic insulating material can be used. When the layer 120b is formed using a conductive material, the contact area between the upper electrode 115 and the conductive material in the partition 120 can be increased, whereby the contact resistance can be suitably reduced.

In the case where adhesion between the top surface of the partition 120 and a resist mask is low, an etchant easily enters between the top surface of the partition 120 and the resist mask. Thus, the etching on the upper layer side of the partition 120 proceeds as the etching on the lower layer side of the partition 120 proceeds, and it is sometimes difficult to make the partition 120 have an inverse tapered shape.

Thus, in the case where the adhesion between the layer 120a and the resist mask is not sufficiently high, the layer 120b is provided on the upper layer side of the partition 120 that is in contact with the resist mask, in which case the adhesion between the top surface of the partition 120 and the resist mask can be ensured and as a result, the partition 120 can have an inverse tapered shape.

The adhesion between a material used for the layer 120b and the resist mask is higher than the adhesion between a material used for the layer 120a and the resist mask, for example. In the case where films of materials used for the layers 120b and 120a are formed and a resist mask is formed over each film, the force required for peeling the resist mask from the material used for the layer 120b, which is measured using a separation test, is preferably greater than the force required for peeling the resist mask from the material used for the layer 120a.

The adhesion can be examined by a separation test described later, for example.

In the case where the layer 120a and the layer 120b are formed using the same wet etchant, a material whose wet etching rate is lower than that of a material for the layer 120a is preferably used for the layer 120b. In the case where the wet etching rate of the layer 120b is higher than that of the layer 120a, an end portion of the layer 120b might be positioned inward from that of the layer 120a, for example, which might generate a portion where the layer 120b is removed by wet etching between the layer 120a and the resist mask. This might generate a gap between the top surface of the layer 120a and the resist mask in the upper region of the layer 120a. When the layer 120b is formed using a material with a lower wet etching rate than a material for the layer 120a, the partition 120 can have a suitable shape.

In the case where the layer 120b has a stacked-layer structure of two or more layers, different materials are preferably used for a lower layer that is in contact with the layer 120a and an upper layer that is in contact with a resist mask, and a material with lower wet etching rate is preferably used for the upper layer of the layer 120b. In that case, an end portion of the lower layer of the layer 120b is positioned inward from an end portion of the upper layer of the layer 120b, whereby the partition 120 can suitably have an inverse tapered shape.

In the layer 120b having a stacked-layer structure, an indium tin zinc oxide (In—Sn—Zn oxide) can be used for the lower layer, for example. For the upper layer, an indium tin oxide containing silicon (In—Sn—Si oxide, also referred to as ITSO), which has a lower wet etching rate than the indium tin zinc oxide (In—Sn—Zn oxide), can be used, for example.

In the layer 120b having a stacked-layer structure, the same material can be used for each layer. In that case, the layers are preferably formed by changing the conditions of a film formation apparatus such that the lower layer has a lower density than the upper layer and the upper layer has a higher density than the lower layer. For example, a high-density film can be obtained when the pressure in a film formation chamber of the film formation apparatus during film formation is reduced, whereas a low-density film can be obtained when the pressure is increased. Furthermore, a high-density film can be obtained when the power (which corresponds to, but is not limited to, the output value of a power source of the film formation apparatus, for example) of the film formation apparatus during film formation is increased, whereas a low-density film can be obtained when the power during film formation is decreased. A high-density layer has a lower wet etching rate than a low-density layer; thus, when the density of the upper layer of the layer 120b having a stacked-layer structure is high, the layer 120b can suitably have an inverse tapered shape.

In the case where the same material is used for each layer in the layer 120b having a stacked-layer structure, an indium tin zinc oxide (In—Sn—Zn oxide) or an indium tin oxide containing silicon (In—Sn—Si oxide, also referred to as ITSO) can be used, for example.

In the layer 120b having a stacked-layer structure, providing a plurality of layers formed using materials with different wet etching rates and providing a plurality of layers having different film densities formed using the same material may be combined. For example, a stacked-layer structure of three or more layers may be formed by forming a low-density film of an indium tin zinc oxide as the layer 120b, forming a high-density film of an indium tin zinc oxide over the layer 120b, and forming a film of an indium tin oxide containing silicon thereover.

When the partition 120 or the layer 120b is formed using a material with low reflectance or a material with low light transmittance, or the top surfaces of the layer 120b is subjected to surface treatment to be blackened, the partition 120 or the layer 120b can function as a light-blocking layer. The partition 120 or the layer 120b functioning as a light-blocking layer can prevent light entering from an adjacent light-emitting device. Furthermore, the transistor 150 is preferably laid out to overlap with the partition 120 or the layer 120b.

Although FIG. 4A or the like illustrates an example in which the end portion P of the first EL layer 112B is aligned with the end portion of the top surface of the partition 120, the end portion P of the first EL layer 112B is positioned inward from the end portion of the top surface of the partition 120 (referred to as an end portion R here) in some cases as illustrated in FIG. 4C or FIG. 4D. In the case where the first EL layer 112B is formed by an evaporation method, for example, evaporation can be performed such that a material travels from an evaporation source toward a substrate surface obliquely so as to allow the first EL layer 112B to be evaporated also in a region under the partition 120.

The partition 120 illustrated in FIG. 2B and the like can also be regarded as having a substantially trapezoidal shape in which the length of an upper base is longer than the length of a lower base in a cross-sectional view. The shape of the partition 120 is not limited thereto, and the partition 120 can have a variety of shapes as long as the first EL layer 112 can be disconnected. Note that the partition 120 can have a bilaterally symmetrical shape in a cross-sectional view. In the case where the partition 120 has a flat top surface, the shape of the partition 120 in a cross-sectional view is a polygonal shape with even-numbered corners. Other examples of the cross-sectional shape of the partition 120 will be described below. In this specification and the like, these cross-sectional shapes of the partition 120 are referred to as inverse tapered shapes.

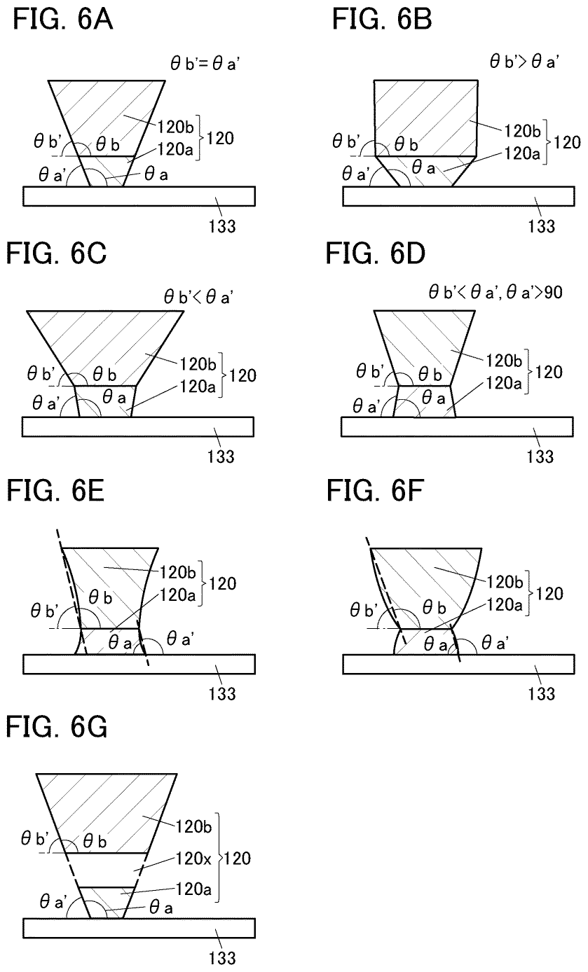

FIGS. 6A to 6G illustrate variations of the cross-sectional shape of the partition 120 having an inverse tapered shape. For the taper angles (θa and θb) and supplements of the taper angles (θa′ and θb′), the description for FIG. 4B can be referred to. FIG. 6A illustrates an example in which the angle θa′ and the angle θb′ are the same. The angle θa′ and the angle θb′ can be different from each other. The taper angle at the side surface of the layer 120b sometimes changes depending on an etching method and etching conditions used for the layer 120b. FIG. 6B illustrates an example in which the angle θb′ is larger than the angle θa′, and FIG. 6C illustrates an example in which the angle θb′ is smaller than the angle θa'. FIG. 6D illustrates an example in which the angle θb′ is smaller than the angle θa′ and the angle θa′ is greater than 90°.

FIG. 6E and FIG. 6F each illustrate an example in which the side surface of the partition 120 is curved. FIG. 6E illustrates the side surface having a concave surface, and FIG. 6F illustrates the side surface having a convex surface.

In the case where the side surface of the partition 120 is curved, it is difficult to uniquely define the taper angle θ. Thus, in this specification and the like, a straight line connecting the upper end and the lower end of the side surface of the layer 120a is drawn in a cross-sectional view, and the angle between the straight line and the bottom surface of the layer 120a is referred to as the taper angle θa, as illustrated in FIGS. 6E and 6F. Furthermore, a straight line connecting the upper end and the lower end of the side surface of the layer 120b is drawn in a cross-sectional view, and the angle between the straight line and the bottom surface of the layer 120b is referred to as the taper angle θb.

The partition 120 can have a stacked-layer structure of three or more layers. FIG. 6G illustrates an example in which the partition 120 includes the layer 120a, the layer 120b, and a region 120x between the layer 120a and the layer 120b. The region 120x is one or more layers positioned between the layer 120a and the layer 120b. A taper angle at a side surface of each layer included in the region 120x can be greater than 0° and less than 180°, and is preferably greater than 90° and less than 180°.

Although the side surface of the partition 120 is illustrated as having a corner portion in the above examples, the corner is rounded in some cases depending on a processing method of the partition 120. In particular, when the partition 120 is formed by an isotropic etching method such as wet etching, the partition tends to have rounded corners.

Although FIGS. 2B and 2C illustrate an example in which a plurality of light-emitting elements each include an EL layer, it is also possible to provide an EL layer to be shared by the plurality of light-emitting elements. For example, a stacked-layer structure of a first EL layer provided in each of a plurality of light-emitting elements and a second EL layer shared by the plurality of light-emitting elements can be used as an EL layer of the light-emitting elements. The second EL layer is referred to as a common layer in some cases.

FIG. 7A illustrates an example in which the EL layer of the light-emitting element 110R has a stacked-layer structure of the first EL layer 112R and the second EL layer 114 over the first EL layer 112R. The light-emitting element 110G includes the first EL layer 112G and the second EL layer 114 over the first EL layer 112G between the pixel electrode 111G and the upper electrode 115. The light-emitting element 110B includes the first EL layer 112B and the second EL layer 114 over the first EL layer 112B between the pixel electrode 111B and the upper electrode 115.

FIG. 7A illustrates a structure in which the upper electrode 115 is shared by the light-emitting elements 110R, 110G, and 110B, thereby forming a continuous conductive layer that covers the EL layers of the three light-emitting elements.

In the light-emitting element 110R, the second EL layer 114 preferably covers a side surface of the first EL layer 112R. In that case, a structure can be obtained in which the first EL layer 112R and the upper electrode 115 are not in contact with each other. In the case where the side surface of the first EL layer 112R is in contact with the upper electrode 115, leakage current might flow between the upper electrode 115 and a layer of the first EL layer 112R that has high conductivity. Such leakage current might cause a malfunction in the operation of the light-emitting element 110R. For example, a carrier-injection layer such as an electron-injection layer or a hole-injection layer has high conductivity in some cases. When the first EL layer 112R includes a hole-injection layer, in particular, it is preferable that the hole-injection layer not be in contact with the upper electrode 115. Furthermore, in the case where the first EL layer 112R has a tandem structure, it is preferable that a charge-generation layer, which has high conductivity, not be in contact with the upper electrode 115.

Likewise, in the light-emitting element 110G, the second EL layer 114 preferably covers a side surface of the first EL layer 112G. Moreover, in the light-emitting element 110B, the second EL layer 114 preferably covers a side surface of the first EL layer 112B.

The second EL layer 114 of each of the light-emitting elements 110R, 110G, and 110B can be formed using the same material in the same step. Although the second EL layer 114 and a film 114r over the partition 120 are separated between the three light-emitting elements in a region illustrated in FIG. 7A, the second EL layer 114 may be connected between different light-emitting elements in some regions of the display device 100.

FIG. 7B is an enlarged view of FIG. 7A, illustrating the light-emitting elements 110B and 110G, the partition 120 positioned therebetween, and the vicinity thereof.

The end portions of the first EL layers 112B and 112G are positioned over the insulating layer 133. On the light-emitting element 110B side of the partition 120, the second EL layer 114 covers the end portion of the first EL layer 112B, and the upper electrode 115 covers an end portion of the second EL layer 114 and is in contact with at least part of the top surface of the insulating layer 133 and at least part of the side surface of the partition 120. On the light-emitting element 110G side of the partition 120, the second EL layer 114 covers the end portion of the first EL layer 112G, and the upper electrode 115 covers an end portion of the second EL layer 114 and is in contact with at least part of the top surface of the insulating layer 133 and at least part of the side surface of the partition 120.

As illustrated in FIG. 7B, the films 112Gr and 112Br are provided over the partition 120. The film 114r covers the films 112Gr and 112Br and has a region in contact with the top surface of the partition 120. The upper electrode 115 covers the top surface of the second EL layer 114.

Although FIG. 7B illustrates an example in which the height of the partition 120 is larger than the width thereof, the actual cross-sectional width is larger than the actual height in some cases.

The film 112Br has a side surface that does not face the film 112Gr, and the side surface is continuous with the side surface of the partition 120 and is covered with the upper electrode 115. The film 112Gr had a side surface that does not face the film 112Br, and the side surface is continuous with the side surface of the partition 120 and is covered with the upper electrode 115.

The upper electrode 115 covers the side surface of the partition 120 and the top surface of the insulating layer 133. A sidewall of the partition 120 has a region in contact with the upper electrode 115. The top surface of the insulating layer 133 preferably has a region in contact with the upper electrode 115.

In FIG. 7B, an end portion Q of the second EL layer 114 is positioned closer to the side surface of the partition 120 than the end portion P of the first EL layer 112B is. FIG. 7B illustrates a state where the end portion P is aligned with the end portion of the top surface of the partition 120. In the case where the first EL layer 112B and the second EL layer 114 are formed by an evaporation method, the first EL layer 112B is deposited by evaporation of a material traveling in a direction perpendicular or substantially perpendicular to a substrate surface from an evaporation source, and the second EL layer 114 is deposited by evaporation of a material traveling to a region below the side surface of the partition 120 from the evaporation source. Here, “a material traveling in a direction perpendicular or substantially perpendicular to a substrate surface” means, for example, that the material travels in a direction at an angle, with respect to the substrate surface, greater than or equal to 75° and less than or equal to 105°, preferably greater than or equal to 80° and less than or equal to 100°, further preferably greater than or equal to 85° and less than or equal to 95°. In this manner, by controlling the direction in which a material travels from the evaporation source, the first EL layer 112B and the second EL layer 114 can be formed such that the end portion Q is positioned closer to the side surface of the partition 120 than the end portion P is.

The second EL layer 114 is sometimes provided to cover a side surface of the first EL layer 112 over the partition 120 as illustrated in FIG. 7C. In FIG. 7C, the second EL layer 114 covers part of the side surface of the layer 120b. In a region where the second EL layer 114 covers the side surface of the layer 120b, the upper electrode 115 cannot be in contact with the layer 120b; thus, the upper electrode 115 is preferably provided to be in contact with a region where the side surface of the partition 120 is not covered with the second EL layer 114, and the region not covered with the second EL layer 114 preferably has conductivity.

Although the above-described structures are each an example in which the partition 120 is provided over the insulating layer 133, the insulating layer 133 is not necessarily provided.

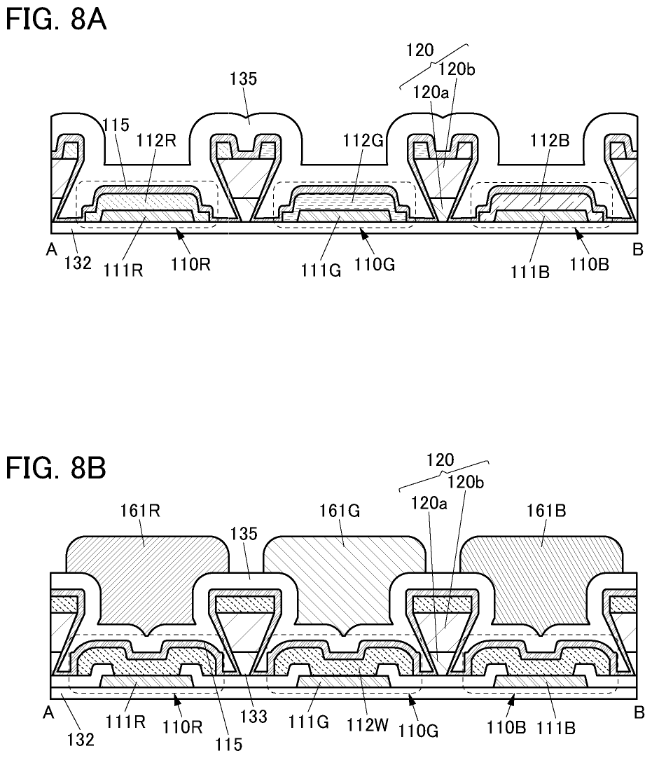

FIG. 8A illustrates an example in which the insulating layer 133 illustrated in FIG. 7A and the like is not provided. In FIG. 8A, the partition 120 is provided in contact with the top surface of the insulating layer 132 like the pixel electrode 111. The end portion of the first EL layer 112B and the end portion of the first EL layer 112G are each positioned over the insulating layer 132, and the upper electrode 115 is in contact with the insulating layer 132 and the partition 120.

FIG. 8B illustrates a structure example of a display device in which each of the light-emitting elements 110 emits white light and the light from the light-emitting elements 110 pass through color filters.

An EL layer 112W of each of the light-emitting elements 110 contains two or more light-emitting organic compounds that emit light of different colors. The EL layer 112W can include, for example, a plurality of light-emitting layers each containing a different light-emitting organic compound. A combination of light-emitting layers of the EL layer 112W can be such that white light can be obtained by light emission from the light-emitting layers, for example. Non-limiting examples of such a combination can include three kinds of light-emitting layers for red (R), green (G), and blue (B) and two kinds of light-emitting layers for blue and yellow (Y). For example, in the case of two colors, when emission colors of a first light-emitting layer and a second light-emitting layer are complementary colors, the light-emitting element can be configured to emit white light as a whole. To obtain white light emission by using three or more light-emitting layers, the light-emitting device can be configured to emit white light as a whole by combining emission colors of the three or more light-emitting layers.

A color filter 161R, a color filter 161G, and a color filter 161B are provided over the insulating layer 135.

The color filter 161R is provided to overlap with at least the pixel electrode 111R and has a function of transmitting red light and blocking (absorbing or reflecting) light of the other colors. The color filter 161G is provided to overlap with at least the pixel electrode 111G and has a function of transmitting green light and blocking light of the other colors. The color filter 161B is provided to overlap with at least the pixel electrode 111B and has a function of transmitting blue light and blocking light of the other colors. Each of the color filters 161 is preferably provided such that its end portion overlaps with the partition 120. When the two adjacent color filters 161 partly overlap with each other, white light can be prevented from leaking through a gap between the color filters 161, whereby a high-contrast display device can be obtained.

For each of the color filters 161, a resin material in which one or more of a metal, an alloy, a pigment, and a dye are dispersed can be used. The color filters 161 can be formed in desired positions by a photolithography method, an inkjet method, or the like.

Here, a structure can also be employed in which a light-emitting element that emits blue light or light having a shorter wavelength than blue light is used as the light-emitting element 110 and a wavelength conversion layer is provided instead of the color filter 161. In that case, each of the green pixel, the red pixel, and the blue pixel can include the light-emitting element 110 and a wavelength conversion layer that converts light emitted from the light-emitting element 110 into green light, red light, or blue light. The wavelength conversion layer can be formed using a resin or the like containing a wavelength conversion material, for example. In the case where a light-emitting element that emits blue light is used as the light-emitting element 110, a wavelength conversion layer is not necessarily provided in the blue pixel. As the wavelength conversion material, a fluorescent material, a quantum dot, or the like can be used.

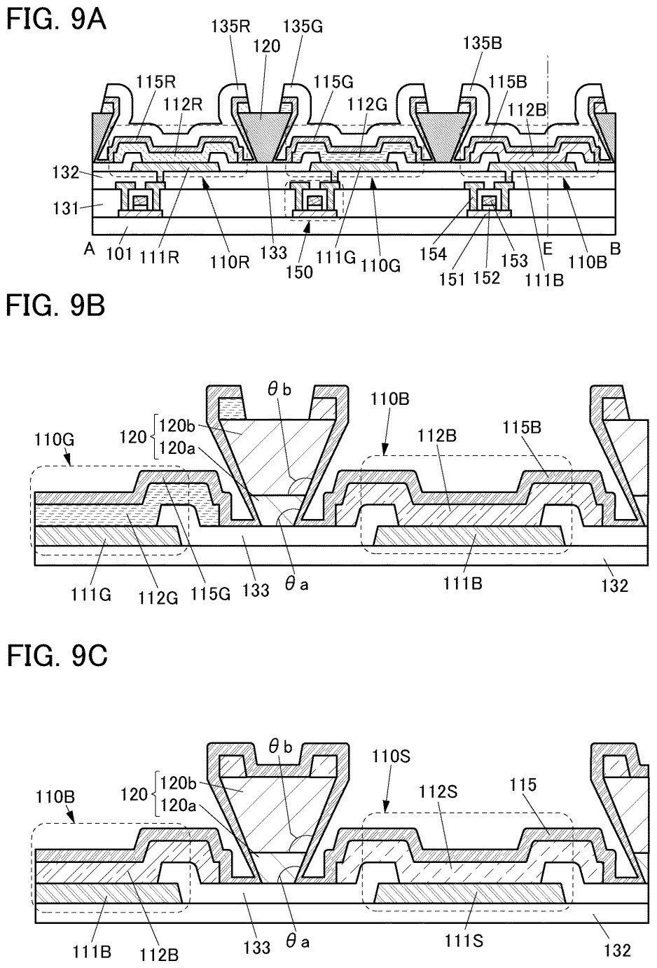

The display device illustrated in FIG. 9A is an example in which an upper electrode and protective layer over the upper electrode are each provided separately between the light-emitting element 110R, the light-emitting element 110G, and the light-emitting element 110B. In the display device illustrated in FIG. 9A, the upper electrodes are not directly connected to each other between the light-emitting elements 110. FIG. 9B illustrates an example of an enlarged view of FIG. 9A that illustrates the light-emitting elements 110B and 110G, the partition 120 positioned therebetween, and the vicinity thereof. In FIG. 9B, the dimension ratios between some components, the aspect ratios of some components, and the like are sometimes different from those in FIG. 9A.

The light-emitting element 110R includes an upper electrode 115R over the first EL layer 112R, and a protective layer 135R is provided over the upper electrode 115R. Likewise, the light-emitting element 110G includes an upper electrode 115G over the first EL layer 112G, and a protective layer 135G is provided over the upper electrode 115G. Moreover, the light-emitting element 110B includes an upper electrode 115B over the first EL layer 112B, and a protective layer 135B is provided over the upper electrode 115B.

End portions of the upper electrode 115R and the protective layer 135R are each positioned over the partition 120. Processing into the upper electrode 115R, processing into the protective layer 135R, and processing into the first EL layer 112R are performed using the same mask, whereby the end portions of the upper electrode 115R, the protective layer 135R, and the first EL layer 112R are substantially aligned with one another over the partition 120 as illustrated in FIG. 9A and the like.

End portions of the upper electrode 115G and the protective layer 135G are each positioned over the partition 120, and the end portions of the upper electrode 115G, the protective layer 135G, and the first EL layer 112G are substantially aligned with one another over the partition 120 as illustrated in FIG. 9A and the like.

End portions of the upper electrode 115B and the protective layer 135B are each positioned over the partition 120, and the end portions of the upper electrode 115B, the protective layer 135B, and the first EL layer 112B are substantially aligned with one another over the partition 120 as illustrated in FIG. 9A and the like.

The material described as that for the upper electrode 115 can be suitably used for the upper electrodes 115R, 115G, and 115B. The material described as that for the protective layer 135 can be suitably used for the protective layers 135R, 135G, and 135B.

In the above example, the display device 100 includes the light-emitting element 110 of three colors (the light-emitting element 110R, the light-emitting element 110G, and the light-emitting element 110B); however, the display device 100 may include another element. For example, in addition to red, green, and blue light-emitting elements, a white light-emitting element can be included.

An EL layer of the white light-emitting element can include two or more light-emitting layers. When two light-emitting layers are combined so as to emit light of complementary colors, for example, white light emission can be obtained. A structure including three or more light-emitting layers may also be employed.

Using the white light-emitting element in addition to the red, green, and blue light-emitting elements can achieve higher contrast and higher reliability.

The display device 100 can include a light-receiving element in addition to the light-emitting elements.

The light-receiving element can function as a photoelectric conversion element and output an electric signal corresponding to the amount of incident light. Thus, an image sensor can be incorporated in the display device 100. FIG. 9C illustrates an example in which the display device 100 includes a light-receiving element 110S placed adjacent to the light-emitting element 110. The light-receiving element 110S includes a pixel electrode 111S, a sensor layer 112S, and the upper electrode 115. The protective layer 135 can be provided to cover the light-receiving element 110S as in FIG. 2B and the like.

The sensor layer 112S and the first EL layer 112R or the like preferably include a common organic layer. For example, the sensor layer 112S can have a structure obtained by replacing the light-emitting layer of the first EL layer 112R with a light-receiving layer (also referred to as an active layer or a photoelectric conversion layer).

The light-receiving layer included in the sensor layer 112S can have a stacked-layer structure in which a p-type semiconductor and an n-type semiconductor are stacked to form a PN junction; or a stacked-layer structure in which a p-type semiconductor, an i-type semiconductor, and an n-type semiconductor are stacked to form a PIN junction, for example.

As the semiconductor used for the light-receiving layer, an inorganic semiconductor such as silicon or an organic semiconductor containing an organic compound can be used. It is particularly preferable to use an organic semiconductor material because in that case, the first EL layer 112R and the light-receiving layer are easily formed by the same vacuum evaporation method, and thus the same manufacturing apparatus can be used.

When an organic semiconductor material is used for the light-receiving layer, an electron-accepting organic semiconductor material such as fullerene (e.g., C₆₀ or C₇₀) or its derivative can be used as an n-type semiconductor material. As a p-type semiconductor material, an electron-donating organic semiconductor material such as copper(II) phthalocyanine (CuPc) or tetraphenyldibenzoperiflanthene (DBP) can be used. The light-receiving layer may have a stacked-layer structure including an electron-accepting semiconductor material and an electron-donating semiconductor material (a p-n structure), or a stacked-layer structure in which a bulk heterostructure layer formed by co-evaporation of an electron-accepting semiconductor material and an electron-donating semiconductor material is provided between the materials of the p-n structure (a p-i-n structure). A layer functioning as a hole blocking layer or a layer functioning as an electron blocking layer may be provided around (above or below) the p-n structure or the p-i-n structure, in order to inhibit dark current caused when light is not applied.

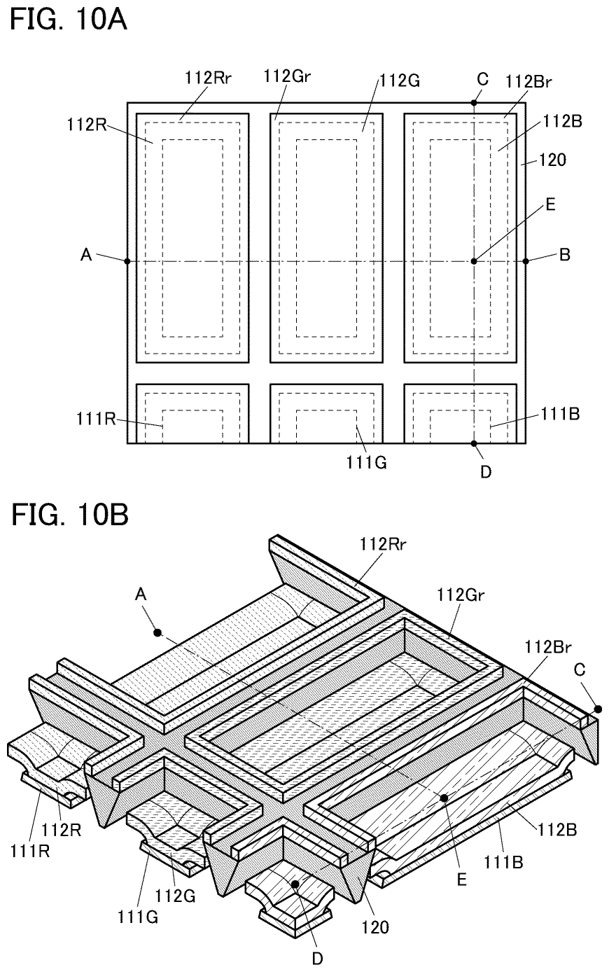

A schematic top view in FIG. 10A is different from that in FIG. 2A in the top-view shapes of the films 112r (films 112Rr, 112Gr, and 112Br). FIG. 10B is a schematic perspective view corresponding to the schematic top view in FIG. 10A.

The films 112r of the light-emitting elements 110 arranged in the longitudinal direction are connected to each other in FIG. 2A, whereas the films 112r of the light-emitting elements 110 are provided separately to surround the respective light-emitting elements 110 in FIG. 10A. In the stripe arrangement illustrated in FIG. 1A, the films 112r can be arranged to be connected in the longitudinal direction as illustrated in FIG. 2A, or the films 112r can be separated for the light-emitting elements. In the S-stripe arrangement, the delta arrangement, the zigzag arrangement, and the like, the films 112r are separately provided for the light-emitting elements 110, for example.

The above is the description of the structure examples.

### Manufacturing Method Example 1

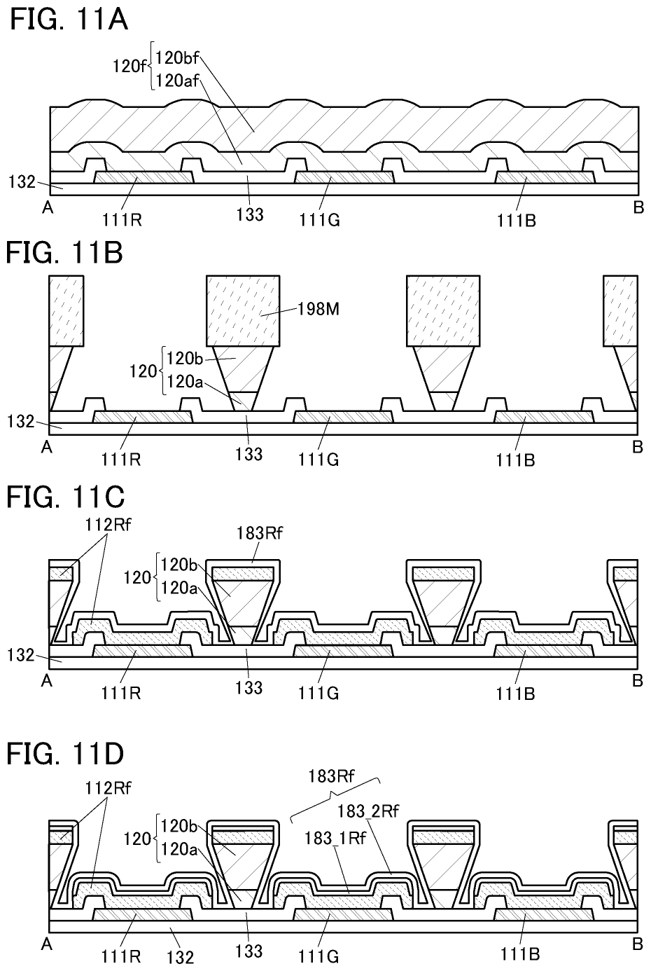

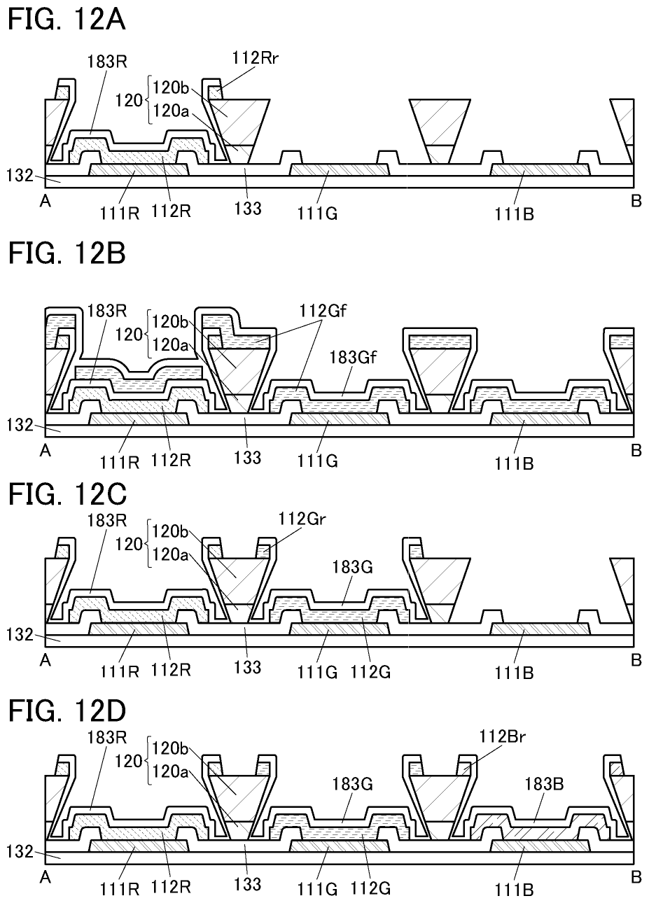

An example of a method for manufacturing the display device of one embodiment of the present invention will be described below with reference to the drawings. Here, the description is made with the use of the display device 100 described above in Structure example. FIGS. 11A to 11D and FIGS. 12A to 12D are schematic cross-sectional views of steps in the method for manufacturing the display device described as an example below.

Note that thin films included in the display device (e.g., insulating films, semiconductor films, or conductive films) can be formed by any of a sputtering method, a chemical vapor deposition (CVD) method, a vacuum evaporation method, a pulsed laser deposition (PLD) method, an atomic layer deposition (ALD) method, and the like.

Alternatively, thin films included in the display device (e.g., insulating films, semiconductor films, and conductive films) can be formed by a method such as spin coating, dipping, spray coating, ink-jetting, dispensing, screen printing, or offset printing or with a doctor knife, a slit coater, a roll coater, a curtain coater, or a knife coater.

Examples of the sputtering method include an RF sputtering method using a high-frequency power source for a sputtering power source, a DC sputtering method using a DC power source, and a pulsed DC sputtering method in which voltage applied to an electrode is changed in a pulsed manner. For film formation using an insulating target, an RF sputtering method is preferably used. A DC sputtering method is used mainly in the case of film formation using a conductive target. In a DC sputtering method, not only formation of a conductive film but also formation of an insulating film is possible by reactive sputtering using a pulsed DC sputtering method. The pulsed DC sputtering method can be specifically used to form a layer of a compound such as an oxide, a nitride, or a carbide by a reactive sputtering method.

Note that CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object. A thermal CVD method yields a film with few defects because of no plasma damage during film formation.

As an ALD method, a thermal ALD method, in which a precursor and a reactant react with each other only by a thermal energy, a PEALD method, in which a reactant excited by plasma is used, or the like can be used.

Unlike a sputtering method, a CVD method and an ALD method are less likely to be influenced by the shape of an object to be processed and thus enable favorable step coverage. In particular, an ALD method allows excellent step coverage and excellent thickness uniformity and can be suitably used to cover a surface of an opening portion with a high aspect ratio, for example. Note that an ALD method has a relatively low deposition rate; hence, in some cases, an ALD method is preferably combined with another film formation method with a high deposition rate, such as a CVD method.

By a CVD method, a film with a desired composition can be formed by adjusting the flow rate ratio of the source gases. For example, a CVD method enables formation of a film whose composition is gradually changed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer or pressure adjustment is not required. Hence, the productivity of the semiconductor device can be improved in some cases.

An ALD method, in which a plurality of different kinds of precursors are introduced at a time, enables formation of a film with a desired composition. In the case where a plurality of different kinds of precursors are introduced, the number of cycles for each precursor is controlled, whereby a film with a desired composition can be formed. Furthermore, a film whose composition is continuously changed can be formed as in the CVD method.

The thin films constituting the display device can be processed using a photolithography method or the like. Besides, a nanoimprinting method, a sandblasting method, a lift-off method, or the like may be employed to process the thin films. Alternatively, island-shaped thin films may be directly formed by a film formation method using a shielding mask such as a metal mask. Further alternatively, a directed self-assembly (DSA) method may be used.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Instead of the light for exposure, an electron beam can be used. EUV, X-rays, or an electron beam is preferably used to enable extremely minute processing. Note that a photomask is not needed when exposure is performed by scanning with a beam such as the above-described light or an electron beam.

For etching of thin films, a dry etching method, a wet etching method, a sandblast method, or the like can be used. In the dry etching method, isotropic etching or anisotropic etching can be performed when the conditions are controlled. In the wet etching method, isotropic etching can be performed.

The method for manufacturing the display device will be described below. The transistor 150, the substrate 101, the insulating layer 131, and conductive layers embedded in the insulating layer 132 are not illustrated in the drawings used for the description.

First, the substrate 101 is prepared, and the transistor 150, the insulating layer 131, the insulating layer 132, and the like are formed. Next, a conductive film is formed over the insulating layer 132 and an unnecessary portion of the conductive film is removed by etching, so that the pixel electrode 111R, the pixel electrode 111G, and the pixel electrode 111B are formed.

As the substrate 101, a substrate that has heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

In the case where a conductive film that has a property of reflecting visible light is used for the pixel electrodes 111, it is preferable to use a material having as high a reflectivity as possible in the entire wavelength range of visible light (e.g., silver or aluminum). This can increase both light extraction efficiency and color reproducibility of the light-emitting elements.

Subsequently, the insulating layer 133 is formed to cover an end portion of each pixel electrode 111. An organic insulating film or an inorganic insulating film can be used for the insulating layer 133. The end portions of the insulating layer 133 are preferably tapered to improve step coverage with an EL film formed later. The insulating layer 133 is formed by forming an insulating film (referred to as a film 133f) over the pixel electrode 111 and then forming an opening in the film 133f. A portion where the pixel electrode 111 is exposed through the opening of the film 133f functions as a light-emitting region. In the formation of the insulating layer 133, the opening of the film 133f may be formed before the partition 120 is formed or after the partition 120 is formed.

Next, a film 120af and a film 120bf are formed in this order (see FIG. 11A). The film 120af and the film 120bf are films to be the layer 120a and the layer 120b, respectively. The film 120f is preferably formed using a material that exhibits high etching rate selectivity with respect to the pixel electrodes 111. In the case where the film 120f is formed using a material that exhibits low etching rate selectivity with respect to the pixel electrodes 111 and the opening of the film 133f is formed before the partition 120 is formed, the film thickness loss might occur in parts of the pixel electrodes 111 that are not covered with the insulating layer 133 at the time of the etching of the film 120f. To inhibit the film thickness loss of the pixel electrodes 111, the opening of the film 133f is preferably formed after the formation of the partition 120 using a mask different from that used in the formation of the partition 120. Alternatively, a film functioning as an etching stopper may be formed before the formation of the film 120f, and the film positioned over the pixel electrode 111 may be removed after the etching of the film 120f.

Then, a mask 198M is formed over the film 120bf. A resist mask can be used as the mask 198M, for example. Next, portions of the films 120bf and 120af that are not covered with the mask 198M are removed by etching to form the layers 120b and 120a (see FIG. 11B).

It is preferable to select a material used for the film 120bf and the characteristics of the film 120bf so that the film 120bf has high adhesion to the mask 198M provided thereover.

Etching for making a side surface inversely tapered can be performed by an isotropic etching method. For example, a wet etching method or an isotropic dry etching method can be used. A wet etching method is particularly preferable because it excels in isotropic etching and enables favorable processability even when a film to be etched has a small thickness. The film to be etched is processed such that a lower portion of the film is etched faster than an upper portion thereof, whereby a film having its side surface inversely tapered can be formed.

Described here is the case of making a side surface of the film 120bf inversely tapered. The film 120bf is preferably processed by isotropic etching.

Low adhesion between the film 120bf and the mask 198M might cause an increase in the etching rate of the film 120bf, so that an upper portion of the film 120af might be etched together with the film 120bf at a high etching rate. Thus, the adhesion between the film 120bf and the mask 198M is preferably high. For example, the adhesion between the film 120bf and the mask 198M is preferably higher than the adhesion between the film 120af and the insulating layer 133. Furthermore, the adhesion between the film 120af and the film 120bf is preferably higher than the adhesion between the film 120af and the insulating layer 133.

The etching of the film 120af can be performed by either an isotropic method or an anisotropy method. In the case where the film 120bf is sufficiently thicker than the film 120af, in particular, the degree of freedom of the angle of the side surface of the film 120af is increased; thus, the EL layer can be disconnected by the partition 120 without any problems even when an anisotropic etching method is used.

The etching of the film 120af and the etching of the film 120bf can be performed under different etching conditions or under the same etching conditions. In the case of using different etching conditions, different etchants may be used for the film 120af and the film 120bf. In the case of performing wet etching, for example, a solution containing acid may be used, or an alkaline developer containing tetramethyl ammonium hydroxide (abbreviation: TMAH) or the like may be used. When an oxide containing indium is used for the film 120af and the film 120bf, for example, wet etching using a solution containing acid can be employed.

The adhesion can be examined by a separation test, for example.

In the separation test, force required for peeling can be measured in the following manner, for example. A tape is attached onto a layer including a layer to be peeled and force required for peeling the tape and the layer is measured.

For the separation test, an adhesive tape/adhesive sheet testing method based on standard number JIS Z0237 of Japanese Industrial Standards (JIS) can be employed.

Next, the mask 198M is removed. Subsequently, a film 112Rf that is to be the first EL layer 112R is formed over the pixel electrodes 111R, 111G, and 111B and the partition 120. At this time, the film 112Rf is disconnected by the partition 120 and is formed over each of the pixel electrodes 111R, 111G, and 111B and the partition 120.

The film 112Rf includes a first portion over the pixel electrode 111R and a second portion over the partition 120 that surrounds the pixel electrode 111R. The first portion and the second portion are separated from each other. The first portion can function as the first EL layer 112R.

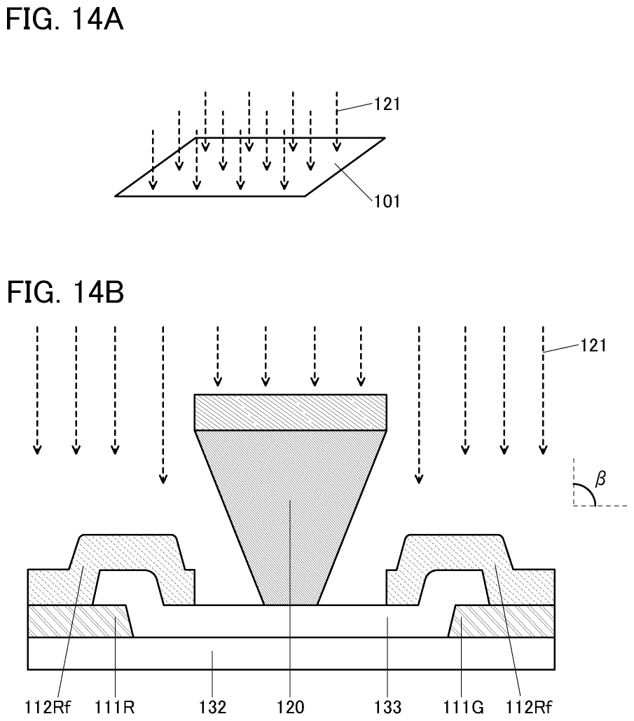

A method for forming the film 112Rf is described with reference to FIGS. 14A and 14B. The film 112Rf is preferably formed by a highly anisotropic film formation method. That is, as illustrated in FIG. 14A, the film formation is performed such that an angle β formed by the substrate surface and a traveling direction of a film formation material 121 is substantially perpendicular to the top surface of the substrate 101. In this manner, disconnection can be caused by the partition 120 as illustrated in FIG. 14B. In that case, a sufficient space for entry of the upper electrode 115 is preferably provided between the film 112Rf and the partition 120. The angle β formed by the substrate surface and the traveling direction of the film formation material 121 includes, besides components that are approximately perpendicular, components where the angle β is smaller than or larger than the approximately perpendicular angle, in some cases. The range of variation in the angle β may change depending on the positional relationship between the evaporation source and the substrate and a change over time in the relative positional relationship between the evaporation source and the substrate, for example.

The film 112Rf can be formed by, for example, a vacuum evaporation method.

It is preferable that a light-emitting layer not be exposed as the uppermost layer of the film 112Rf. For example, the film 112Rf has a stacked-layer structure of a hole-injection layer, a hole-transport layer, a light-emitting layer, and an electron-transport layer. In that case, the light-emitting layer is covered with the electron-transport layer, so that damage to the light-emitting layer can be reduced in subsequent film formation steps. Thus, the characteristics and reliability of the light-emitting element 110R can be improved.

Next, a film 183Rf is formed over the film 112Rf (FIG. 11C). The film 183Rf has a function of protecting the film 112Rf.

Owing to the film 183Rf, diffusion of oxygen or moisture into the film 112Rf can be inhibited and deterioration of the film 112Rf can thus be inhibited even when the film 112Rf is exposed to an air atmosphere.

For the film 183Rf, one or more of organic materials and inorganic materials (e.g., a metal, an alloy, a metal compound, a semiconductor, and an inorganic insulating material) can be used, for example. Alternatively, a stack containing two or more materials selected from the above can be used.

For the film 183Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material, for example. In particular, the use of a low-melting-point material such as aluminum or silver can decrease the temperature in the manufacturing process, which not only increases productivity but also reduces damage to the film 112Rf due to overheating.

In that case, deterioration of the film 112Rf due to light irradiation in the manufacturing process can be inhibited. In particular, the use of a metal material capable of shielding ultraviolet rays can inhibit the film 112Rf from being irradiated with ultraviolet rays in light exposure in a photolithography process.

The film 183Rf can be formed using, for example, a metal compound such as an indium gallium zinc oxide (In—Ga—Zn oxide), indium oxide, an indium zinc oxide (In—Zn oxide), an indium tin oxide (In—Sn oxide), an indium titanium oxide (In—Ti oxide), an indium tin zinc oxide (In—Sn—Zn oxide), an indium titanium zinc oxide (In—Ti—Zn oxide), an indium gallium tin zinc oxide (In—Ga—Sn—Zn oxide), or an indium tin oxide containing silicon (In—Sn—Si oxide).

In the metal compound, in place of gallium, an element M1 (M1 is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The film 183Rf is preferably formed using a semiconductor material such as silicon or germanium for excellent compatibility with a semiconductor manufacturing process. Alternatively, a compound containing the above semiconductor material can be used.

For example, any of a variety of inorganic insulating films can be used as the film 183Rf. An oxide insulating film, a nitride insulating film, or the like can be used, for example.

Alternatively, an organic material can be used for the film 183Rf.

Specifically, the film 183Rf can be suitably formed using a metal complex such as tris(8-quinolinolato)aluminum(III) (abbreviation: Alq₃), bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ).

The film 183Rf is preferably formed using a material different from that for the partition 120. Specifically, for example, the materials for the film 183Rf and the partition 120 are preferably selected so as not to reduce the thickness of the partition 120 in etching for removing the film 183Rf in a later step.

As the film 183Rf, a film that can be removed by a wet etching method or a dry etching method is preferably used. The use of a wet etching method can reduce damage to the film 112Rf, for example. The film 183Rf can have a single-layer structure or a stacked-layer structure of two or more layers. In the case of a stacked-layer structure, a lower layer that is closer to the film 112Rf is etched by wet etching, in which case damage to the film 112Rf can be reduced.

The film 183Rf can be formed by a CVD method, a sputtering method, a vacuum evaporation method, an ALD method, or the like. Since an ALD method offers excellent coverage, the sidewall of the partition 120 having an inverse tapered shape can be favorably covered. A CVD method and a sputtering method have high deposition rates and enable easy film formation on a large substrate, resulting in high productivity.

In the case where the film 183Rf has a stacked-layer structure, the stacked films can be formed by different film formation methods.

As illustrated in FIG. 11D, the film 183Rf can have a stacked-layer structure of a film 183_1Rf formed by a highly anisotropic method and a film 183_2Rf formed by a method that offers higher coverage on the sidewall of the partition 120 or the like than the coverage with the film 183_1Rf. The film 183_1Rf can be formed by a film formation method similar to that for the film 112Rf, for example.

After the formation of the film 112Rf, the film 183_1Rf is preferably formed without exposure to an air atmosphere. With the film 183_1Rf, the adhesion of the film 183_2Rf to be formed later is improved in some cases.

The film 183_1Rf is preferably etched by a method that causes less damage to the film 112Rf than a method for the film 183_2Rf formed later. For example, the etching is preferably performed by a wet etching method. It is also preferable that the film 112Rf not be changed in quality due to a chemical solution used for wet etching of the film 183_1Rf. For example, a water-soluble material can be used for the film 183_1Rf.

The film 183_1Rf can have a single-layer structure or a stacked-layer structure of two or more layers. The film 183_2Rf can have a single-layer structure or a stacked-layer structure of two or more layers.

Any of the above-described materials that can be used for the film 183Rf can be used for the film 183_1Rf and the film 183_2Rf. For the film 183_1Rf and the film 183_2Rf, a water-soluble material can be used. In other words, a material that will be dissolved in a solvent containing water can be used. Specifically, a material having higher water solubility than the film 112Rf can be used. For example, a material that will be dissolved in an aqueous solution containing hydrofluoric acid (HF) can be used. A material that will be dissolved in an aqueous solution containing tetramethyl ammonium hydroxide (abbreviation: TMAH) can be used.

Among the above organic materials, tris(8-quinolinolato)aluminum(III) (abbreviation: Alq₃) can be particularly suitably used for the film 183_1Rf, in which case the film 183_1Rf can be easily removed due to its solubility and can increase the adhesion with the film 183_2Rf when provided between the film 112Rf and the film 183_2Rf.

For the film 183_2Rf, any of the above-described materials that can be used for the film 183Rf can be used. For example, one or more of a metal film, an alloy film, a metal compound film, a semiconductor film, an inorganic insulating film, and the like can be used. Alternatively, a stack including two or more layers selected from these can be used.

Next, part of the film 183Rf is removed using a mask such as a resist mask, whereby a layer 183R is formed.

The layer 183R can function as a hard mask. The layer 183R is sometimes referred to as a mask layer, a sacrificial layer, or the like.

For the processing of the film 183Rf, a wet etching method or a dry etching method can be used. In the case of using a wet etching method, damage to the film 112Rf in the processing of the film 183Rf can be reduced as compared with the case of using a dry etching method. In the case of using a dry etching method in the processing of the film 183Rf, deterioration of the film 112Rf can be inhibited by not using a gas containing oxygen as the etching gas.

After that, the mask is removed. Subsequently, part of the film 112Rf is removed using the layer 183R as a mask, whereby the first EL layer 112R is formed over the pixel electrode 111R (see FIG. 12A).

In consideration of misalignment in patterning, the mask used for forming the layer 183R is preferably formed to overlap with part of the top surface of the partition 120. Thus, the film 112Rr and the layer 183R remain also over the partition 120.

The film 112Rf is preferably processed by anisotropic etching. Anisotropic dry etching is particularly preferable. Alternatively, wet etching may be used.

In the case of using a dry etching method, deterioration of the film 112Rf can be inhibited by not using a gas containing oxygen as the etching gas.

A gas containing oxygen may be used as the etching gas. When the etching gas contains oxygen, the etching rate can be increased. Thus, the etching can be performed under a low-power condition while an adequately high etching rate is maintained. Accordingly, damage to the part of the film 112Rf can be inhibited. Furthermore, a defect such as attachment of a reaction product generated during the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one of the above is preferably used as the etching gas. Alternatively, an oxygen gas may be used as the etching gas.

Next, a film 112Gf to be the first EL layer 112G is formed over the layer 183R, the pixel electrode 111G, the pixel electrode 111B, and the partition 120. Subsequently, a film 183Gf is formed (see FIG. 12B). The film 183Gf has a function of protecting the film 112Gf. At this time, the film 112Gf is disconnected by the partition 120 and is formed over the pixel electrode 111G, the pixel electrode 111B, the partition 120, and the like. For the method for forming the film 112Gf, the method for forming the film 112Rf can be referred to.

Next, a layer 183G is formed using a mask such as a resist mask, the resist mask is removed, and then the first EL layer 112G is formed using the layer 183G as a mask (see FIG. 12C). Here, the layer 183G is provided to cover the film 112Gr remaining over the partition 120 in some cases.

Then, the first EL layer 112B and a layer 183B are formed over the pixel electrode 111B with reference to the methods for forming the first EL layer 112R, the layer 183R, and the like (see FIG. 12D). The layer 183B can function as a hard mask when the first EL layer 112B is etched.

Next, the layers 183R, 183G, and 183B are removed. The layers 183 are preferably removed by wet etching. In the case of using a wet etching method, damage to the first EL layer 112 can be reduced as compared with the case of using a dry etching method. The wet etching is preferably performed using an aqueous solution so that the first EL layer 112 is not dissolved; for example, an alkaline solution or an acidic solution can be used.

Next, the upper electrode 115 is formed. Specifically, the upper electrode 115 is formed over the first EL layer 112B, the first EL layer 112G, the first EL layer 112R, and the partition 120. The upper electrode 115 can be formed by one or more of a vacuum evaporation method, a sputtering method, a CVD method, and an ALD method. Furthermore, the upper electrode 115 preferably includes a portion in contact with the top surface of the insulating layer 133.

The upper electrode 115 is preferably formed by a less anisotropic film formation method than that for the EL layer 112. It is preferable to employ a film formation method in which the traveling direction of the film formation material of the upper electrode 115 includes not only a component perpendicular to the top surface of the substrate but also a component oblique thereto. A low-anisotropy film formation method can be obtained by, for example, decreasing the distance between an evaporation source (or a sputtering target) and the substrate, using a plurality of evaporation sources (or sputtering targets), or increasing the area of an evaporation source (or a sputtering target).

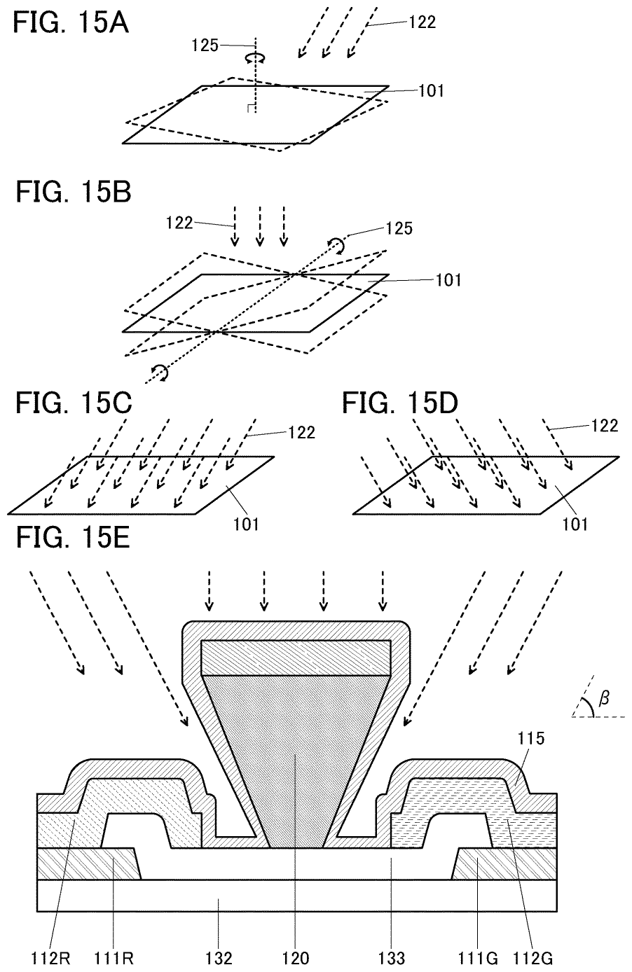

Alternatively, it is possible to use a film formation apparatus including a mechanism by which a film formation material 122 travels in a direction oblique to the top surface of the substrate 101 and the substrate 101 rotates on a rotation axis 125 as illustrated in FIG. 15A. At this time, the angle β formed by the substrate surface and the traveling direction of the film formation material is less than 90°. Although FIG. 15A illustrates an example in which the rotation axis 125 passes through the center of the substrate 101, the rotation axis 125 may pass through any point on the substrate 101 or may be positioned outside the substrate 101. The rotation axis 125 is not necessarily perpendicular to the surface of the substrate 101.

Alternatively, it is possible to use a film formation apparatus including a mechanism by which the substrate 101 rotates (or swings) on the rotation axis 125 that is parallel to the substrate surface as illustrated in FIG. 15B. In that case, the film formation material 122 can travel in a direction perpendicular to the rotation axis 125.

With the use of a film formation apparatus including a mechanism like those illustrated in FIGS. 15A and 15B, the film formation process for the upper electrode 115 can include a period in which the film formation material 122 travels toward the surface of the substrate 101 in an oblique direction as illustrated in FIG. 15C and a period in which the film formation material 122 travels in the symmetrically opposite oblique direction as illustrated in FIG. 15D. Thus, the upper electrode 115 can also be formed on the side surface of the partition 120 having an inverse tapered shape, as illustrated in FIG. 15E.

Although the cases where the substrate 101 moves are described above as examples, the evaporation source may move, or both the substrate 101 and the evaporation source may move.

In the formation of the upper electrode 115, the angle β formed by the substrate surface and the traveling direction of the film formation material is smaller than the angle formed by the substrate surface and the traveling direction of the film formation material of each of the first EL layer 112R, the first EL layer 112G, and the first EL layer 112B, for example.

Next, the protective layer 135 is formed to cover the upper electrode 115, whereby the display device illustrated in FIG. 2B and the like can be manufactured.

The protective layer 135 is preferably formed by a film formation method that provides high step coverage, and is preferably formed by a CVD method or an ALD method. In particular, an ALD method is preferable because of less film formation damage to a layer on which a film is formed.

For example, an aluminum oxide film can be formed as the protective layer 135 by an ALD method. In that case, as a precursor containing aluminum, trimethylaluminum, triethylaluminum, triisobutylaluminum, dimethylaluminum hydride, tris(dimethylamino)aluminum, tris(diethylamino)aluminum, aluminum trichloride, or the like is preferably used. As an oxidizer, any one or two or more of ozone (O₃), oxygen (O₂), water (H₂O), nitrogen dioxide (NO₂), dinitrogen monoxide (N₂O), and hydrogen peroxide (H₂O₂) can be used, for example.

The protective layer 135 may have a stacked-layer structure of a film formed by an ALD method and a film formed by a film formation method other than an ALD method (e.g., a CVD method or a sputtering method). An ALD method provides extremely high step coverage but has a lower deposition rate than other film formation methods; the time taken for the film formation step for the protective layer 135 can be shortened by first forming a film with extremely few defects by an ALD method and then forming a thick insulating film by a CVD method or the like.

### Manufacturing Method Example 2

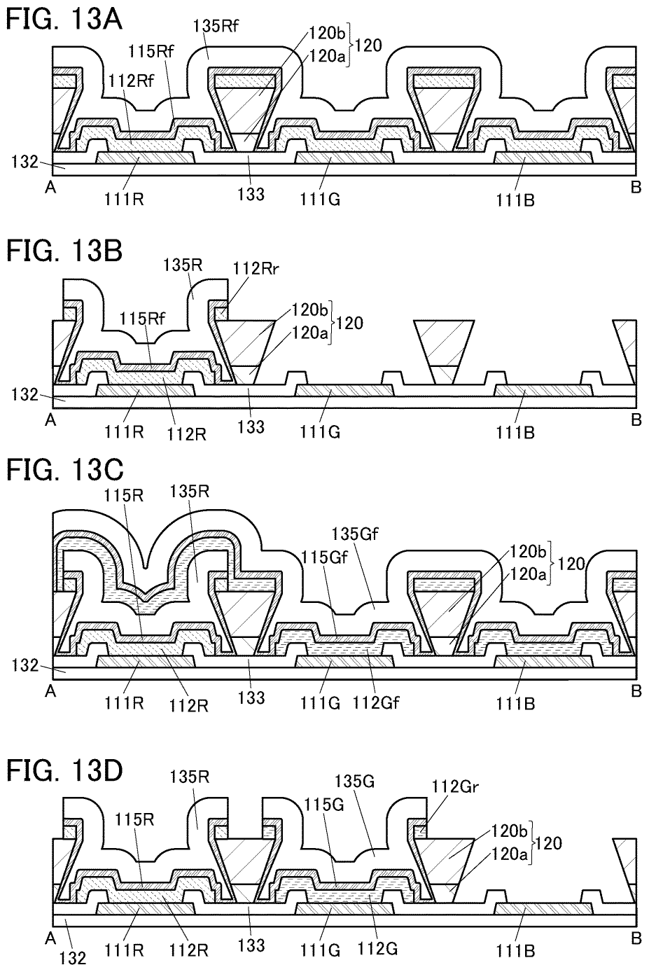

A method for manufacturing the display device illustrated in FIG. 9A will be described with reference to FIGS. 13A to 13D and the like.

First, with reference to FIGS. 11A to 11C, the film 112Rf is formed over the pixel electrodes 111R, 111G, and 111B and the partition 120 (note that the film 183Rf is not formed). After that, a conductive film 115Rf and a protective film 135Rf are formed in this order (see FIG. 13A).

Subsequently, the protective film 135Rf, the conductive film 115Rf, and the film 112Rf are processed in this order using a mask such as a resist mask. In this manner, the first EL layer 112R is formed over the pixel electrode 111R; the upper electrode 115R is formed to cover the first EL layer 112R, the insulating layer 133, and the sidewall of the partition 120; and the protective layer 135R is formed over the upper electrode 115R (see FIG. 13B). In the example illustrated in FIG. 13B, the film 112Rr remains over the partition 120, and end portions of the film 112Rr, the upper electrode 115R, and the protective layer 135R are positioned over the partition 120.

Next, the film 112Gf, a conductive film 115Gf, and a protective film 135Gf are formed over the pixel electrodes 111G and 111B, the protective layer 135R, and the partition 120 (see FIG. 13C). After that, the protective film 135Gf, the conductive film 115Gf, and the film 112Gf are processed in this order using a mask. In this manner, the first EL layer 112G is formed over the pixel electrode 111G; the upper electrode 115G is formed to cover the first EL layer 112G, the insulating layer 133, and the sidewall of the partition 120; and the protective layer 135G is formed over the upper electrode 115G (see FIG. 13D).

Next, the first EL layer 112B, the upper electrode 115B, and the protective layer 135B are formed with reference to the methods for forming the first EL layer 112R, the upper electrode 115R, the protective layer 135R, and the like, whereby the display device illustrated in FIG. 9A can be completed.

### Example of Film Formation Apparatus

Described below are examples of film formation apparatuses capable of forming an EL layer, an upper electrode, and a protective layer successively without exposure to the air. The film formation apparatuses described below as examples can be used as manufacturing apparatuses for a display device. The film formation apparatuses described below as examples can be used to form the first EL layer 112, the second EL layer 114, the upper electrode 115, and the protective layer 135 for each of the light-emitting elements 110.

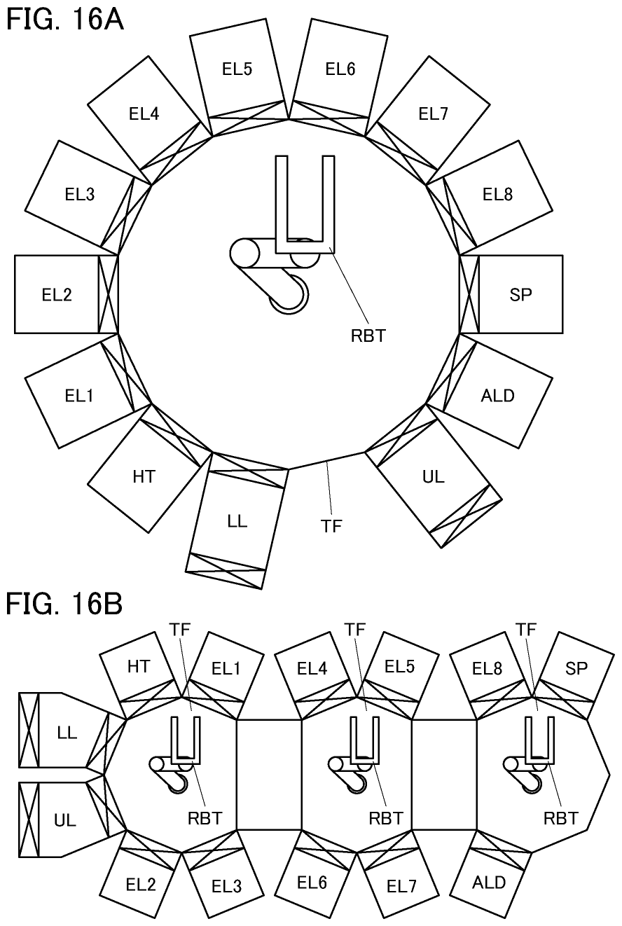

FIG. 16A is a schematic diagram of a film formation apparatus. The film formation apparatus includes a loading chamber LL, an unloading chamber UL, a treatment chamber HT, film formation chambers EL1 to EL8, a film formation chamber ALD, and a film formation chamber SP around a transfer chamber TF. The transfer chamber TF includes a transfer robot RBT, and the transfer robot RBT can load and unload the substrate 101 into and from each chamber.

The transfer chamber TF and each chamber are connected to a vacuum pump and are kept under reduced pressure. A gate valve is provided between the transfer chamber TF and each chamber to separately control the atmosphere, e.g., the pressure or the temperature, of each chamber.

The loading chamber LL is a chamber for loading the substrate 101, and the unloading chamber UL is a chamber for unloading the substrate 101. The loading chamber LL and the unloading chamber UL are each provided with a gate valve that connects to the outside.

In the treatment chamber HT, treatment for heating the substrate 101 can be performed. The treatment chamber HT includes a baking apparatus. For example, a hot plate baking apparatus or a baking apparatus including a resistive heater or an infrared lamp may be used.

In the film formation chambers EL1 to EL8, films included in the first EL layer 112 and the second EL layer 114 can be formed. The film formation chambers EL1 to EL8 each include a vacuum evaporation apparatus or a sputtering apparatus, for example.

For example, the film formation chamber EL1 includes an apparatus for forming a hole-injection layer; the film formation chamber EL2, a hole-transport layer; the film formation chamber EL3, an electron-blocking layer; the film formation chamber EL4, a light-emitting layer; the film formation chamber EL5, a hole-blocking layer; the film formation chamber EL6, an electron-transport layer; the film formation chamber EL7, an electron-injection layer; and the film formation chamber EL8, a charge-generation layer. The film formation chambers EL1 to EL8 each preferably include an apparatus for forming the mask layer described above. For example, in the case where the electron-transport layer is the uppermost layer of the first EL layer 112, the film formation chamber EL6 includes an apparatus for forming the electron-transport layer and a mask layer. Since the electron-transport layer is formed and then the mask layer is formed over the electron-transport layer in the film formation chamber EL6, the top surface of the first EL layer 112 can be prevented from being exposed to the air.

In the film formation chamber SP, the upper electrode 115 can be formed. The film formation chamber SP includes a sputtering apparatus, for example.

In the film formation chamber ALD, the layer 183 and the protective layer 135 can be formed. The film formation chamber ALD includes an ALD apparatus, for example.

Although FIG. 16A illustrates an example in which one transfer chamber TF is provided, a plurality of transfer chambers TF may be joined together. FIG. 16B illustrates an example in which three transfer chambers TF are joined. Each of the transfer chambers TF is provided with one transfer robot RBT. In the example illustrated in FIG. 16B, each of the transfer chambers TF can be connected to four to six chambers excluding the loading chamber LL and the unloading chamber UL. In FIG. 16B, up to three more chambers can be provided depending on the application.

Next, an example of a film formation method using either of the film formation apparatuses is described. First, the substrate 101 provided with components up to the partition 120 is loaded into the film formation apparatus from the loading chamber LL, and heat treatment is performed in the treatment chamber HT. Through this heat treatment, moisture or the like adsorbed on the surface can be removed. Next, the hole-injection layer, the hole-transport layer, the electron-blocking layer, the light-emitting layer, the hole-blocking layer, the electron-transport layer, and the electron-injection layer are sequentially formed in the film formation chambers EL1 to EL7. Then, the upper electrode is formed in the film formation chamber SP. Subsequently, the protective layer 135 is formed in the film formation chamber ALD, and then the substrate 101 is unloaded to the outside from the unloading chamber UL. In the above manner, the first EL layer 112, the second EL layer 114, the upper electrode 115, and the protective layer 135 can be formed successively without exposure of the substrate 101 to the air.

The above-described film formation apparatus can also be used to form a light-emitting element having what is called a tandem structure, which includes a plurality of light-emitting layers with a charge-generation layer(s) therebetween.

First, as described above, after heat treatment is performed in the treatment chamber, the substrate 101 is sequentially transferred to the film formation chambers EL1 to EL7, so that hole-injection to electron-injection layers are sequentially formed. Next, a charge-generation layer is formed in the film formation chamber EL8. After that, hole-injection to electron-injection layers are sequentially formed again in the film formation chambers EL1 to EL7. Then, as described above, the upper electrode 115 is formed in the film formation chamber SP, the protective layer 135 is formed in the film formation chamber ALD, and the substrate 101 is unloaded from the unloading chamber UL. This makes it possible to manufacture a light-emitting element having a two-unit tandem structure in which the two light-emitting layers are stacked with the charge-generation layer therebetween.

In the film formation chamber EL8, at least one layer included in the charge-generation layer is formed. At least one of the electron-injection layer and the hole-injection layer formed before and after the film formation step in the film formation chamber EL8 can also serve as a layer included in the charge-generation layer. For example, in the case where the charge-generation layer has a stacked-layer structure of an electron-injection buffer layer, an electron-relay layer, and a p-type layer, the electron-injection layer may function as the electron-injection buffer layer, and the hole-injection layer may function as the p-type layer. In that case, the electron-relay layer may be formed in the film formation chamber EL8.

In the case of manufacturing a light-emitting element having an N-unit tandem structure (N is a natural number greater than or equal to 2), the film formation in the film formation chambers EL1 to EL8 can be repeated N-1 times, the film formation in the film formation chamber EL8 can be omitted for the last N-th time, and then the upper electrode 115 and the protective layer 135 can be formed.

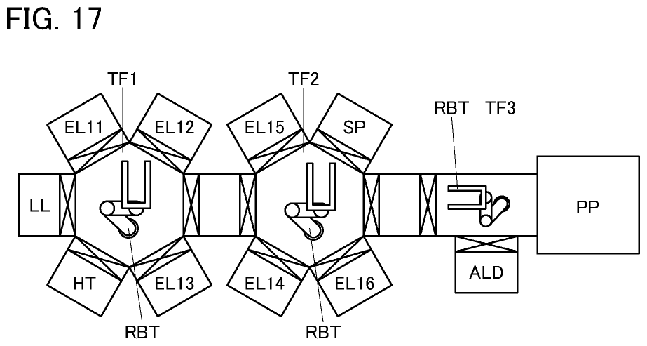

FIG. 17 illustrates a structure example of a film formation apparatus different from the above. In the film formation apparatus illustrated in FIG. 17, three transfer chambers (a transfer chamber TF1, a transfer chamber TF2, and a transfer chamber TF3) are joined.

The transfer chamber TF1 is connected to the loading chamber LL, three film formation chambers (a film formation chamber EL11, a film formation chamber EL12, and a film formation chamber EL13), and the treatment chamber HT. The transfer chamber TF2 is connected to four film formation chambers (a film formation chamber EL14, a film formation chamber EL15, a film formation chamber EL16, and the film formation chamber SP). The transfer chamber TF3 is connected to the film formation chamber ALD and a treatment chamber PP that performs a post-process such as sealing. In the structure illustrated in FIG. 17, the loading chamber LL also serves as the unloading chamber, and a substrate can be loaded and unloaded through the loading chamber LL.

The film formation chambers EL11 to EL16 each include a vacuum evaporation apparatus, where an organic film or an inorganic film can be formed. The above description can be referred to for the film formation chamber SP, the film formation chamber ALD, the treatment chamber HT, and the like.

Here, the transfer chambers TF1 and TF2 preferably have a reduced-pressure atmosphere. Meanwhile, the transfer chamber TF3 preferably has an atmospheric pressure atmosphere or a pressured (positive pressure) atmosphere. The inside of the transfer chamber TF3 is preferably kept in an atmosphere that contains an inert gas such as nitrogen or a noble gas as its main component and contains as little water as possible.

A sealing apparatus included in the treatment chamber PP, the ALD apparatus included in the film formation chamber ALD, and the like sometimes perform treatment in a reduced-pressure atmosphere; however, the treatment does not require a vacuum degree as high as that for a vacuum evaporation apparatus in some cases. For example, the vacuum evaporation apparatus keeps pressure inside its chamber reduced and performs film formation treatment in a reduced-pressure atmosphere, whereas the ALD apparatus, the sealing apparatus, and the like greatly change their pressure during the treatment in some cases. Thus, the transfer chamber TF3 does not need to have a reduced-pressure atmosphere. The inside of the transfer chamber TF3 is preferably kept under positive pressure, in which case entry of minute dust from the outside can be prevented and thus the inside can be kept clean. Furthermore, the transfer chambers TF1 and TF2 each have a structure that can withstand a high vacuum degree by using a metal member for the exterior, for example. The transfer chamber TF3, on the other hand, does not require high airtightness, and thus can be formed using a lightweight member such as an acrylic resin.

One or both of the treatment chamber PP and the transfer chamber TF3 may be provided with a mechanism for unloading the substrate. In that case, the substrate processed in the treatment chamber PP or the film formation chamber ALD does not need to be transferred to the transfer chamber TF1, the transfer chamber TF2, or the like in a reduced-pressure atmosphere again, so that the time required for unloading the substrate can be shortened. At this time, it is preferable to use a container with high hermeticity, such as a front-opening unified pod (FOUP) or a front-opening shipping box (FOSB) for unloading the substrate, in which case the substrate can be transferred to an external apparatus without exposure to the air.

In the film formation apparatus illustrated in FIG. 17, the substrate can be loaded from the loading chamber LL; heat treatment can be performed in the treatment chamber HT; thin films constituting the light-emitting elements can be formed in the film formation chambers connected to the transfer chamber TF1 and the transfer chamber TF2; the substrate can be transferred to the transfer chamber TF3; and then a protective film can be formed in the film formation chamber ALD. Since the substrate is not exposed to the air before the protective film is completed in this manner, a light-emitting element with extremely high reliability can be manufactured. Furthermore, even after all the light-emitting elements are formed, processing can be successively performed without exposure of the substrate to the air between the step of forming a protective film in the film formation chamber ALD and the sealing step in the treatment chamber PP. This can prevent generation of a defect such as defective sealing due to dust and increase the manufacturing yield.

The above is the description of the film formation apparatuses and the film formation methods using the film formation apparatuses.

### Structure Example of Evaporation Apparatus

A structure of an evaporation apparatus suitable for the substrate 101 with a large size is described here. The evaporation apparatus described below as an example can be used in any of the film formation chambers EL1 to EL8 and EL11 to EL16. The evaporation apparatus described below as an example can be used for both the upper electrode 115 and the first EL layers 112.

The use of a plurality of evaporation sources for formation of a film on the substrate 101 with a large size enables a reduction in the time required for the film formation and formation of a uniform film without any unevenness in thickness.

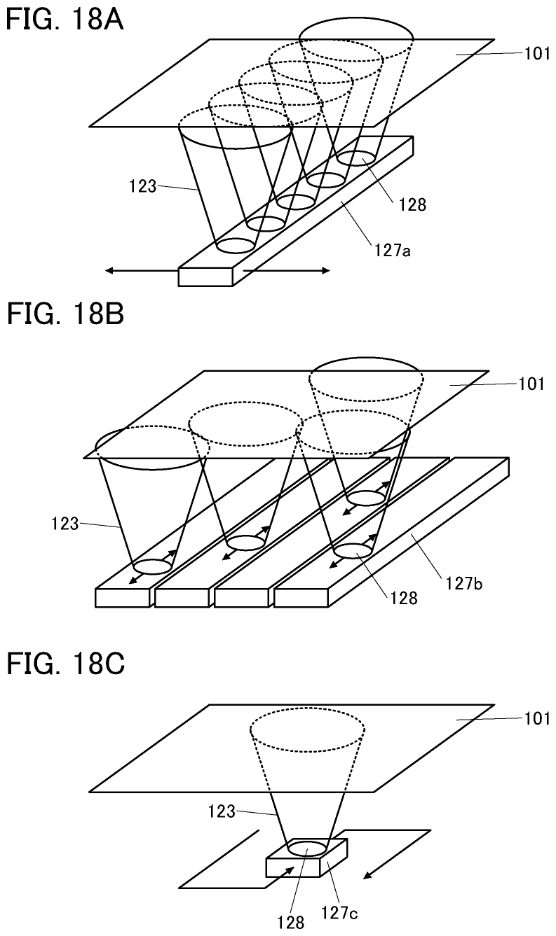

For example, as illustrated in FIG. 18A, a unit 127a in which a plurality of nozzles 128 are provided at regular intervals in one direction can be used. An evaporation source is placed for each of the nozzles 128, and a film formation material 123 is ejected from each nozzle 128 in a substantially conical shape. The spread range of the film formation material 123 is determined by the shape of the nozzle 128, the distance between the substrate 101 and the nozzle 128, and the like. The unit 127a can be moved in a direction intersecting (or orthogonal to, for example) the arrangement direction of the nozzles 128. The unit 127a is preferably movable because in that case, the footprint of a film formation chamber can be small. The unit 127a may be fixed and the substrate 101 may be moved.

FIG. 18B illustrates a structure including a plurality of units 127b. Each of the units 127b is provided with one nozzle 128. The units 127b each have a shape that is long in one direction, and have a mechanism in which the nozzle 128 can move in the longitudinal direction. The plurality of units 127b are arranged in a direction intersecting (or orthogonal to, for example) the longitudinal direction. With the substrate 101 and the units 127b fixed, the nozzles 128 included in the units 127b are moved, so that a film can be formed on the entire surface of the substrate 101. With such a structure, it is not necessary to move the unit 127b with a large size; thus, the structure of the apparatus can be simplified.

Although a plurality of nozzles are used in the above description, one nozzle may be used. FIG. 18C illustrates a structure including one unit 127c provided with one nozzle 128. The unit 127c has a mechanism capable of moving in two directions orthogonal to each other. With the substrate 101 fixed, the unit 127c is scanned in a zigzag manner, so that a film can be formed on the entire surface of the substrate 101.

Next, the relationship between a film formation method and the incident angle of a film formation material will be described.

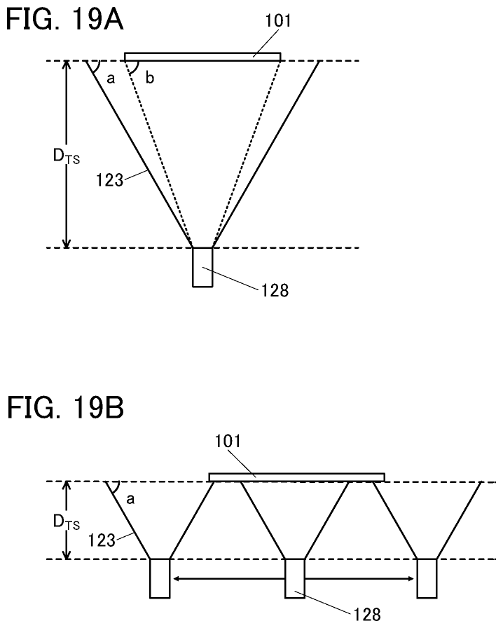

FIG. 19A schematically illustrates a method (also referred to as a point source method) in which film formation is performed with both the substrate 101 and the nozzle 128 fixed. The substrate 101 is placed above the nozzle 128 at a position apart from the nozzle 128 by a distance D_{TS}, and the film formation material 123 is ejected upward from the nozzle. In order to form a film uniformly on the substrate 101, it is important that the distance D_{TS} be made large and the substrate 101 be placed such that the entire substrate surface is positioned within a range in which the film formation material 123 arrives. In the case where the film formation material 123 is diffused from the nozzle 128 at an angle a, the maximum value of the incident angle at which the film formation material 123 arrives at the substrate 101 is smaller than the angle a (i.e., an angle b). Thus, the point source method can be regarded as a method in which the film formation material 123 has high directionality and does not spread easily. Even in the point source method, the distance D_{TS} can be made small by increasing the number of nozzles 128.

FIG. 19B schematically illustrates a method (also referred to as a moving cell method) in which a film is formed while the nozzle 128 is moved parallel to the substrate surface. Since the nozzle 128 can be moved, the distance D_{TS} can be smaller than that of the case of a point source method. The maximum value of the incident angle at which the film formation material 123 arrives at the substrate 101 is equal to the angle α. Thus, the moving cell method can be regarded as a method in which the film formation material 123 has lower directionality and spreads more easily than in the case of a point source method. Even in the moving cell method, the directionality of the film formation material 123 can be enhanced by increasing the distance D_{TS}. The same applies to a method in which the substrate 101 is moved instead of the nozzle 128.

In the above-described methods for manufacturing a display device, the first EL layers 112 are preferably formed by a method in which a film formation material has high directionality, and the upper electrode 115 is preferably formed by a method in which a film formation material has low directionality.

In the case where the upper electrode 115 is formed using a metal material such as silver by a vacuum evaporation method, the temperature of a crucible might become higher than or equal to 1000 °C, in which case reducing the distance D_{TS} between the substrate 101 and the nozzle 128 might be difficult. In that case, a method in which a film formation material has high directionality and a method in which a film formation material has low directionality (e.g., a sputtering method) are preferably used in combination to form the upper electrode 115 having a stacked-layer structure. For example, the upper electrode 115 can have a two-layer structure in which an alloy film containing silver and magnesium is formed by vacuum evaporation method and then an oxide conductor film containing indium is formed by a sputtering method.

The above is the description of the structure examples of the evaporation apparatuses.

### Embodiment 2

In this embodiment, structure examples of the display device of one embodiment of the present invention will be described.

The display device in this embodiment can be a high-definition display device or a large-sized display device. Accordingly, the display device in this embodiment can be used for display portions of electronic devices such as a digital camera, a digital video camera, a digital photo frame, a mobile phone, a portable game console, a smart phone, a wristwatch terminal, a tablet terminal, a portable information terminal, and an audio reproducing device, in addition to display portions of electronic devices with a relatively large screen, such as a television apparatus, a desktop or laptop personal computer, a monitor of a computer or the like, digital signage, and a large game machine like a pachinko machine.

### Display Device 400A

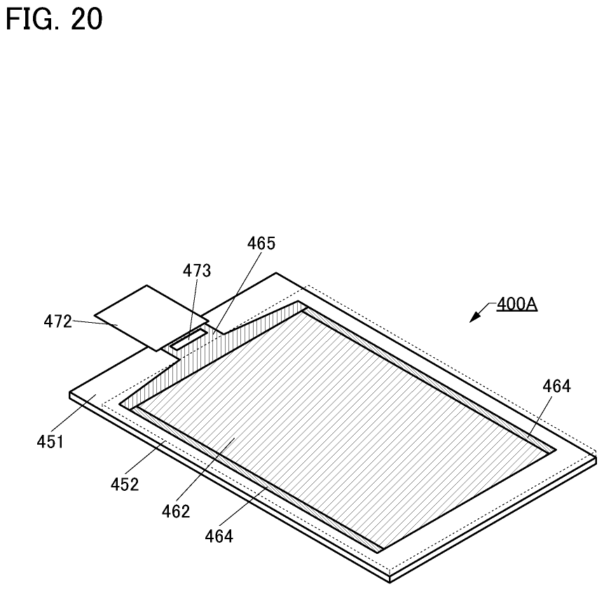

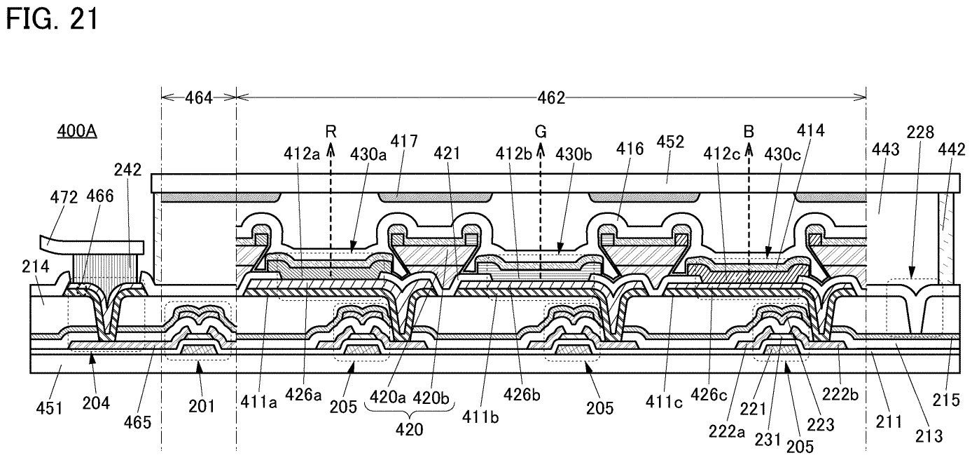

FIG. 20 is a perspective view of a display device 400A, and FIG. 21 is a cross-sectional view of the display device 400A.

In the display device 400A, a substrate 452 and a substrate 451 are bonded to each other. In FIG. 20, the substrate 452 is denoted by a dashed line.

The display device 400A includes a display portion 462, a circuit 464, a wiring 465, and the like. FIG. 20 illustrates an example in which an integrated circuit (IC) 473 and an FPC 472 are mounted on the display device 400A. Thus, the structure illustrated in FIG. 20 can be regarded as a display module including the display device 400A, the IC, and the FPC.

As the circuit 464, a scan line driver circuit can be used, for example.

The wiring 465 has a function of supplying a signal and power to the display portion 462 and the circuit 464. The signal and power are input to the wiring 465 from the outside through the FPC 472 or input to the wiring 465 from the IC 473.

FIG. 20 illustrates an example in which the IC 473 is provided over the substrate 451 by a chip on glass (COG) method, a chip on film (COF) method, or the like. An IC including a scan line driver circuit, a signal line driver circuit, or the like can be used as the IC 473, for example. Note that the display device 400A and the display module are not necessarily provided with an IC. Alternatively, the IC may be mounted on the FPC by a COF method or the like.

FIG. 21 illustrates an example of cross sections of part of a region including the FPC 472, part of the circuit 464, part of the display portion 462, and part of a region including an end portion in the display device 400A.

The display device 400A includes a transistor 201, a transistor 205, a light-emitting element 430a which emits red light, a light-emitting element 430b which emits green light, a light-emitting element 430c which emits blue light, and the like between the substrate 451 and the substrate 452.

The light-emitting element described as an example in Embodiment 1 can be employed for the light-emitting element 430a, the light-emitting element 430b, and the light-emitting element 430c.

A protective layer 416 and the substrate 452 are bonded to each other with an adhesive layer 442. A solid sealing structure, a hollow sealing structure, or the like can be employed to seal the light-emitting elements. In FIG. 21, a hollow sealing structure is employed in which a space 443 surrounded by the substrate 452, the adhesive layer 442, and the substrate 451 is filled with an inert gas (e.g., nitrogen or argon). The adhesive layer 442 may overlap with the light-emitting element. The space 443 surrounded by the substrate 452, the adhesive layer 442, and the substrate 451 may be filled with a resin different from that of the adhesive layer 442.

FIG. 21 illustrates an example in which each light-emitting element 430 includes any one of a pixel electrode 411a, a pixel electrode 411b, and a pixel electrode 411c; any one of an island-shaped first EL layer 412a, an island-shaped first EL layer 412b, and an island-shaped first EL layer 412c which include light-emitting layers emitting light of different colors; and an upper electrode 414 over the first EL layers 412a, 412b, and 412c.

In the case where a pixel of the display device includes three kinds of subpixels including light-emitting elements emitting light of different colors, the three subpixels can be of three colors of R, G, and B or of three colors of yellow (Y), cyan (C), and magenta (M). In the case where four subpixels are included, the four subpixels can be of four colors of R, G, B, and white (W) or of four colors of R, G, B, and Y.

The light-emitting elements 430a, 430b, and 430c each have an optical adjustment layer between the pixel electrode and the EL layer. The light-emitting element 430a includes an optical adjustment layer 426a, the light-emitting element 430b includes an optical adjustment layer 426b, and the light-emitting element 430c includes an optical adjustment layer 426c. Embodiment 1 can be referred to for the details of the light-emitting elements. The optical adjustment layers 426 have different thicknesses. The optical adjustment layers 426 preferably contain the same material having a light-transmitting property and conductivity. For the optical adjustment layers 426, a conductive metal oxide film containing indium or zinc is preferably used.

The pixel electrodes 411a, 411b, and 411c are each connected to a conductive layer 222b included in the transistor 205 through an opening provided in an insulating layer 214.

End portions of the pixel electrodes and the optical adjustment layers are covered with an insulating layer 421. The pixel electrodes contain a material that reflects visible light, and the counter electrodes contain a material that transmits visible light.

Light emitted from the light-emitting element is emitted to the substrate 452 side. For the substrate 452, a material having a high visible-light-transmitting property is preferably used.

A partition 420 including a layer 420a and a layer 420b is provided over the insulating layer 421. For the partition 420, the description of the partition 120 in Embodiment 1 can be referred to. The partition 420 is provided in a region overlapping with a light-blocking layer 417. Parts of upper electrodes of two light-emitting elements adjacent to each other with the partition 420 therebetween and a layer containing the same material as the EL layers are provided over the partition 420. The protective layer 416 is provided to cover the partition 420.

The transistor 201 and the transistor 205 are formed over the substrate 451. These transistors can be manufactured through the same process.

An insulating layer 211, the insulating layer 213, the insulating layer 215, and the insulating layer 214 are provided in this order over the substrate 451. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. The number of gate insulating layers and the number of insulating layers covering the transistors are not limited and may each be one or more.

A material through which impurities such as water and hydrogen are not easily diffused is preferably used for at least one of the insulating layers covering the transistors. This is because such an insulating layer can function as a barrier layer. Such a structure can effectively inhibit diffusion of impurities into the transistors from the outside and improve the reliability of the display device.

An inorganic insulating film is preferably used as each of the insulating layers 211, 213, and 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. Two or more of the above insulating films may also be stacked.

Here, an organic insulating film often has a lower barrier property against impurities such as water or moisture than an inorganic insulating film does. Thus, the organic insulating film preferably has an opening in the vicinity of the end portion of the display device 400A. This can inhibit entry of impurities from the end portion of the display device 400A through the organic insulating film. Alternatively, the organic insulating film may be formed such that its end portion is positioned inward from the end portion of the display device 400A, to prevent the organic insulating film from being exposed at the end portion of the display device 400A.

In this specification and the like, a barrier film refers to a film having a barrier property or a film having a high barrier property. A barrier property means one or both of a function of hindering diffusion of a target substance and thereby inhibiting the substance from passing through a film (also referred to as low permeability) and a function of capturing or fixing (also referred to as gettering) the substance.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

In a region 228 illustrated in FIG. 21, an opening is formed in the insulating layer 214 so as to surround the display portion 462. This can inhibit entry of impurities into the display portion 462 from the outside through the insulating layer 214 even when an organic insulating film is used as the insulating layer 214. Consequently, the reliability of the display device 400A can be increased.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is employed for each of the transistors 201 and 205. The two gates may be connected to each other and supplied with the same signal to drive the transistor. Alternatively, the threshold voltage of the transistor may be controlled by supplying a potential for controlling the threshold voltage to one of the two gates and supplying a potential for driving to the other of the two gates.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

It is preferable that a semiconductor layer of a transistor contain a metal oxide (also referred to as an oxide semiconductor). That is, a transistor containing a metal oxide in its channel formation region (hereinafter referred to as an OS transistor) is preferably used in the display device of this embodiment. Alternatively, the semiconductor layer of the transistor may contain silicon. Examples of silicon include amorphous silicon and crystalline silicon (e.g., low-temperature polysilicon or single crystal silicon).

The semiconductor layer preferably contains a metal oxide containing indium. In particular, the semiconductor layer preferably contains indium oxide.

The semiconductor layer preferably contains indium, an element M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, the element M is preferably one or more of aluminum, gallium, yttrium, and tin.

It is particularly preferable that an oxide containing indium (In), gallium (Ga), and zinc (Zn) (also referred to as IGZO) be used for the semiconductor layer.

When the semiconductor layer is an In—M—Zn oxide, the atomic proportion of In is preferably higher than or equal to the atomic proportion of M in the In—M—Zn oxide. Examples of the atomic ratio of the metal elements in such an In—M—Zn oxide include In:M:Zn=1:1:1, 1:1:1.2, 2:1:3, 3:1:2, 4:2:3, 4:2:4.1, 5:1:3, 5:1:6, 5:1:7, 5:1:8, 6:1:6, and 5:2:5 and an atomic ratio in the neighborhood thereof. Note that the neighborhood of the atomic ratio includes ±30% of an intended atomic ratio.

For example, when the atomic ratio is described as In:Ga:Zn=4:2:3 or being in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn=5:1:6 or being in the neighborhood thereof, the case is included where the atomic proportion of Ga is greater than 0.5 and less than or equal to 2 and the atomic proportion of Zn is greater than or equal to 5 and less than or equal to 7 with the atomic proportion of In being 5. Furthermore, when the atomic ratio is described as In:Ga:Zn=1:1:1 or being in the neighborhood thereof, the case is included where the atomic proportion of Ga is greater than 0.5 and less than or equal to 2 and the atomic proportion of Zn is greater than 0.5 and less than or equal to 2 with the atomic proportion of In being 1.

The transistor included in the circuit 464 and the transistor included in the display portion 462 may have the same structure or different structures. One structure or two or more kinds of structures may be employed for a plurality of transistors included in the circuit 464. Similarly, one structure or two or more kinds of structures may be employed for a plurality of transistors included in the display portion 462.

A connection portion 204 is provided in a region of the substrate 451 that does not overlap with the substrate 452. In the connection portion 204, the wiring 465 is electrically connected to the FPC 472 through a conductive layer 466 and a connection layer 242. An example is illustrated in which the conductive layer 466 has a stacked-layer structure of a conductive film obtained by processing the same conductive film as the pixel electrode and a conductive film obtained by processing the same conductive film as the optical adjustment layer. On the top surface of the connection portion 204, the conductive layer 466 is exposed. Thus, the connection portion 204 and the FPC 472 can be electrically connected to each other through the connection layer 242.

The light-blocking layer 417 is preferably provided on the surface of the substrate 452 on the substrate 451 side. A variety of optical members can be arranged on the outer surface of the substrate 452. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be arranged on the outer surface of the substrate 452.

Providing the protective layer 416 that covers the light-emitting element can inhibit impurities such as water from entering the light-emitting element and increase the reliability of the light-emitting element.

In the region 228 in the vicinity of the end portion of the display device 400A, the insulating layer 215 and the protective layer 416 are preferably in contact with each other through the opening in the insulating layer 214. In particular, the inorganic insulating film included in the insulating layer 215 and an inorganic insulating film included in the protective layer 416 are preferably in contact with each other. This can inhibit entry of impurities into the display portion 462 from the outside through the organic insulating film. Consequently, the reliability of the display device 400A can be increased.

The protective layer 416 may have a stacked-layer structure of an organic insulating film and an inorganic insulating film. In that case, an end portion of the inorganic insulating film preferably extends beyond an end portion of the organic insulating film.

For each of the substrates 451 and 452, glass, quartz, ceramics, sapphire, a resin, a metal, an alloy, a semiconductor, or the like can be used. The substrate on the side from which light from the light-emitting element is extracted is formed using a material that transmits the light. When the substrates 451 and 452 are formed using a flexible material, the flexibility of the display device can be increased. Furthermore, a polarizing plate may be used as the substrate 451 or the substrate 452.

For each of the substrates 451 and 452, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for one or both of the substrates 451 and 452.

In the case where a circularly polarizing plate overlaps with the display device, a highly optically isotropic substrate is preferably used as the substrate included in the display device. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display panel might be changed, e.g., creases are generated. Thus, as the substrate, a film with a low water absorption rate is preferably used. For example, the water absorption rate of the film is preferably 1% or lower, further preferably 0.1% or lower, still further preferably 0.01% or lower.

The adhesive layer can be formed using any of a variety of curable adhesives, e.g., a reactive curable adhesive, a thermosetting adhesive, an anaerobic adhesive, or a photocurable adhesive such as an ultraviolet curable adhesive. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene-vinyl acetate (EVA) resin. In particular, a material with low moisture permeability, such as an epoxy resin, is preferable. A two-component resin may be used. An adhesive sheet or the like may be used.

For the connection layer 242, an anisotropic conductive film (ACF), an anisotropic conductive paste (ACP), or the like can be used.

As materials for the gates, the source, and the drain of each transistor and conductive layers functioning as wirings and electrodes included in the display device, any of metals such as aluminum, titanium, chromium, nickel, copper, yttrium, zirconium, molybdenum, silver, tantalum, and tungsten, or an alloy containing any of these metals as its main component can be used, for example. A single-layer structure or a stacked-layer structure including a film containing any of these materials can be used.

Examples of light-transmitting conductive materials include graphene and a conductive oxide such as indium oxide, an indium tin oxide, an indium zinc oxide, zinc oxide, or zinc oxide containing gallium. Other examples include a metal material such as gold, silver, platinum, magnesium, nickel, tungsten, chromium, molybdenum, iron, cobalt, copper, palladium, or titanium, and an alloy material containing any of these metal materials. Alternatively, a nitride of the metal material (e.g., titanium nitride) or the like may be used. In the case of using the metal material or the alloy material (or the nitride thereof), the thickness is preferably set small enough to transmit light. Alternatively, a stacked film of any of the above materials can be used for the conductive layers. For example, a stacked film of indium tin oxide and an alloy of silver and magnesium is preferably used because conductivity can be increased. These can also be used for conductive layers such as wirings and electrodes included in the display device, and conductive layers (e.g., a conductive layer functioning as a pixel electrode or a common electrode) included in a light-emitting element.

Examples of insulating materials that can be used for the insulating layers include a resin such as an acrylic resin or an epoxy resin, and an inorganic insulating material such as silicon oxide, silicon oxynitride, silicon nitride oxide, silicon nitride, or aluminum oxide.

### Display Device 400B

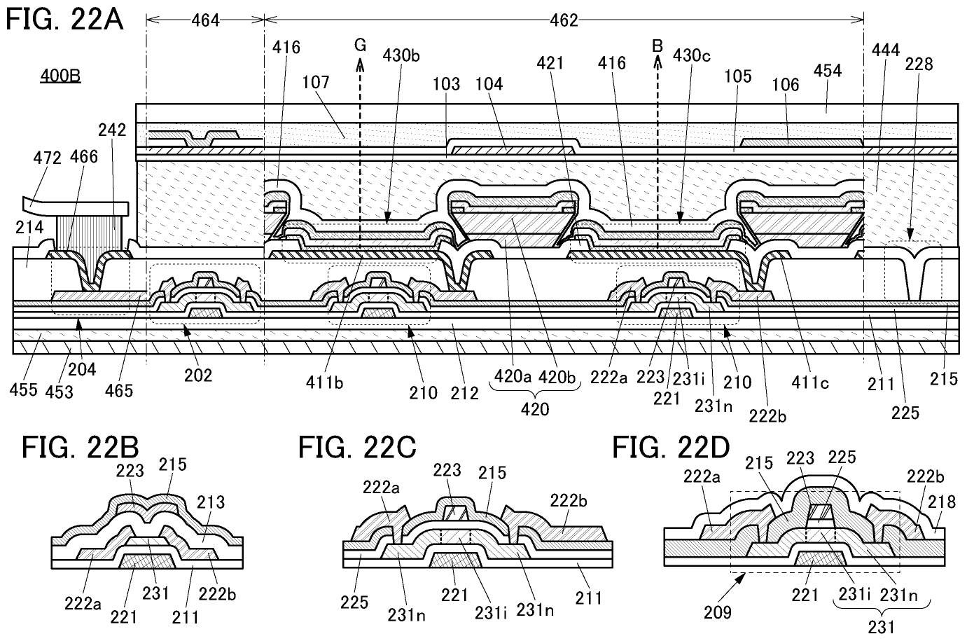

FIG. 22A is a cross-sectional view of a display device 400B. A perspective view of the display device 400B is similar to that of the display device 400A (FIG. 20). FIG. 22A illustrates an example of cross sections of part of a region including the FPC 472, part of the circuit 464, and part of the display portion 462 in the display device 400B. FIG. 22A specifically illustrates an example of a cross section of a region including the light-emitting element 430b which emits green light and the light-emitting element 430c which emits blue light, in the display portion 462. The light-emitting element described as an example in Embodiment 1 can be employed for each of the light-emitting elements. Note that portions similar to those in the display device 400A illustrated in FIG. 21 are not described in some cases.

The display device 400B illustrated in FIG. 22A includes a transistor 202, a transistor 210, the light-emitting element 430b, the light-emitting element 430c, a touch sensor, and the like between a substrate 453 and a substrate 454.

The display device 400B illustrated in FIG. 22A includes an organic insulating layer 444, an inorganic insulating layer 103, a conductive layer 104, an inorganic insulating layer 105, a conductive layer 106, and an adhesive layer 107.

The substrate 454 is bonded to the conductive layer 106 and the inorganic insulating layer 105 with the adhesive layer 107. The adhesive layer 107 is provided so as to overlap with the light-emitting element 430b and the light-emitting element 430c; that is, the display device 400B employs a solid sealing structure.

The substrate 453 and an insulating layer 212 are bonded to each other with an adhesive layer 455.

The conductive layer 104 functions as one electrode of the touch sensor, and the conductive layer 106 functions as the other electrode of the touch sensor. Each of the conductive layers 104 and 106 is preferably provided in a region overlapping with the partition 420 including the layer 420a and the layer 420b. Furthermore, each of the conductive layers 104 and 106 preferably functions as a light-blocking layer.

As a method for manufacturing the display device 400B, first, a formation substrate provided with the insulating layer 212, the transistors, the light-emitting elements, the touch sensor, and the like and the substrate 454 are bonded to each other with the adhesive layer 107. Then, the substrate 453 is attached to a surface exposed by separation of the formation substrate, whereby the components formed over the formation substrate are transferred to the substrate 453. The substrates 453 and 454 are preferably flexible. Accordingly, the display device 400B can be highly flexible.

The inorganic insulating film that can be used as each of the insulating layers 211, 213, and 215 can be used as each of the insulating layer 212, the inorganic insulating layer 103, and the inorganic insulating layer 105.

The pixel electrode is connected to the conductive layer 222b included in the transistor 210 through the opening provided in the insulating layer 214. The conductive layer 222b is connected to a low-resistance region 231n through an opening provided in the insulating layer 215 and an insulating layer 225. The transistor 210 has a function of controlling the driving of the light-emitting element.

The transistor 202 and the transistor 210 will be described later with reference to FIG. 22C.

An end portion of the pixel electrode is covered with the insulating layer 421.

Light emitted from the light-emitting elements 430b and 430c is emitted to the substrate 454 side. For the substrate 454, a material having a high visible-light-transmitting property is preferably used.

The connection portion 204 is provided in a region of the substrate 453 that does not overlap with the substrate 454. In the connection portion 204, the wiring 465 is electrically connected to the FPC 472 through the conductive layer 466 and the connection layer 242. The conductive layer 466 can be obtained by processing the same conductive film as the pixel electrode. Thus, the connection portion 204 and the FPC 472 can be electrically connected to each other through the connection layer 242. The conductive layer 106 may be connected to a conductive layer provided in the same layer as the conductive layer 104 via an opening provided in the inorganic insulating layer 105. The conductive layers 104 and 106 may be electrically connected to the FPC 472 in a connection portion.

Although the touch sensor is provided between the substrate 453 and the substrate 454 in FIG. 22A, the touch sensor may be provided on the top surface of the substrate 454. In that case, a touch sensor panel can be attached to the top surface of the substrate 454 with an adhesive layer.

A structure of a mutual capacitive touch sensor will be described below.

### Structure Example of Touch Sensor

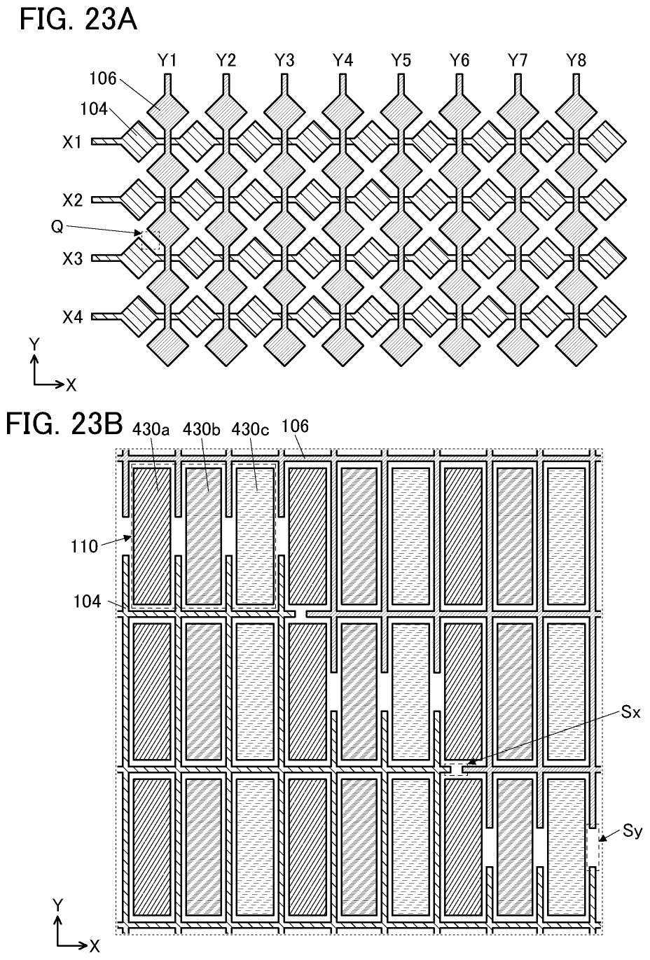

FIG. 23A is a schematic top view illustrating an example of a conductive layer included in a touch sensor. The touch sensor illustrated in FIG. 23A includes the conductive layer 104 and the conductive layer 106.

The touch sensor includes a plurality of wirings extending in the X direction and arranged in the Y direction (wirings X1 to X4) and a plurality of wirings extending in the Y direction and arranged in the X direction (wirings Y1 to Y8). Hereinafter, an expression “wiring Xn” is used for describing the matter common to the wirings X1 to X4, and an expression “wiring Ym” is used for describing the matter common to the wirings Y1 to Y8.

The wiring Xn is formed of the conductive layer 104. The wiring Xn has a shape in which portions elongated in the X direction and rhombic portions are alternately connected to each other.

The wiring Ym is formed of the conductive layer 106. The wiring Ym has a shape in which portions elongated in the Y direction and rhombic portions are alternately connected to each other. Each wiring Ym has a region that overlaps with each wiring Xn.

Although not illustrated, the wiring Xn may be formed of the conductive layer 104 and the wiring Ym may be formed of the conductive layers 104 and 106. In that case, the wiring Xn and the wiring Ym intersect with each other by a narrow portion formed of the conductive layer 104 of the wiring Xn and a narrow portion formed of the conductive layer 106 of the wiring Ym.

Although FIG. 23A illustrates an example in which four wirings X1 to X4 and eight wirings Y1 to Y8 are included, the number of wirings is not limited thereto and can be set as appropriate depending on the size of a display portion of a display device or required wiring density of a touch sensor.

### Structure Example of Electrode Shape

More specific examples of top-view shapes of electrodes of the wirings Xn and Ym will be described below.

FIG. 23B is an enlarged view of a region Q illustrated in FIG. 23A. The region Q includes the rhombic portions of the wirings Xn and Ym and a boundary therebetween.

FIG. 23B illustrates top-view shapes of the conductive layer 104 that forms the wiring Xn and the conductive layer 106 that forms the wiring Ym. The conductive layers 104 and 106 each have a lattice-like top-view shape. In other words, the conductive layers 104 and 106 each have a top-view shape having a plurality of openings.

FIG. 23B illustrates the light-emitting elements 430. The light-emitting elements 430 include the light-emitting elements 430a, 430b, and 430c. For example, the light-emitting elements 430a, 430b, and 430c may be a red subpixel R, a green subpixel G, and a blue subpixel B, respectively.

The conductive layers 104 and 106 are provided between adjacent light-emitting elements in a plan view. In other words, the light-emitting elements 430a, 430b, and 430c are each provided in a position overlapping with an opening of the conductive layer 104 or 106. Here, an example is illustrated in which one subpixel is provided in a position overlapping with one opening of the conductive layer 104 or 106 in a plan view. One embodiment of the present invention is not limited to this example, and a plurality of subpixels may be provided in a position overlapping with one opening.

The conductive layers 104 and 106 each have a lattice-like top-view shape formed of portions extending in the X direction, portions extending in the Y direction, and their intersections. The conductive layers 104 and 106 are separated from each other by notches Sx provided in the portions extending in the X direction of the lattice-shaped conductive layer and notches Sy provided in the portions extending in the Y direction of the lattice-shaped conductive layer. The conductive layers 104 and 106 can be provided to overlap with each other. Such a structure allows the distance between the conductive layers 104 and 106 to be small, thereby increasing the capacitance therebetween. Thus, the detection sensitivity of the touch sensor can be increased, which makes the above structure preferable.

Although a notch may be provided at the intersection of the lattice, it is preferable that the notch Sx and the notch Sy be respectively positioned in a portion extending in the X direction and a portion extending in the Y direction of the lattice as illustrated in FIG. 23B, whereby the patterns of the conductive layers 104 and 106 can be less likely to be recognized from the display surface side.

Furthermore, as illustrated in FIG. 23B, portions of at least one of the conductive layers 104 and 106 are necessarily provided adjacent to the perimeters of the light-emitting elements 430a, 430b, and 430c. With such a structure, the patterns of the conductive layers 104 and 106 can be less likely to be recognized from the display surface side.

In FIG. 23B, the conductive layers 104 and 106 each have a lattice-like top-view shape having vertically long openings. The light-emitting elements 430a, 430b, and 430c are each positioned to overlap with one opening. The light-emitting elements 430a, the light-emitting elements 430b, and the light-emitting elements 430c illustrated in FIG. 23B are each arranged in the Y direction as in FIG. 1A. The positions of the light-emitting elements 430a, 430b, and 430c are not limited thereto, and the positions of any two light-emitting elements 430 can be interchanged.

Note that the positions of the pixel and the touch sensor of the present invention are not limited to the positions illustrated in FIG. 23B. For example, although not illustrated, the light-emitting elements 430a, 430b, and 430c may be collectively provided in one opening of the conductive layer 104 or 106. That is, a pixel including a plurality of subpixels may be provided in one opening of the conductive layer 104 or 106 instead of providing one subpixel in one opening.

Although the light-emitting elements 430 are arranged in a stripe pattern in FIG. 23B as in FIG. 1A, the arrangement of the light-emitting elements is not limited thereto. For example, the light-emitting elements 430 may be arranged in an S-stripe pattern as FIG. 1B.

### Transistor

As a transistor in the display device of one embodiment of the present invention, the transistor illustrated in FIG. 22B can be used. The transistor illustrated in FIG. 22B is similar to the above-described transistor illustrated in FIG. 21, and thus detailed description is omitted. As the transistor in the display device of one embodiment of the present invention, the transistor illustrated in FIG. 22C or FIG. 22D can also be used.

The transistor illustrated in FIG. 22C includes the conductive layer 221 functioning as a gate, the insulating layer 211 functioning as a gate insulating layer, a semiconductor layer including a channel formation region 231i and a pair of low-resistance regions 231n, the conductive layer 222a connected to one of the low-resistance regions 231n, the conductive layer 222b connected to the other low-resistance region 231n, the insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between the conductive layer 223 and the channel formation region 231i.

The conductive layer 222a and the conductive layer 222b are connected to the corresponding low-resistance regions 231n through openings provided in the insulating layer 215 and the insulating layer 225. One of the conductive layers 222a and 222b functions as a source, and the other functions as a drain. In FIG. 22C, the insulating layer 225 covers the top surface and a side surface of the semiconductor layer.

In a transistor 209 illustrated in FIG. 22D, the insulating layer 225 overlaps with the channel formation region 231i of the semiconductor layer 231 and does not overlap with the low-resistance regions 231n. The structure illustrated in FIG. 22D is obtained by processing the insulating layer 225 using the conductive layer 223 as a mask, for example. In FIG. 22D, the insulating layer 215 is provided to cover the insulating layer 225 and the conductive layer 223, and the conductive layer 222a and the conductive layer 222b are connected to the low-resistance regions 231n through the openings in the insulating layer 215. Furthermore, an insulating layer 218 covering the transistor may be provided.

At least part of any of the structure examples, the drawings corresponding thereto, and the like described in this embodiment can be combined with any of the other structure examples, the other drawings corresponding thereto, and the like as appropriate.

At least part of this embodiment can be implemented as appropriate in combination with any of the other embodiments described in this specification.

### Embodiment 3

In this embodiment, a structure example of a display device different from the above will be described.

The display device in this embodiment can be a high-resolution display device. Thus, the display device in this embodiment can be used for display portions of information terminals (wearable devices) such as watch-type or bracelet-type information terminals and display portions of wearable devices capable of being worn on a head, such as a VR device like a head-mounted display and a glasses-type AR device.

### Display Module

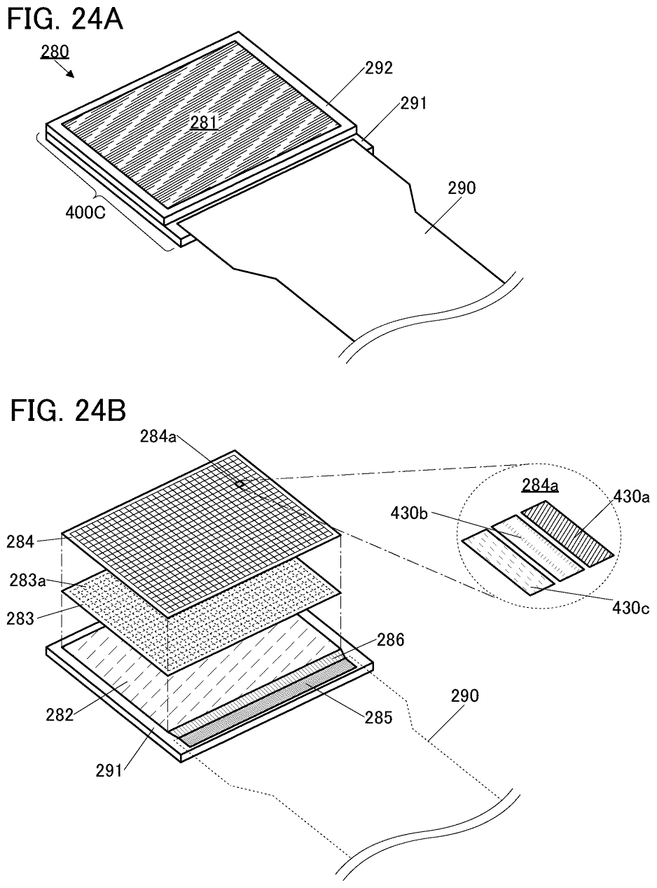

FIG. 24A is a perspective view of a display module 280. The display module 280 includes a display device 400C and an FPC 290. The display device included in the display module 280 is not limited to the display device 400C and may be a display device 400D or a display device 400E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 24B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 24B. The pixel 284a includes the light-emitting elements 430a, 430b, and 430c emitting light of different colors. The plurality of light-emitting elements may be arranged in a stripe pattern as illustrated in FIG. 24B. With the stripe arrangement that enables high-density arrangement of pixel circuits, a high-resolution display device can be provided. Alternatively, a variety of arrangement methods such as a delta arrangement or a pentile arrangement can be employed.

The pixel circuit portion 283 includes a plurality of pixel circuits 283a arranged periodically.

One pixel circuit 283a is a circuit that controls light emission of three light-emitting elements included in one pixel 284a. One pixel circuit 283a may be provided with three circuits each of which controls light emission of one light-emitting element. For example, the pixel circuit 283a can include at least one selection transistor, one current control transistor (driving transistor), and a capacitor for one light-emitting element. A gate signal is input to a gate of the selection transistor, and a source signal is input to one of a source and a drain of the selection transistor. Thus, an active-matrix display device is obtained.

### Configuration Example of Pixel

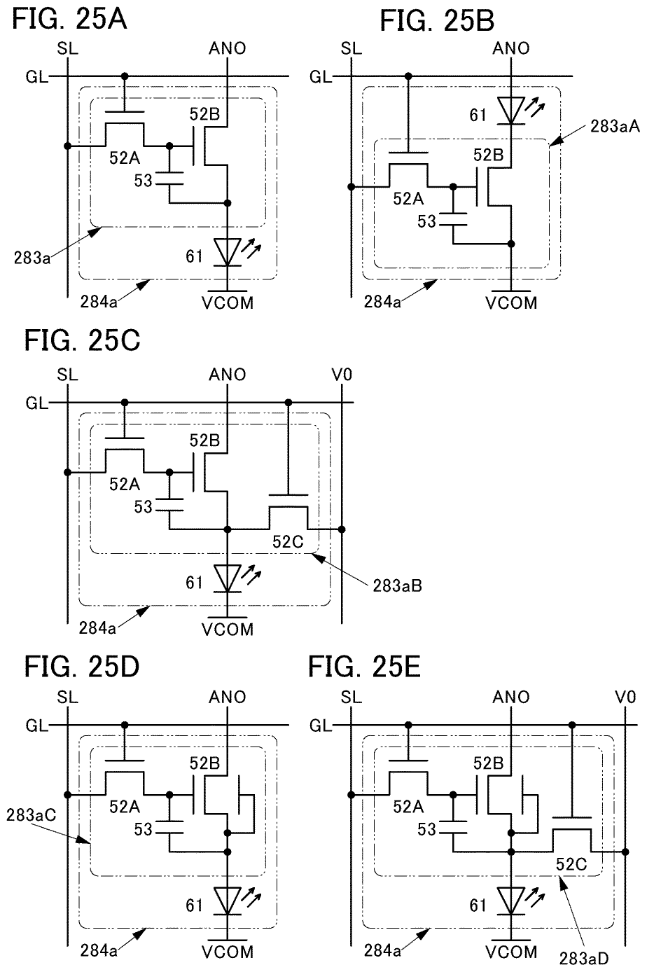

FIG. 25A illustrates a configuration example of the pixel 284a. The pixel 284a includes the pixel circuit 283a and a light-emitting device 61.

The pixel circuit 283a includes a transistor 52A, a transistor 52B, and a capacitor 53. The pixel circuit 283a is a 2Tr1C-type pixel circuit including two transistors and one capacitor. There is no particular limitation on the pixel circuit that can be used for the display device of one embodiment of the present invention.

An anode of the light-emitting device 61 is connected to one of a source and a drain of the transistor 52B and one electrode of the capacitor 53. The other of the source and the drain of the transistor 52B is connected to a wiring ANO. A gate of the transistor 52B is connected to one of a source and a drain of the transistor 52A and the other electrode of the capacitor 53. The other of the source and the drain of the transistor 52A is connected to a wiring SL. A gate of the transistor 52A is connected to a wiring GL. A cathode of the light-emitting device 61 is connected to a wiring VCOM.

The wiring VCOM supplies a potential for supplying current to the light-emitting device 61. The transistor 52A has a function of controlling electrical continuity and discontinuity between the wiring SL and the gate of the transistor 52B in accordance with the potential of the wiring GL. For example, VDD is supplied to the wiring ANO, and VSS is supplied to the wiring VCOM.

The transistor 52A functions as a selection transistor for controlling the selection state of the pixel 284a. The transistor 52B functions as a driving transistor that controls the amount of current flowing to the light-emitting device 61. The capacitor 53 has a function of retaining a gate potential of the transistor 52B. The intensity of light emitted from the light-emitting device 61 is controlled in accordance with an image signal supplied to the gate of the transistor 52B.

FIG. 25B illustrates a configuration example different from that of the pixel 284a illustrated in FIG. 25A. The pixel 284a includes a pixel circuit 283aA and the light-emitting device 61.

The pixel circuit 283aA is different from the pixel circuit 283a illustrated in FIG. 25A mainly in that the anode of the light-emitting device 61 is connected to the wiring ANO.

One of the source and the drain of the transistor 52B and one electrode of the capacitor 53 are connected to the wiring VCOM. The cathode of the light-emitting device 61 is connected to the other of the source and the drain of the transistor 52B.

In the pixel circuit 283aA, a source potential of the transistor 52B functioning as a driving transistor becomes the potential of the wiring VCOM; thus, a change in voltage (Vgs) between the gate and the source of the transistor 52B can be inhibited. Accordingly, variation in luminance can be reduced.

FIG. 25C illustrates a configuration example different from that of the pixel 284a illustrated in FIG. 25A. The pixel 284a includes a pixel circuit 283aB and the light-emitting device 61.

The pixel circuit 283aB is different from the pixel circuit 283a illustrated in FIG. 25A mainly in including a transistor 52C. The pixel circuit 283aB includes the transistor 52A, the transistor 52B, the transistor 52C, and the capacitor 53. The pixel circuit 283aB is a 3Tr1C-type pixel circuit including three transistors and one capacitor.

One of a source and a drain of the transistor 52C is connected to one of the source and the drain of the transistor 52B. The other of the source and the drain of the transistor 52C is connected to a wiring V0. A reference potential is supplied to the wiring V0, for example. A gate of the transistor 52C is connected to the wiring GL.

The transistor 52C has a function of controlling electrical continuity and discontinuity between the wiring V0 and one of the source and the drain of the transistor 52B in accordance with the potential of the wiring GL. A variation in the gate-source potential of the transistor 52B can be inhibited by the reference potential of the wiring V0 supplied through the transistor 52C.

A current value that can be used for setting pixel parameters can be obtained with the use of the wiring V0. Specifically, the wiring V0 can function as a monitor line for outputting, to the outside, current flowing to the transistor 52B or current flowing to the light-emitting device 61. Current output to the wiring V0 can be converted into voltage by a source follower circuit and can be output to the outside. Alternatively, the current can be converted into a digital signal by an A/D converter and can be output to the outside.

Some or all of the transistors included in the pixel circuit 283a can be provided with back gates. In a pixel circuit 283aC illustrated in FIG. 25D, the transistor 52B in the pixel circuit 283a illustrated in FIG. 25A includes a back gate, and the back gate is connected to one of the source and the drain of the transistor 52B. In a pixel circuit 283aD illustrated in FIG. 25E, the transistor 52B in the pixel circuit 283aB illustrated in FIG. 25C includes a back gate, and the back gate is connected to one of the source and the drain of the transistor 52B. Accordingly, the reliability can be increased. The back gate of the transistor 52B can be connected to the gate of the transistor 52B. This structure enables the transistor 52B to have a higher on-state current.

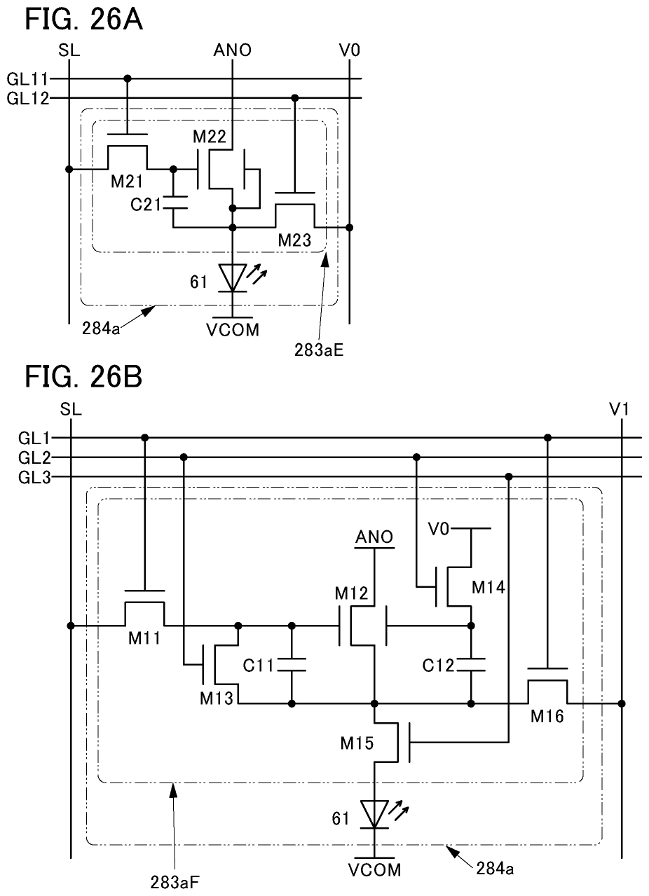

FIG. 26A illustrates a configuration example different from that of the above-described pixel 284a. The pixel 284a includes a pixel circuit 283aE and the light-emitting device 61.

The pixel circuit 283aE includes a transistor M21, a transistor M22, a transistor M23, and a capacitor C21. The pixel circuit 283aE is a 3Tr1C-type pixel circuit including three transistors and one capacitor. One of a source and a drain of the transistor M21 is connected to the wiring SL. One of a source and a drain of the transistor M22 is connected to the wiring ANO. One of a source and a drain of the transistor M23 is connected to the wiring V0. The other of the source and the drain of the transistor M21 is connected to a gate of the transistor M22 and one electrode of the capacitor C21. The other of the source and the drain of the transistor M22 is connected to the other of the source and the drain of the transistor M23, the other electrode of the capacitor C21, and the anode of the light-emitting device 61. The cathode of the light-emitting device 61 is connected to the wiring VCOM.

A gate of the transistor M21 is connected to a wiring GL11. A gate of the transistor M23 is connected to a wiring GL12. When the wiring connected to the gate of the transistor M21 and the wiring connected to the gate of the transistor M23 are different from each other, potentials with different levels can be applied to the gates of the transistors M21 and M23, so that the transistors M21 and M23 can operate independently.

The transistor M21 functions as a selection transistor, the transistor M22 functions as a driving transistor, and the capacitor C21 has a function of retaining a gate potential of the transistor M22. The intensity of light emitted from the light-emitting device 61 is controlled in accordance with an image signal supplied to the gate of the transistor M22. The description of the transistor 52C can be referred to for the transistor M23.

FIG. 26B illustrates a configuration example different from that of the above-described pixel 284a. The pixel 284a includes a pixel circuit 283aF and the light-emitting device 61.

The pixel circuit 283aF includes a transistor M11, a transistor M12, a transistor M13, a transistor M14, a transistor M15, a transistor M16, a capacitor C11, and a capacitor C12. The pixel circuit 283aF is a 6Tr2C-type pixel circuit including six transistors and two capacitors.

The anode of the light-emitting device 61 is connected to one of a source and a drain of the transistor M15. The cathode of the light-emitting device 61 is connected to the wiring VCOM. The other of the source and the drain of the transistor M15 is connected to one of a source and a drain of the transistor M12, one of a source and a drain of the transistor M13, one of a source and a drain of the transistor M16, one electrode of the capacitor C11, and one electrode of the capacitor C12. A gate of the transistor M12 is connected to one of a source and a drain of the transistor M11, the other of the source and the drain of the transistor M13, and the other electrode of the capacitor C11. A back gate of the transistor M12 is connected to one of a source and a drain of the transistor M14 and the other electrode of the capacitor C12.

The other of the source and the drain of the transistor M11 is connected to the wiring SL. The other of the source and the drain of the transistor M12 is connected to the wiring ANO. The other of the source and the drain of the transistor M14 is connected to the wiring V0. The other of the source and the drain of the transistor M16 is connected to a wiring V1. A constant potential is supplied to the wiring V1, for example. A gate of the transistor M11 and a gate of the transistor M16 are connected to a wiring GL1. A gate of the transistor M13 and a gate of the transistor M14 are connected to a wiring GL2. A gate of the transistor M15 is connected to a wiring GL3.

The transistor M11 functions as a selection transistor that controls electrical continuity and discontinuity between the gate of the transistor M12 and the wiring SL. The transistor M12 functions as a driving transistor that controls current flowing to the light-emitting device 61. The transistor M14 has a function of supplying a potential of the wiring V0 to the back gate of the transistor M12. When a constant potential is supplied to the back gate of the transistor M12, the threshold voltage can be controlled. The capacitor C11 has a function of retaining a gate potential of the transistor M12. The capacitor C12 has a function of retaining a back gate potential of the transistor M12. The pixel circuit 283aF has a function of correcting the threshold voltage of the transistor M12 with use of the back gate thereof, what is called an internal correcting function of the threshold voltage. Specifically, a back gate potential that makes the threshold voltage of the transistor M12 be 0 V is retained in the capacitor C12. Accordingly, regardless of a variation in the threshold voltage and over-time deterioration of the transistor, the threshold voltage of the transistor M12 can be corrected to be constant at 0 V or the vicinity thereof.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have significantly high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a device for VR such as a head-mounted display or a glasses-type device for AR. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device, such as a wrist watch.

### Display Device 400C

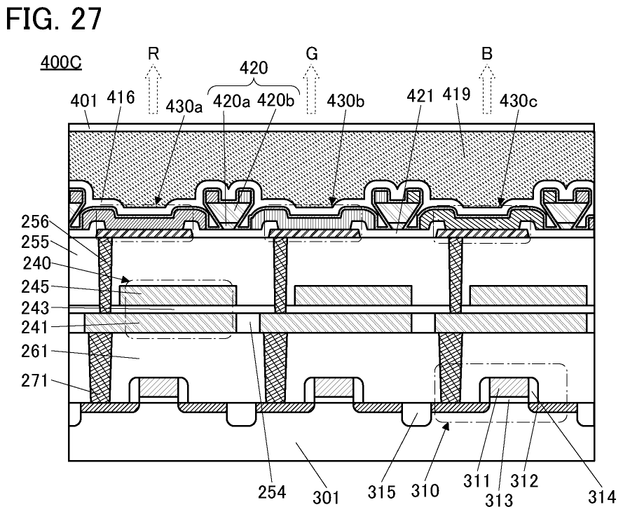

The display device 400C illustrated in FIG. 27 includes a substrate 301, the light-emitting elements 430a, 430b, and 430c, a capacitor 240, and a transistor 310.

The substrate 301 corresponds to the substrate 291 illustrated in FIGS. 24A and 24B.

The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240, and the light-emitting elements 430a, 430b, and 430c and the like are provided over the insulating layer 255. The protective layer 416 is provided over the light-emitting elements 430a, 430b, and 430c, and a substrate 401 is bonded to a top surface of the protective layer 416 with a resin layer 419. The substrate 401 corresponds to the substrate 292 in FIG. 24A.

The pixel electrode of the light-emitting element is electrically connected to the one of the source and the drain of the transistor 310 through a plug 256 embedded in the insulating layer 255, the conductive layer 241 embedded in the insulating layer 254, and the plug 271 embedded in the insulating layer 261.

The insulating layer 421 is provided to cover the end portion of each pixel electrode. An inorganic insulating material is preferably used for the insulating layer 421. For example, an inorganic insulating material such as silicon oxide, silicon nitride, or aluminum oxide can be used.

The partition 420 is provided over the insulating layer 421. For the partition 420, the description of the partition 120 in Embodiment 1 can be referred to. A layer containing the same material as the EL layers and parts of the upper electrodes of two light-emitting elements adjacent to each other with the partition 420 therebetween are provided over the partition 420.

### Display Device 400D

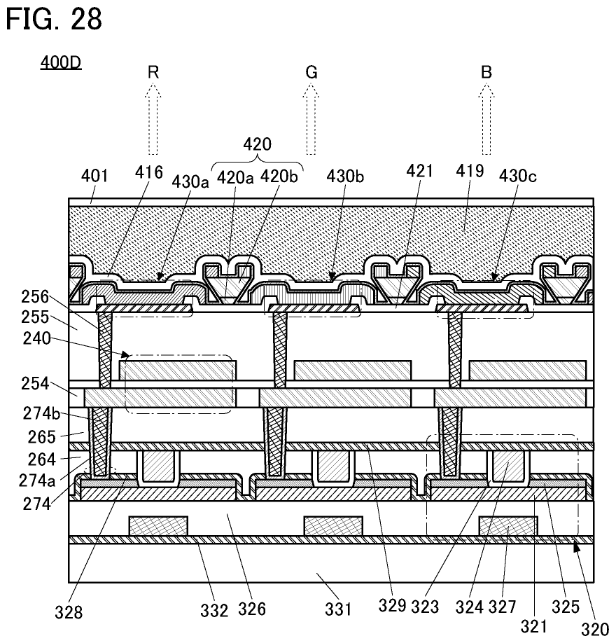

The display device 400D illustrated in FIG. 28 differs from the display device 400C mainly in transistor structure. Note that portions similar to those in the display device 400C are not described in some cases.

A transistor 320 contains a metal oxide (also referred to as an oxide semiconductor) in a semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 illustrated in FIGS. 24A and 24B. As the substrate 331, an insulating substrate or a semiconductor substrate can be used.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 which is in contact with the semiconductor layer 321. The top surface of the insulating layer 326 is preferably planarized.

The semiconductor layer 321 is provided over the insulating layer 326. A metal oxide film having semiconductor characteristics (also referred to as an oxide semiconductor film) is preferably used for the semiconductor layer 321. A material that can be used for the semiconductor layer 321 is described in detail later.

The pair of conductive layers 325 is provided over and in contact with the semiconductor layer 321, and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layers 328 and 264. The insulating layer 323 that is in contact with the side surfaces of the insulating layers 264 and 328, the side surface of the conductive layer 325, and the top surface of the semiconductor layer 321 and the conductive layer 324 fill the inside of the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are substantially level with each other, and an insulating layer 329 and an insulating layer 265 are provided to cover these layers.

The insulating layers 264 and 265 each function as an interlayer insulating layer. The insulating layer 329 functions as a barrier layer that prevents diffusion of impurities such as water or hydrogen from the insulating layer 265 or the like into the transistor 320. As the insulating layer 329, an insulating film similar to the insulating layers 328 and 332 can be used.

A plug 274 electrically connected to one of the pair of conductive layers 325 is provided to be embedded in the insulating layers 265, 329, and 264. Here, the plug 274 preferably includes a conductive layer 274a that covers the side surface of an opening formed in the insulating layers 265, 329, 264, and 328 and part of the top surface of the conductive layer 325, and a conductive layer 274b in contact with the top surface of the conductive layer 274a. For the conductive layer 274a, a conductive material in which hydrogen and oxygen are unlikely to diffuse is preferably used.

Components from the insulating layer 254 to the substrate 401 in the display device 400D are similar to those in the display device 400C.

### Display Device 400E

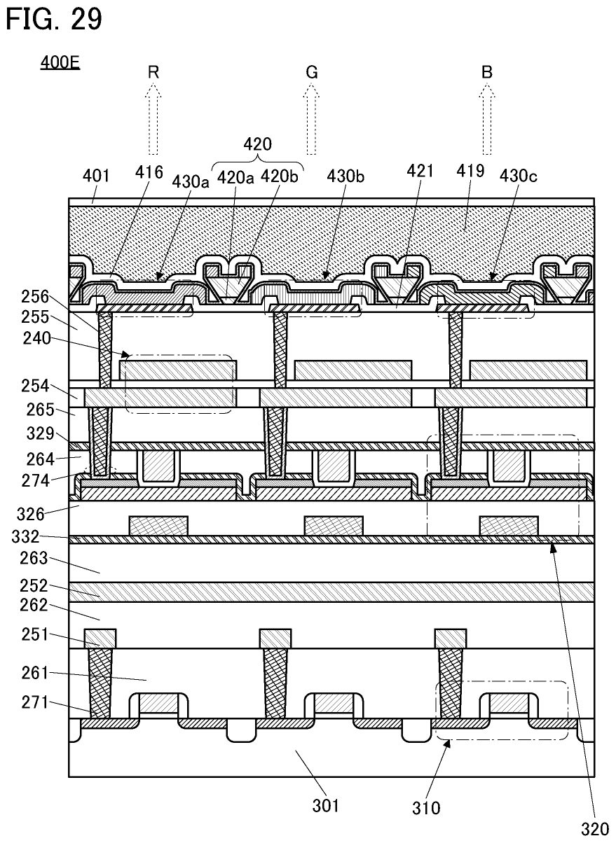

The display device 400E illustrated in FIG. 29 has a structure in which the transistor 310 whose channel is formed in the substrate 301 and the transistor 320 containing a metal oxide in the semiconductor layer where the channel is formed are stacked. Note that portions similar to those in the display devices 400C and 400D are not described in some cases.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layers 251 and 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistors 310 and 320 can also be used as transistors included in a variety of circuits such as an arithmetic circuit and a memory circuit.

With such a structure, not only the pixel circuit but also the driver circuit or the like can be formed directly under the light-emitting element; thus, the display device can be downsized as compared with the case where the driver circuit is provided around a display region.

At least part of any of the structure examples, the drawings corresponding thereto, and the like described in this embodiment can be combined with any of the other structure examples, the other drawings corresponding thereto, and the like as appropriate.

At least part of this embodiment can be implemented as appropriate in combination with any of the other embodiments described in this specification.

### Embodiment 4

In this embodiment, a light-emitting element (also referred to as a light-emitting device) that can be used in the display device of one embodiment of the present invention will be described.

In this specification and the like, a light-emitting device (also referred to as a light-emitting element) includes an EL layer between a pair of electrodes. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a device formed using a metal mask or a fine metal mask (FMM, a high-resolution metal mask) is sometimes referred to as a device having a metal mask (MM) structure. In this specification and the like, a device formed without using a metal mask or an FMM is sometimes referred to as a device having a metal maskless (MML) structure.

In this specification and the like, a structure in which light-emitting layers in light-emitting devices of different colors (here, blue (B), green (G), and red (R)) are separately formed or separately patterned may be referred to as a side-by-side (SBS) structure. The SBS structure can optimize materials and structures of light-emitting devices and thus can extend the freedom of choices of materials and structures, whereby the luminance and the reliability can be easily improved. In this specification and the like, a light-emitting device capable of emitting white light may be referred to as a white-light-emitting device. Note that a combination of white light-emitting devices with coloring layers (e.g., color filters) enables a full-color display device.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other. One layer may have two or three functions of the carrier-injection layer, the carrier-transport layer, and the carrier-blocking layer in some cases.

### Light-Emitting Device

Structures of light-emitting devices can be classified roughly into a single structure and a tandem structure. A light-emitting device having a single structure includes one light-emitting unit between a pair of electrodes. The light-emitting unit includes one or more light-emitting layers. To obtain white light emission with a single structure, two or more light-emitting layers can be selected such that emission of the light-emitting layers can produce white color. For example, in the case of two colors, when emission colors of a first light-emitting layer and a second light-emitting layer are complementary colors, the light-emitting device can be configured to emit white light as a whole. To obtain white light emission by using three or more light-emitting layers, the light-emitting device can be configured to emit white light as a whole by combining emission colors of the three or more light-emitting layers.

A light-emitting device having a tandem structure includes a plurality of light-emitting units between a pair of electrodes. Each light-emitting unit includes one or more light-emitting layers. When light-emitting layers that emit light of the same color are used in each light-emitting unit, luminance per predetermined current can be increased, and the light-emitting device can have higher reliability than that with a single structure. To obtain white light emission with a tandem structure, the light-emitting device can be configured to emit white light by combining light from light-emitting layers of a plurality of light-emitting units. Note that a combination of emission colors for obtaining white light emission is similar to that for a single structure. In the light-emitting device with a tandem structure, it is preferable that an intermediate layer such as a charge-generation layer be provided between the plurality of light-emitting units.

When a white-light-emitting device and a light-emitting device with an SBS structure are compared with each other, the latter can have lower power consumption than the former. Meanwhile, the white-light-emitting device is preferable in terms of lower manufacturing cost and higher manufacturing yield because the manufacturing process of the white-light-emitting device is simpler than that of the light-emitting device with the SBS structure.

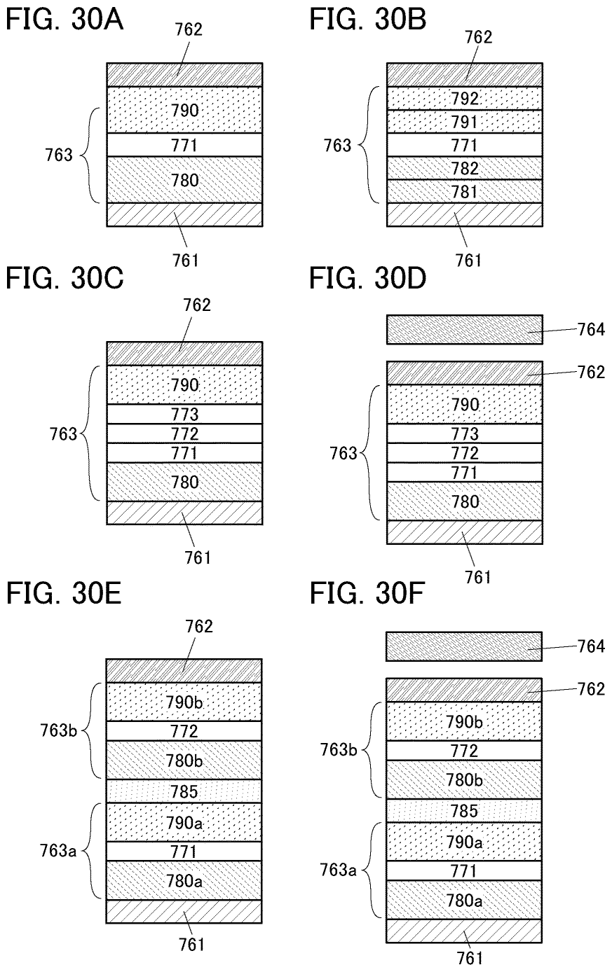

As illustrated in FIG. 30A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (hole-injection layer), a layer containing a substance having a high hole-transport property (hole-transport layer), and a layer containing a substance having a high electron-blocking property (electron-blocking layer). Furthermore, the layer 790 includes one or more of a layer containing a substance having a high electron-injection property (electron-injection layer), a layer containing a substance having a high electron-transport property (electron-transport layer), and a layer containing a substance having a high hole-blocking property (hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790, which is provided between the pair of electrodes, can function as a single light-emitting unit, and the structure in FIG. 30A is referred to as a single structure in this specification.

FIG. 30B is a modification example of the EL layer 763 included in the light-emitting device illustrated in FIG. 30A. Specifically, the light-emitting device illustrated in FIG. 30B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected into the light-emitting layer 771, and the efficiency of the recombination of carriers in the light-emitting layer 771 can be enhanced.

Note that structures in which a plurality of light-emitting layers (the light-emitting layer 771 and light-emitting layers 772 and 773) are provided between the layer 780 and the layer 790 as illustrated in FIGS. 30C and 30D are variations of a single structure. Although FIGS. 30C and 30D each illustrate an example in which three light-emitting layers are included, the number of light-emitting layers in a light-emitting device with a single structure may be two or four or more.

In addition, the light-emitting device with a single structure may include a buffer layer between two light-emitting layers.

A structure in which a plurality of light-emitting units (a light-emitting unit 763a and a light-emitting unit 763b) are connected in series through a charge-generation layer 785 (also referred to as an intermediate layer) as illustrated in FIGS. 30E and 30F is referred to as a tandem structure in this specification. The tandem structure can be rephrased as a stack structure. The tandem structure enables a light-emitting device to emit light with high luminance. Furthermore, the amount of current needed for obtaining a predetermined luminance can be smaller in the tandem structure than in the single structure; thus, the tandem structure enables higher reliability.

FIGS. 30D and 30F each illustrate an example in which the display device includes a layer 764 overlapping with the light-emitting device. FIG. 30D is an example in which the layer 764 overlaps with the light-emitting device illustrated in FIG. 30C, and FIG. 30F illustrates an example in which the layer 764 overlaps with the light-emitting device illustrated in FIG. 30E. In FIGS. 30D and 30F, a conductive film that transmits visible light is used for the upper electrode 762 so that light is extracted from the upper electrode 762 side.

One or both of a color conversion layer and a color filter (coloring layer) can be used as the layer 764.

In FIGS. 30C and 30D, light-emitting substances that emit light of the same color or the same light-emitting substance may be used for the light-emitting layers 771, 772, and 773. For example, a light-emitting substance that emits blue light may be used for the light-emitting layers 771, 772, and 773. In a subpixel that exhibits blue light, blue light from the light-emitting device can be extracted as it is. In a subpixel that exhibits red light and a subpixel that exhibits green light, respective color conversion layers are provided as the layer 764 illustrated in FIG. 30D, whereby blue light emitted by light-emitting devices can be converted into light with a longer wavelength and thus red light or green light can be extracted. As the layer 764, both a color conversion layer and a coloring layer are preferably used. In some cases, part of light emitted from the light-emitting device is transmitted through the color conversion layer without being converted. When light passing through the color conversion layer is extracted through the coloring layer, light other than light of a desired color can be absorbed by the coloring layer, and color purity of light exhibited by a subpixel can be improved.

In FIGS. 30C and 30D, light-emitting substances that emit light of different colors may be used for the light-emitting layers 771, 772, and 773. White light emission can be obtained by selecting the light-emitting layers 771, 772, and 773 so that emission of the light-emitting layers can produce white color. The light-emitting device with a single structure preferably includes a light-emitting layer containing a light-emitting substance that emits blue light and a light-emitting layer containing a light-emitting substance that emits visible light with a longer wavelength than blue light, for example.

A color filter may be provided as the layer 764 illustrated in FIG. 30D. When white light passes through a color filter, light of a desired color can be obtained.

In the case where the light-emitting device with a single structure includes three light-emitting layers, for example, a light-emitting layer containing a light-emitting substance that emits red (R) light, a light-emitting layer containing a light-emitting substance that emits green (G) light, and a light-emitting layer containing a light-emitting substance that emits blue (B) light are preferably included. The stacking order of the light-emitting layers can be RGB or RBG from an anode side, for example. In that case, a buffer layer may be provided between R and G or between R and B.

In the case where the light-emitting device with a single structure includes two light-emitting layers, for example, a light-emitting layer containing a light-emitting substance that emits blue (B) light and a light-emitting layer containing a light-emitting substance that emits yellow (Y) light are preferably included. Such a structure may be referred to as a BY single structure.

A light-emitting device that emits white light preferably contains two or more kinds of light-emitting substances. To obtain white light emission, two or more light-emitting substances can be selected such that emission of the light-emitting substances can produce white color. For example, when emission colors of a first light-emitting layer and a second light-emitting layer are complementary colors, a light-emitting device that emits white light as a whole can be obtained. To obtain white light emission by using three or more light-emitting layers, the light-emitting device can be configured to emit white light as a whole by combining emission colors of the three or more light-emitting layers.

In FIGS. 30C and 30D, the layers 780 and 790 may each have a stacked-layer structure of two or more layers as illustrated in FIG. 30B.

In FIGS. 30E and 30F, light-emitting substances that emit light of the same color, or moreover, the same light-emitting substance may be used for the light-emitting layers 771 and 772. For example, in light-emitting devices included in subpixels that exhibit light of different colors, a light-emitting substance that emits blue light can be used for each of the light-emitting layers 771 and 772. In a subpixel that exhibits blue light, blue light from the light-emitting device can be extracted as it is. In each of the subpixel that exhibits red light and the subpixel that exhibits green light, a color conversion layer is provided as the layer 764 illustrated in FIG. 30F for converting blue light from the light-emitting device into light with a longer wavelength, so that red light or green light can be extracted. As the layer 764, both a color conversion layer and a coloring layer are preferably used.

In FIGS. 30E and 30F, light-emitting substances that emit light of different colors may be used for the light-emitting layers 771 and 772. When the light-emitting layers 771 and 772 emit light of complementary colors, white light emission can be obtained. As the layer 764 illustrated in FIG. 30F, a color filter may be provided. When white light passes through a color filter, light of a desired color can be obtained.

Although FIGS. 30E and 30F each illustrate an example in which the light-emitting unit 763a includes one light-emitting layer 771 and the light-emitting unit 763b includes one light-emitting layer 772, one embodiment of the present invention is not limited thereto. Each of the light-emitting units 763a and 763b may include two or more light-emitting layers.

Although FIGS. 30E and 30F each illustrate an example of a light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In each of FIGS. 30E and 30F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layers 780a and 780b each include one or more of a hole-injection layer, a hole-transport layer, and an electron-blocking layer. Furthermore, the layers 790a and 790b each include one or more of an electron-injection layer, an electron-transport layer, and a hole-blocking layer. In the case where the lower electrode 761 is a cathode and the upper electrode 762 is an anode, the structures of the layers 780a and 790a are interchanged and the structures of the layers 780b and 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing the light-emitting device with a tandem structure, two light-emitting units are stacked with the charge-generation layer 785 therebetween. The charge-generation layer 785 has a function of injecting electrons into one of the two light-emitting units and injecting holes into the other when voltage is applied between the pair of electrodes.

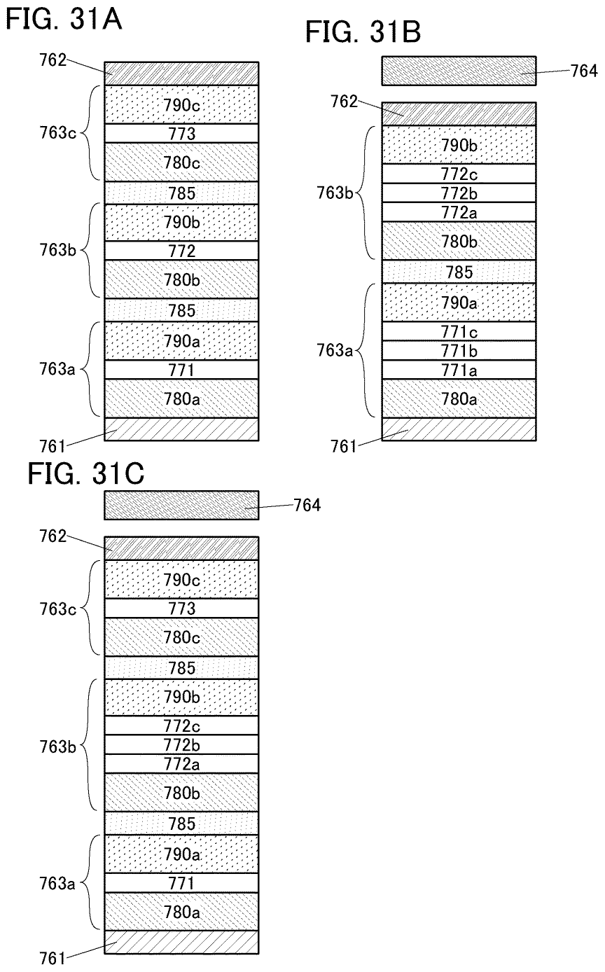

Examples of the light-emitting device with a tandem structure are structures illustrated in FIGS. 31A to 31C.

FIG. 31A illustrates a structure including three light-emitting units. In the structure illustrated in FIG. 31A, a plurality of light-emitting units (the light-emitting units 763a and 763b and a light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layers 780a and 780b, and the layer 790c can have a structure applicable to the layers 790a and 790b.

In FIG. 31A, the light-emitting layers 771, 772, and 773 can contain light-emitting substances that emit light of the same color. Specifically, the light-emitting layers 771, 772, and 773 can each contain a blue (B) light-emitting substance (i.e., a B/B/B three-unit tandem structure). Note that “b/a” means that a light-emitting unit containing a light-emitting substance that emits light of the color “b” is provided over a light-emitting unit containing a light-emitting substance that emits light of the color “a” with a charge-generation layer therebetween.

In FIG. 31A, light-emitting substances that emit light of different colors may be used for some or all of the light-emitting layers 771, 772, and 773. Examples of the combination of emission colors for the light-emitting layers 771, 772, and 773 include blue (B) for two of them and yellow (Y) for the other; and red (R) for one of them, green (G) for another, and blue (B) for the other.

Note that the structure containing the light-emitting substances that emit light of the same color is not limited to the above structure. For example, a light-emitting device with a tandem structure may be employed in which light-emitting units each including a plurality of light-emitting layers are stacked as illustrated in FIG. 31B. FIG. 31B illustrates a structure in which two light-emitting units (the light-emitting units 763a and 763b) are connected in series through the charge-generation layer 785. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 31B, the light-emitting unit 763a is configured to emit white (W) light by selecting light-emitting substances for the light-emitting layers 771a, 771b, and 771c such that their emission colors produce white in combination. In addition, the light-emitting unit 763b is configured to emit white (W) light by selecting light-emitting substances for the light-emitting layers 772a, 772b, and 772c such that their emission colors produce white in combination. This means that the structure illustrated in FIG. 31B is a two-unit tandem structure of W/W. There is no particular limitation on the stacking order of the light-emitting substances. The practitioner can select the optimal stacking order as appropriate. Although not illustrated, a W/W/W three-unit tandem structure or a tandem structure with four or more units may be employed.

In the case of a light-emitting device with a tandem structure, any of the following structures may be employed, for example: a B/Y or Y/B two-unit tandem structure including a light-emitting unit that emits yellow (Y) light and a light-emitting unit that emits blue (B) light; a R·G/B or B/R·G two-unit tandem structure including a light-emitting unit that emits red (R) and green (G) light and a light-emitting unit that emits blue (B) light; a B/Y/B three-unit tandem structure including a light-emitting unit that emits blue (B) light, a light-emitting unit that emits yellow (Y) light, and a light-emitting unit that emits blue (B) light in this order; a B/YG/B three-unit tandem structure including a light-emitting unit that emits blue (B) light, a light-emitting unit that emits yellow-green (YG) light, and a light-emitting unit that emits blue (B) light in this order; and a B/G/B three-unit tandem structure including a light-emitting unit that emits blue (B) light, a light-emitting unit that emits green (G) light, and a light-emitting unit that emits blue (B) light in this order. Note that “a×b” means that one light-emitting unit contains a light-emitting substance that emits light of the color “a” and a light-emitting substance that emits light of the color “b”.

As illustrated in FIG. 31C, a light-emitting unit including one light-emitting layer and a light-emitting unit including a plurality of light-emitting layers may be used in combination.

Specifically, in the structure illustrated in FIG. 31C, a plurality of light-emitting units (the light-emitting units 763a, 763b, and 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure illustrated in FIG. 31C can be, for example, a B/R·G·YG/B three-unit tandem structure in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device will be described.

A conductive film that transmits visible light is used for the electrode through which light is extracted, which is either the lower electrode 761 or the upper electrode 762. A conductive film that reflects visible light is preferably used for the electrode through which light is not extracted. In the case where the display device includes a light-emitting device that emits infrared light, it is preferable that a conductive film that transmits visible light and infrared light be used for the electrode through which light is extracted, and a conductive film that reflects visible light and infrared light be used for the electrode through which light is not extracted.

A conductive film that transmits visible light may be used also for the electrode through which light is not extracted. In that case, the electrode is preferably provided between a reflective layer and the EL layer 763. In other words, light emitted from the EL layer 763 may be reflected by the reflective layer to be extracted from the display device.

As a material for the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include an indium tin oxide (In—Sn oxide, also referred to as ITO), an indium tin oxide containing silicon (In—Si—Sn oxide, also referred to as ITSO), an indium zinc oxide (In—Zn oxide), and an In—W—Zn oxide. Other examples of the material include an alloy containing aluminum (aluminum alloy), such as an alloy of aluminum, nickel, and lanthanum (Al—Ni—La), an alloy of silver and magnesium (Ag—Mg), and an alloy of silver, palladium, and copper (Ag—Pd—Cu, also referred to as APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting device preferably employs a microcavity structure. Thus, one of the pair of electrodes of the light-emitting device is preferably an electrode having properties of transmitting and reflecting visible light (transflective electrode), and the other is preferably an electrode having a property of reflecting visible light (reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer containing any of a substance having a high hole-injection property, a substance having a high hole-transport property, a hole-blocking material, a substance having a high electron-transport property, an electron-blocking material, a substance having a high electron-injection property, a substance having a bipolar property (a substance with high electron- and hole-transport properties), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer contains one or more kinds of light-emitting substances. As the light-emitting substance, a substance whose emission color is blue, violet, bluish violet, green, yellowish green, yellow, orange, red, or the like is appropriately used. As the light-emitting substance, a substance that emits near-infrared light can also be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; an iridium complex; and a rare earth metal complex.

The light-emitting layer may contain one or more kinds of organic compounds (e.g., a host material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material with a high hole-transport property which can be used for the hole-transport layer and will be described later. As the electron-transport material, it is possible to use a material with a high electron-transport property which can be used for the electron-transport layer and will be described later. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (the phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

A hole-injection layer injects holes from an anode to a hole-transport layer and contains a material with a high hole-injection property. Examples of the material with a high hole-injection property include an aromatic amine compound and a composite material containing a hole-transport material and an acceptor material (electron-accepting material).

As the hole-transport material, it is possible to use a material with a high hole-transport property which can be used for the hole-transport layer and will be described later.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used.

As the material with a high hole-injection property, a material that contains a hole-transport material and the above-described oxide of a metal belonging to Group 4 to Group 8 of the periodic table (typified by molybdenum oxide) may be used, for example.

The hole-transport layer transports holes, which are injected from the anode by the hole-injection layer, to the light-emitting layer. The hole-transport layer contains a hole-transport material. The hole-transport material preferably has a hole mobility higher than or equal to 1×10⁻⁶ cm²/Vs. Note that other substances can also be used as long as the substances have a hole-transport property higher than an electron-transport property. The hole-transport material is preferably a material with a high hole-transport property, such as a π-electron rich heteroaromatic compound (e.g., a carbazole derivative, a thiophene derivative, and a furan derivative) or an aromatic amine (a compound having an aromatic amine skeleton).

The electron-blocking layer is provided in contact with the light-emitting layer. The electron-blocking layer has a hole-transport property and contains a material that can block an electron. Among the above-described hole-transport materials, a material with an electron-blocking property can be used for the electron-blocking layer.

Since the electron-blocking layer has a hole-transport property, the electron-blocking layer can also be referred to as a hole-transport layer. A hole-transport layer with an electron-blocking property can be referred to as an electron-blocking layer.

The electron-transport layer transports electrons, which are injected from the cathode by the electron-injection layer, to the light-emitting layer. The electron-transport layer contains an electron-transport material. The electron-transport material preferably has an electron mobility higher than or equal to 1×10⁻⁶ cm²/Vs. Note that other substances can also be used as long as the substances have an electron-transport property higher than a hole-transport property. The electron-transport material can be a material with a high electron-transport property, e.g., a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer has an electron-transport property and contains a material that can block a hole. Among the above-described electron-transport materials, a material with a hole-blocking property can be used for the hole-blocking layer.

Since the hole-blocking layer has an electron-transport property, the hole-blocking layer can also be referred to as an electron-transport layer. An electron-transport layer with a hole-blocking property can be referred to as a hole-blocking layer.

An electron-injection layer injects electrons from a cathode to an electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The lowest unoccupied molecular orbital (LUMO) level of the material with a high electron-injection property preferably has a small difference (specifically, 0.5 eV or less) from the work function of a material for the cathode.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where x is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. An example of the stacked-layer structure is a structure in which lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the LUMO level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition temperature (T_{g}) than BPhen and thus has high heat resistance.

The charge-generation layer preferably includes a p-type layer. The p-type layer preferably contains an acceptor material. For example, the p-type layer preferably contains the above-described hole-transport material and acceptor material that can be used for the hole-injection layer.

The charge-generation layer preferably includes a layer containing a material with a high electron-injection property. The layer can also be referred to as an electron-injection buffer layer or an n-type layer. The electron-injection buffer layer is preferably provided between the p-type layer and the electron-transport layer. With use of the electron-injection buffer layer, an injection barrier between the p-type layer and the electron-transport layer can be lowered; thus, electrons generated in the p-type layer can be easily injected into the electron-transport layer.

The electron-injection buffer layer preferably contains an alkali metal or an alkaline earth metal, and can contain an alkali metal compound or an alkaline earth metal compound, for example. Specifically, the electron-injection buffer layer preferably contains an inorganic compound containing an alkali metal and oxygen or an inorganic compound containing an alkaline earth metal and oxygen, and further preferably contains an inorganic compound containing lithium and oxygen (e.g., lithium oxide (Li₂O)). Alternatively, the above-described material that can be used for the electron-injection layer can be favorably used for the electron-injection buffer layer.

The charge-generation layer preferably includes a layer containing a material with a high electron-transport property. The layer can also be referred to as an electron-relay layer. The electron-relay layer is preferably provided between the p-type layer and the electron-injection buffer layer. In the case where the charge-generation layer does not include an electron-injection buffer layer, the electron-relay layer is preferably provided between the p-type layer and the electron-transport layer. The electron-relay layer has a function of preventing an interaction between the p-type layer and the electron-injection buffer layer (or the electron-transport layer) and transferring electrons smoothly.

For the electron-relay layer, a phthalocyanine-based material such as copper(II) phthalocyanine (abbreviation: CuPc), or a metal complex having a metal-oxygen bond and an aromatic ligand is preferably used.

Note that the p-type layer, the electron-injection buffer layer, and the electron-relay layer cannot be clearly distinguished from one another on the basis of the cross-sectional shape or properties in some cases.

When the charge-generation layer is provided between two light-emitting units to be stacked, an increase in driving voltage can be inhibited.

At least part of this embodiment can be implemented as appropriate in combination with any of the other embodiments described in this specification.

### Embodiment 5

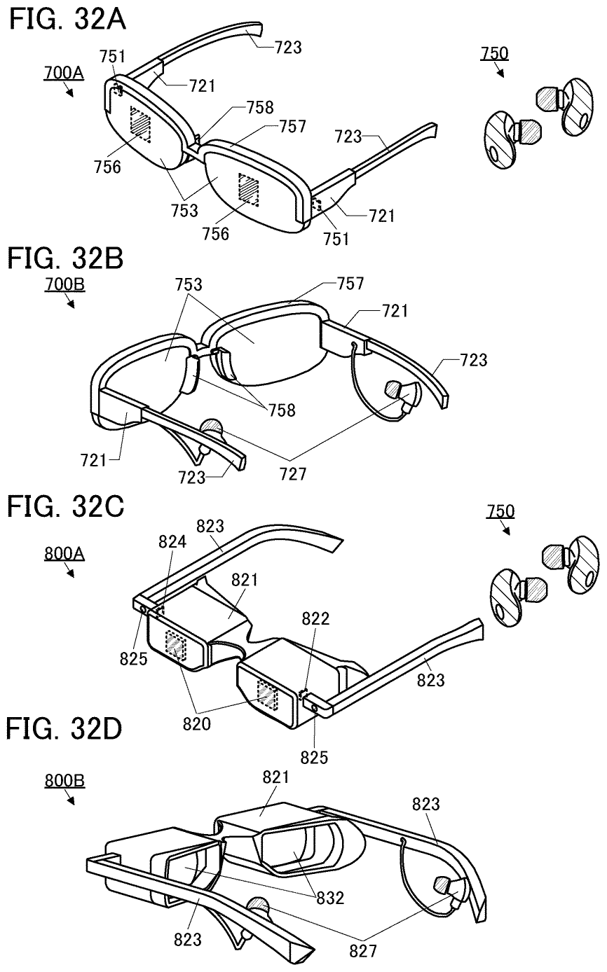

In this embodiment, electronic devices of one embodiment of the present invention will be described with reference to FIGS. 32A to 32D, FIGS. 33A to 33F, and FIGS. 34A to 34G.

Electronic devices in this embodiment each include the display panel (display device) of one embodiment of the present invention in a display portion. The display panel of one embodiment of the present invention can be easily increased in resolution and definition and can achieve high display quality. Thus, the display panel of one embodiment of the present invention can be used for display portions of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television apparatus, desktop and laptop personal computers, a monitor of a computer and the like, digital signage, and a large game machine like a pachinko machine.

In particular, the display panel of one embodiment of the present invention can have high resolution, and thus can be favorably used for an electronic device having a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display panel of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display panel of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display panel having one or both of such high definition and high resolution can further increase realistic sensation, sense of depth, and the like. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices capable of being worn on a head are described with reference to FIGS. 32A to 32D. The wearable devices have one or both of a function of displaying AR content and a function of displaying VR content. Note that these wearable devices may have a function of displaying SR or MR content, in addition to AR and VR content. The electronic device having a function of displaying content of at least one of AR, VR, SR, MR, and the like enables the user to feel a higher level of immersion.

An electronic device 700A illustrated in FIG. 32A and an electronic device 700B illustrated in FIG. 32B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display panel of one embodiment of the present invention can be used for the display panels 751. Thus, the electronic devices are capable of performing ultrahigh-resolution display.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are capable of AR display.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic devices 700A and 700B are provided with a battery, so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be used for the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 32C and an electronic device 800B illustrated in FIG. 32D each include a pair of display portions 820, a housing 821, a communication portion 822, a pair of wearing portions 823, a control portion 824, a pair of image capturing portions 825, and a pair of lenses 832.

The display panel of one embodiment of the present invention can be used in the display portions 820. Thus, the electronic devices are capable of performing ultrahigh-resolution display. Such electronic devices provide a high sense of immersion to the user.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user who wears the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 32C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example in which the image capturing portion 825 is provided is illustrated here, a range sensor (hereinafter also referred to as a sensing portion) capable of measuring a distance to an object may be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic devices 800A and 800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 32A has a function of transmitting information to the earphones 750 with the wireless communication function. As another example, the electronic device 800A in FIG. 32C has a function of transmitting information to the earphones 750 with the wireless communication function.

The electronic device may include an earphone portion. The electronic device 700B illustrated in FIG. 32B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B illustrated in FIG. 32D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 700A and 700B) and the goggles-type device (e.g., the electronic devices 800A and 800B) are preferable as the electronic device of one embodiment of the present invention.

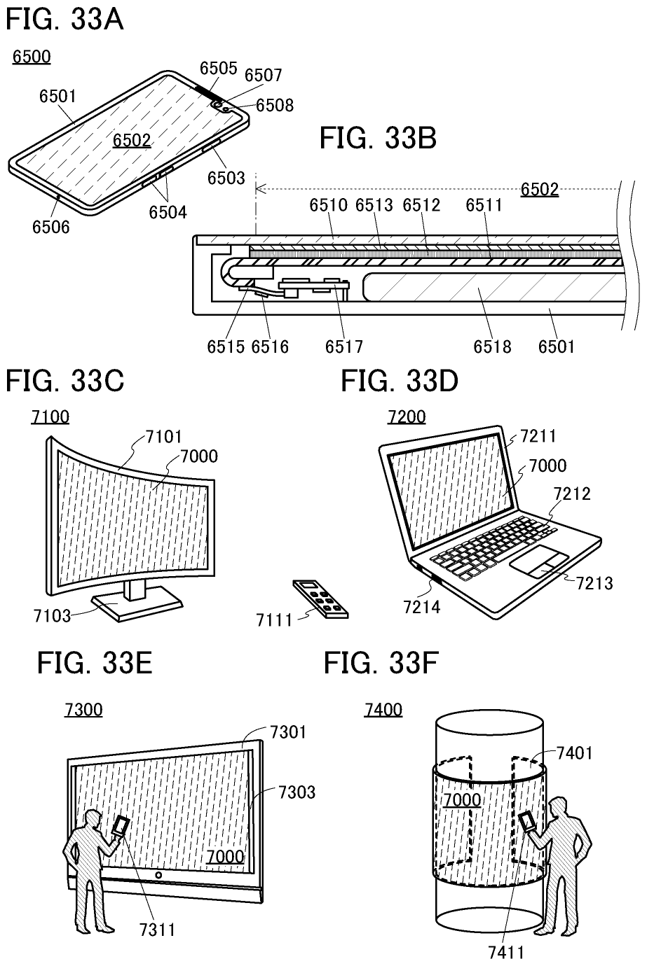

An electronic device 6500 illustrated in FIG. 33A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display panel of one embodiment of the present invention can be used in the display portion 6502.

FIG. 33B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used as the display panel 6511. Thus, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 33C illustrates an example of a television apparatus. In a television apparatus 7100, a display portion 7000 is incorporated in a housing 7101. Here, the housing 7101 is supported by a stand 7103.

Operation of the television apparatus 7100 illustrated in FIG. 33C can be performed with an operation switch provided in the housing 7101 and a separate remote control 7111. Alternatively, the display portion 7000 may include a touch sensor, and the television apparatus 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television apparatus 7100 includes a receiver, a modem, and the like. A general television broadcast can be received with the receiver. When the television apparatus is connected to a communication network by wire or wirelessly via the modem, one-way (from a transmitter to a receiver) or two-way (between a transmitter and a receiver or between receivers, for example) information communication can be performed.

FIG. 33D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

FIGS. 33E and 33F illustrate examples of digital signage.

Digital signage 7300 illustrated in FIG. 33E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 33F illustrates digital signage 7400 attached to a cylindrical pillar 7401. The digital signage 7400 includes the display portion 7000 provided along a curved surface of the pillar 7401.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 33E and 33F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

The display panel of one embodiment of the present invention can be used in the display portion 7000 illustrated in each of FIGS. 33C to 33F.

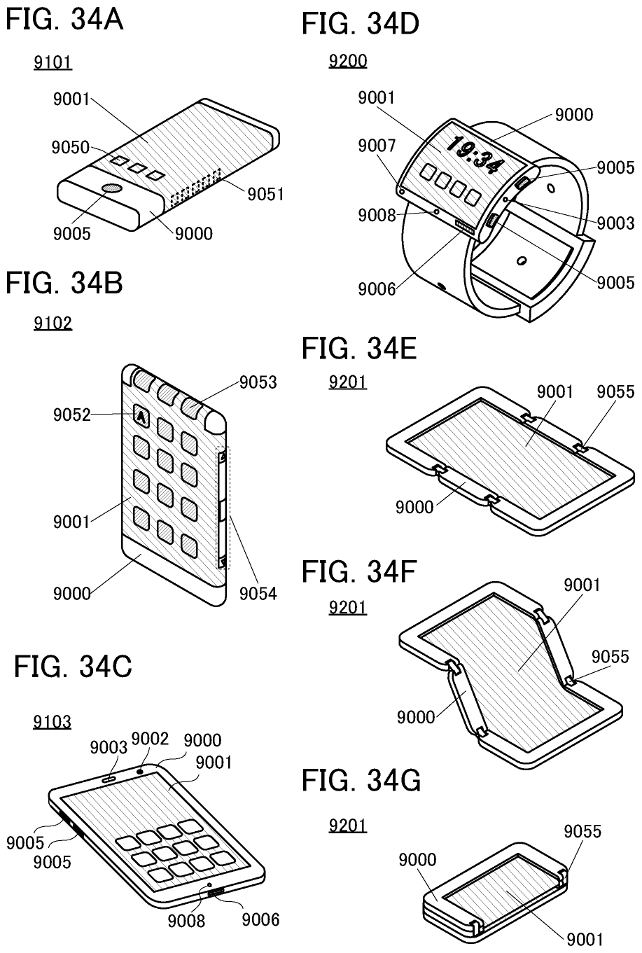

Electronic devices illustrated in FIGS. 34A to 34G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic devices illustrated in FIGS. 34A to 34G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image and storing the captured image in a storage medium (an external storage medium or a storage medium incorporated in the camera), a function of displaying the captured image on the display portion, and the like.

The electronic devices illustrated in FIGS. 34A to 34G are described in detail below.

FIG. 34A is a perspective view of a portable information terminal 9101. The portable information terminal 9101 can be used as a smartphone, for example. The portable information terminal 9101 may include the speaker 9003, the connection terminal 9006, the sensor 9007, and the like. The portable information terminal 9101 can display text and image information on its plurality of surfaces. FIG. 34A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 34B is a perspective view of a portable information terminal 9102. The portable information terminal 9102 has a function of displaying information on three or more surfaces of the display portion 9001. In the example illustrated here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 34C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 34D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 34E to 34G are perspective views of a foldable portable information terminal 9201. FIG. 34E is a perspective view illustrating the portable information terminal 9201 that is opened. FIG. 34G is a perspective view illustrating the portable information terminal 9201 that is folded. FIG. 34F is a perspective view illustrating the portable information terminal 9201 that is shifted from one of the states in FIGS. 34E and 34G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

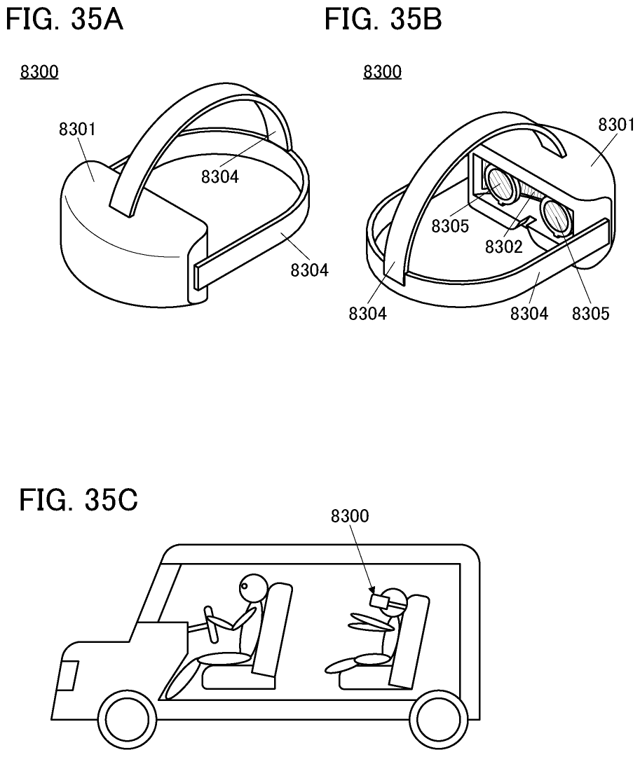

FIG. 35A and FIG. 35B are external views of a head-mounted display 8300. The head-mounted display 8300 includes a housing 8301, a display portion 8302, a band-like fixing member 8304, and a pair of lenses 8305.

A user can see display on the display portion 8302 through the lenses 8305. The display portion 8302 is preferably curved because the user can feel a high realistic sensation. When another image displayed in another region of the display portion 8302 is viewed through the lenses 8305, three-dimensional display using parallax or the like can be performed. Note that the number of the display portions 8302 is not limited to one; two display portions 8302 may be provided for user's respective eyes.

The display device of one embodiment of the present invention can be used for the display portion 8302. The display device of one embodiment of the present invention can have an extremely high resolution. Thus, a pixel is not easily seen by the user even when the user sees display that is magnified by the use of the lenses 8305. In other words, an image with a strong sense of reality can be seen by the user with use of the display portion 8302.

The head-mounted display 8300 preferably has a head tracking function and an eye tracking function. Accordingly, an image displayed can be moved in accordance with the movement of the user and the line of sight of the user. Thus, a highly immersive image can be provided to the user. For example, as illustrated in FIG. 35C, a passenger in the rear seat of a car can wear the head-mounted display 8300. In that case, moving an image in synchronization with the shaking of the car body and not fixing the line of sight, for example, can reduce car sickness as compared with the case where the passenger sees an image with a smartphone, a tablet terminal, or the like.

At least part of this embodiment can be implemented as appropriate in combination with any of the other embodiments described in this specification.

### Embodiment 6

In this embodiment, an indium oxide film that can be used for the semiconductor layer of the transistor included in the display device of one embodiment of the present invention will be described.

In this specification and the like, indium oxide including at least a crystal part or a crystal region in a film is referred to as crystal IO or crystalline IO. Examples of crystal IO or crystalline IO include single crystal indium oxide, polycrystal indium oxide, and microcrystal indium oxide.

Indium oxide is a semiconductor material having physical properties completely different from those of an oxide semiconductor such as In—Ga—Zn oxide (hereinafter, also referred to as IGZO) or zinc oxide.

The dependence of the Hall mobility on the carrier concentration of indium oxide, silicon, and IGZO will be described.

IGZO has a tendency in which the Hall mobility is higher as the carrier concentration is higher. By contrast, single crystal indium oxide has a tendency in which the Hall mobility is higher as the carrier concentration is lower. This tendency is similar to that of silicon; as the concentration of a dopant (impurity) in a material is lower, impurity scattering is inhibited more and thus the Hall mobility is higher. That is, single crystal indium oxide having higher purity and being more intrinsic has higher Hall mobility. Consequently, the physical properties of single crystal indium oxide are different from those of IGZO and similar to those of silicon. Note that the tendency of non-single-crystal (e.g., polycrystal) indium oxide is sometimes different from that of single crystal indium oxide.

A carrier concentration range suitable for a channel formation region of a transistor is a range including a carrier concentration of 1×10¹⁵ cm⁻³, e.g., a range with a carrier concentration higher than or equal to 1×10¹⁴ cm⁻³ and lower than or equal to 1×10¹⁸ cm⁻³. The adequately lowered carrier concentration can increase the Hall mobility to approximately 270 cm²/(V·s).

Indium oxide can include an element that reduces the carrier concentration. Examples of the element that reduces the carrier concentration include magnesium, calcium, zinc, cadmium, and copper. When indium is replaced with any of these elements, the carrier concentration can be reduced. Other examples include nitrogen, phosphorus, arsenic, and antimony. When oxygen is replaced with any of these elements, the carrier concentration can be reduced.

The element that reduces the carrier concentration can be regarded as an element that imparts p-type conductivity. When the element that reduces the carrier concentration is added to an indium oxide film, the indium oxide film is easily i-type or substantially i-type in some cases. In that case, the concentration of the element that reduces the carrier concentration in the indium oxide film is preferably higher than or equal to 1×10¹⁶ atoms/cm³ and lower than or equal to 8×10²⁰ atoms/cm³, more preferably higher than or equal to 1×10¹⁶ atoms/cm³ and lower than or equal to 4×10²⁰ atoms/cm³, further preferably higher than or equal to 1×10¹⁶ atoms/cm³ and lower than or equal to 8×10¹⁹ atoms/cm³, still more preferably higher than or equal to 1×10¹⁶ atoms/cm³ and lower than or equal to 5×10¹⁹ atoms/cm³. With such a concentration, the carrier concentration can be reduced while the crystal structure of indium oxide is maintained.

By contrast, an increase in carrier concentration can reduce electrical resistance. A carrier concentration range suitable for a source region and a drain region of a transistor, a resistor, or a transparent conductive film is, for example, a range including a carrier concentration of 1×10²⁰ cm⁻³, e.g., a range with a carrier concentration higher than or equal to 1×10¹⁹ cm⁻³ and lower than or equal to 1×10²² cm⁻³. The adequately increased carrier concentration can decrease the resistivity to 1×10⁻⁴ Ω·cm or lower.

Indium oxide can include an element that increases the carrier concentration. For example, the same element as a source electrode and a drain electrode of a transistor is preferably included. Examples of the element that increases the carrier concentration include titanium, zirconium, hafnium, tantalum, tungsten, molybdenum, tin, silicon, and boron. It is particularly preferable that an oxide of the element have conductivity or semiconductor properties.

The element that increases the carrier concentration can also be regarded to as an element that imparts n-type conductivity. The concentration of the element that increases the carrier concentration in the indium oxide film is preferably higher than or equal to 1×10¹⁶ atoms/cm³ and lower than or equal to 8×10²⁰ atoms/cm³, more preferably higher than or equal to 1×10¹⁶ atoms/cm³ and lower than or equal to 4×10²⁰ atoms/cm³, further preferably higher than or equal to 1×10¹⁶ atoms/cm³ and lower than or equal to 8×10¹⁹ atoms/cm³, still more preferably higher than or equal to 1×10¹⁶ atoms/cm³ and lower than or equal to 5×10¹⁹ atoms/cm³. With such a concentration, the carrier concentration can be increased while the crystal structure of indium oxide is maintained. Note that antimony sometimes functions as an element that increases the carrier concentration.

As described above, indium oxide is an oxide whose valence electron can be controlled; therefore, the threshold voltage of a transistor including a semiconductor layer containing indium oxide can be controlled. In addition, the region with a low carrier concentration and the region with a high carrier concentration of indium oxide can be used as a channel formation region and source and drain regions, respectively, of a transistor. Thus, the indium oxide enables formation of what is called an n-i-n junction (junction between an n-type region, an i-type region, and an n-type region). Incidentally, the valence electron control by a transistor with silicon is generally known, whereas the valence electron control in a transistor containing indium oxide is a novel technical idea that cannot be conceived usually. With the use of this technical idea, a transistor that has high mobility, has a low off-state current, can be normally off, and has high reliability can be achieved.

An indium oxide film preferably has crystallinity. In particular, the indium oxide film is preferably a polycrystal film, further preferably a single crystal film. A single crystal film does not have a crystal grain boundary (also referred to as a grain boundary). The use of a single crystal film can inhibit carrier scattering or the like at the crystal grain boundary, thereby achieving a transistor having high field-effect mobility. In addition, the use of a single crystal film produces an excellent effect of reducing a variation in transistor characteristics caused by the crystal grain boundary.

A polycrystal film is preferable because it can reduce carrier scattering as compared with a microcrystal film or an amorphous film and enables a transistor to have high field-effect mobility. In the case of using a polycrystal film, it is preferable to use a film that has as large a crystal grain size as possible and few crystal grain boundaries. In the case where the crystal grain boundary is neither included nor observed in a channel formation region of a transistor including a polycrystal film, the channel formation region is positioned in a single crystal region included in the polycrystal film and thus the transistor can be regarded as a transistor including a single crystal film.

The crystallinity of indium oxide can be analyzed with an X-ray diffraction (XRD) pattern, a transmission electron microscope (TEM) image, or an electron diffraction (ED) pattern, for example. Alternatively, two or more of these methods may be combined for the analysis.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be regarded as a single crystal film.

A channel formation region refers to a region of a semiconductor layer that overlaps with (or faces) a gate electrode with a gate insulating layer therebetween and is positioned between a region in contact with a source electrode and a region in contact with a drain electrode. A crystal grain, a crystal grain boundary, a crystal axis, a crystal orientation, or the like in a channel formation region can be confirmed in observation of a cross section including a semiconductor layer, a source electrode, and a drain electrode.

Impurities in the indium oxide film can function as a carrier scattering source and thus can cause a reduction in field-effect mobility and inhibit crystal growth. Examples of the impurities for the indium oxide film include boron and silicon. The concentrations of the impurities in the indium oxide film in the channel formation region are preferably as low as possible. For example, the concentrations of the impurity elements are each lower than or equal to 0.1%, preferably lower than or equal to 0.01% (100 ppm). Note that carbon, hydrogen, and the like are elements that would be contained in a film formation gas or a precursor in film formation, and the amounts of these elements remaining in the indium oxide film might be larger than those of the impurities.

The indium oxide film can contain an element that can form a trivalent cation like indium as long as the cubic crystal structure (bixbyite structure) is retained. Examples of the element include Group 13 elements such as gallium and aluminum and Group 3 elements in the periodic table. These elements have a higher bonding strength with oxygen than indium, and therefore, addition of any of these elements to an indium oxide film can inhibit formation of oxygen vacancies (V_{O}) in the indium oxide film. Since these elements exist mainly as trivalent cations in oxides, the carrier concentration in the indium oxide film can be kept low. This enables the threshold voltage of a transistor to shift in the positive direction and the transistor to exhibit normally-off characteristics. Consequently, the transistor can have favorable electrical characteristics.

The concentration of the above element in the indium oxide film is preferably higher than or equal to 1×10¹⁶ atoms/cm³ and lower than or equal to 8×10²⁰ atoms/cm³, more preferably higher than or equal to 1×10¹⁶ atoms/cm³ and lower than or equal to 4×10²⁰ atoms/cm³, further preferably higher than or equal to 1×10¹⁶ atoms/cm³ and lower than or equal to 8×10¹⁹ atoms/cm³, still more preferably higher than or equal to 1×10¹⁶ atoms/cm³ and lower than or equal to 5×10¹⁹ atoms/cm³.

The element that imparts n-type conductivity, the element that imparts p-type conductivity, and the element that can form a trivalent cation described above can each be added to an indium oxide film by an ion doping method, an ion implantation method, a thermal diffusion method, or the like. Alternatively, the element that imparts n-type conductivity, the element that imparts p-type conductivity, and the element that can form a trivalent cation described above can each be added to a sputtering target, a deposition gas, a precursor for ALD deposition, or the like at the time of depositing an indium oxide film. Alternatively, it is possible to perform autodoping with the element that imparts n-type conductivity, the element that imparts p-type conductivity, and the element that can form a trivalent cation described above from a chamber in depositing the indium oxide film. Note that autodoping refers to addition of an element contained in a member of a chamber for deposition, for example, into the film at the time of depositing the indium oxide film.

A transistor including the above indium oxide film can have a field-effect mobility higher than or equal to 50 cm²/(V·s), preferably higher than or equal to 100 cm²/(V·s), further preferably higher than or equal to 150 cm²/(V·s), still further preferably higher than or equal to 200 cm²/(V·s), yet still further preferably higher than or equal to 250 cm²/(V·s).

One feature of an indium oxide film is to have a higher property of transmitting (diffusing) oxygen than an IGZO film. For example, oxygen diffusing in an indium oxide film is transmitted through the indium oxide film and released as an oxygen molecule. When reacting with hydrogen contained in the film, oxygen is released as a water molecule in some cases. In the case where the film includes oxygen vacancies, the oxygen vacancies are filled with diffusing oxygen atoms. Since oxygen easily diffuses in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

Hydrogen diffuses in the indium oxide film. Hydrogen diffusing into the indium oxide film from the outside is transmitted through the indium oxide film and is released as a hydrogen molecule. When reacting with oxygen contained in the film, hydrogen is released as a water molecule.

Indium oxide has features of a small effective mass of electrons and a large effective mass of holes. In addition, the effective mass of electrons in indium oxide hardly depends on the crystal orientation. Thus, a transistor containing indium oxide having crystallinity can have high field-effect mobility and high frequency characteristics (also referred to as f characteristics). A large effective mass of holes allows a transistor to have an extremely low off-state current. For example, the off-state current per micrometer of channel width of a vertical transistor including an indium oxide film can be lower than or equal to 1 fA (1×10⁻¹⁵ A) or lower than or equal to 1 aA (1×10⁻¹⁸ A) at 125 °C, and can be lower than or equal to 1 aA (1×10⁻¹⁸ A) or lower than or equal to 1 zA (1×10⁻²¹ A) at room temperature (25 °C). Since indium oxide has a smaller effective mass of electrons and a larger effective mass of holes than silicon, a transistor containing indium oxide can have higher field-effect mobility and lower off-state current than a Si transistor.

A seed layer is preferably provided in contact with at least part of the indium oxide film having crystallinity. A material of the seed layer is preferably selected such that the difference in a lattice constant (also referred to as lattice mismatch) between the crystal included in indium oxide and the crystal included in the material is small. In that case, the crystallinity of the indium oxide film can be improved. As a layer in contact with at least part of the indium oxide film having crystallinity, a substrate (e.g., a single crystal substrate) may be used.

One of methods for evaluating the degree of a lattice mismatch is a method using a value of a lattice mismatch degree described below. A lattice mismatch degree Δa [%] of a crystal included in a film to be formed (here, the indium oxide film) with respect to the crystal included in the seed layer is calculated by the formula: Δa=((L₁−L₂)/L₂)×100. Here, L₁ is the lattice constant or the length of the unit lattice vector of the crystal included in the film to be formed, and L₂ is the lattice constant or the length of the unit lattice vector of the crystal included in the seed layer.

The absolute value of the lattice mismatch degree Δa between the seed layer and the indium oxide film is preferably as small as possible, most preferably 0. For example, Δa can be greater than or equal to −5% and less than or equal to 5%, preferably greater than or equal to −4% and less than or equal to 4%, further preferably greater than or equal to −3% and less than or equal to 3%, still further preferably greater than or equal to −2% and less than or equal to 2%.

An indium oxide crystal has a cubic crystal structure (a bixbyite structure). For example, an yttria-stabilized zirconia (YSZ) crystal can have a cubic crystal structure (a fluorite crystal structure). The lattice mismatch degree of an indium oxide crystal with respect to an YSZ crystal having the cubic crystal structure is within the range of −2% to 2%, which enables epitaxial growth of a single crystal film of indium oxide over the YSZ substrate.

The crystal structures of the seed layer and the indium oxide film do not necessarily have the same crystal system or crystal orientation in some cases. For example, a film including a crystal with a hexagonal crystal structure or a trigonal crystal structure can be provided below an indium oxide film including a crystal with a cubic crystal structure. For example, when the crystal orientation of a seed layer surface is set to [001] and the crystal orientation of a bottom surface of the indium oxide film is set to [111], the necessary condition for crystal orientation in epitaxial growth can be satisfied. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO.

At least part of this embodiment can be implemented as appropriate in combination with any of the other embodiments described in this specification.

### Example

In this example, the shape and the like of a partition formed over an insulating layer were evaluated.

Sample S1, Sample S2, and Sample S3 fabricated by the following methods were used in this example. The fabrication conditions for Sample S3 were slightly modified on the basis of the findings obtained from the fabrication of Samples S1 and S2.

### Fabrication Method

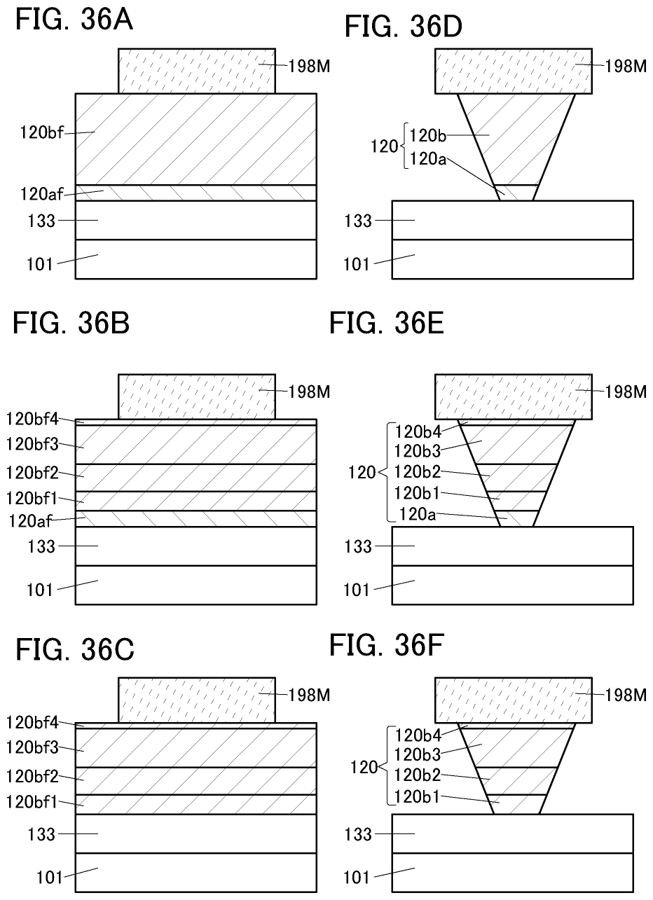

The methods for fabricating the samples and the structures of the fabricated samples will be described with reference to FIGS. 36A to 36F.

First, for Samples S1 and S2, an approximately 400-nm-thick silicon oxynitride film was formed over the substrate 101 made of glass as the insulating layer 133. The silicon oxynitride film was formed by a PECVD method. The silicon oxynitride film was formed under the following conditions: the substrate temperature was 200 °C, a silane (SiH₄) gas at a flow rate of 200 sccm and a dinitrogen monoxide (N₂O) gas at a flow rate of 1000 sccm were used, and the pressure was 100 Pa. For Sample S3, an insulating layer and the pixel electrode 111 were formed over the substrate 101 made of glass and then the insulating layer 133 was formed. As the pixel electrode, 10-nm-thick ITSO, 100-nm-thick APC, and 40-nm-thick ITSO were stacked. As the insulating layer 133, an approximately 200-nm-thick silicon oxynitride film was formed. The conditions for forming Sample S3 were the same as those for forming Samples S1 and Sample S2 except for the thickness of the silicon oxynitride film.

Next, for Samples S1 and S2, an approximately 40-nm-thick aluminum oxide film was formed over the insulating layer 133 as the film 120af. The aluminum oxide film was formed by a sputtering method using an aluminum target. The aluminum oxide film was formed under the following conditions: the substrate temperature was room temperature, the flow rate ratio was optimized so that an oxygen gas accounted for approximately 70% and an argon gas accounted for approximately 30%, and the pressure was 0.6 Pa.

After that, for Sample S1, an approximately 300-nm-thick molybdenum film was formed as the film 120bf. The molybdenum film was formed by a sputtering method using a molybdenum target. The molybdenum film was formed under the following conditions: the substrate temperature was 70 °C, an argon (Ar) gas at a flow rate of 300 sccm was used, the pressure was 0.85 Pa, and the power was 10 kW.

For Sample S2, the film 120bf was formed in the following manner. First, three In—Sn—Zn oxide films were formed under different conditions to have a stacked-layer structure. The thicknesses of the In—Sn—Zn oxide films, from bottom to top, were approximately 50 nm, approximately 100 nm, and approximately 150 nm (here, the three In—Sn—Zn oxide films are referred to as a film 120bf1, a film 120bf2, and a film 120bf3 from the bottom). Then, an approximately 10-nm-thick ITSO film was formed over the In—Sn—Zn oxide films (here, the ITSO film is referred to as a film 120bf4).

For Sample S3, the film 120af was not formed over the insulating layer 133. As the film 120bf, three In—Sn—Zn oxide films were formed under different conditions to have a stacked-layer structure, and an ITSO film was formed thereover. The thicknesses of the In—Sn—Zn oxide films and the ITSO film were the same as those in Sample S2.

In the films 120bf of Samples S2 and S3, each of the three In—Sn—Zn oxide films was formed by a sputtering method using a target with In:Sn:Zn=70.5:1.8:10.0 [weight %]. The deposition conditions of the three In—Sn—Zn oxide films were optimized so that the density of the upper layer became higher than the lower layer. In other words, the pressure in the film formation chamber was lower in forming the upper layer than in forming the lower layer, and the deposition power (corresponding to an output value of a power source of the film formation apparatus) was higher in forming the upper layer than in forming the lower layer. When the density of the upper layer is made higher than the lower layer as described above, the wet etching rate of the upper layer can be lower than that of the lower layer; thus, the partition 120 can suitably have an inverse tapered shape. Specific deposition conditions of the film 120bf1 were as follows: the substrate temperature was room temperature, the gas flow rate ratio was optimized so that an oxygen gas accounted for approximately 3% and an argon gas accounted for approximately 97%, the pressure was 0.6 Pa, and the deposition power was 2.5 kW. Specific deposition conditions of the film 120bf2 were as follows: the substrate temperature was room temperature, the gas flow rate ratio was optimized so that an oxygen gas accounted for approximately 3% and an argon gas accounted for approximately 97%, the pressure was 0.8 Pa, and the deposition power was 1.5 kW. Specific deposition conditions of the film 120bf3 were as follows: the substrate temperature was room temperature, the gas flow rate ratio was optimized so that an oxygen gas accounted for approximately 3% and an argon gas accounted for approximately 97%, the pressure was 0.3 Pa, and the deposition power was 4.5 kW.

In each of the films 120bf of Samples S2 and S3, the ITSO film was formed by a sputtering method using a target with In:Sn:Zn=70.3:7.9:2.3 [weight %]. Specific deposition conditions of the ITSO film were as follows: the substrate temperature was room temperature, the gas flow rate ratio was optimized so that an oxygen gas accounted for approximately 2.5% and an argon gas accounted for approximately 97.5%, the pressure was 0.6 Pa, and the deposition power was 6.0 kW.

Next, for Sample S1, a resist mask was formed as the mask 198M over the film 120bf (see FIG. 36A). After that, part of the film 120bf and part of the film 120af were removed by wet etching, so that the layer 120b and the layer 120a were formed (see FIG. 36D). For Sample S2, a resist mask was formed as the mask 198M over the film 120bf4 (see FIG. 36B). After that, parts of the films 120bf1 to 120bf4 and part of the film 120af were removed by wet etching, so that the layers 120b1 to 120b4 and the layer 120a were formed (see FIG. 36E). For Sample S3, a resist mask was formed as the mask 198M over the film 120bf4 (see FIG. 36C). After that, parts of the films 120bf1 to 120bf4 were removed by wet etching, so that the layers 120b1 to 120b4 were formed (see FIG. 36F).

For Sample S1, the film 120bf (molybdenum film) was etched using, as an etchant, a mixed solution containing phosphoric acid in the range of approximately 70% to 80%, nitric acid in the range of approximately 1% to 9%, acetic acid in the range of approximately 1% to 10%, and water in the range of approximately 1% or more, at a temperature of 30 °C. The etching rate of the film 120bf (molybdenum film) using the mixed solution was approximately 450 nm/min. The etching time for the film 120bf was adjusted to include approximately 25% over-etch time.

For Sample S2, the films 120bf1 to 120bf4 were etched using, as an etchant, an aqueous solution containing oxalic acid in the range of approximately 1% to 10% at a temperature of 40 °C The etching rates of the film 120bf4 (ITSO film), the film 120bf3, the film 120bf2, and the film 120bf1 using the oxalic acid aqueous solution were approximately 80 nm/min, approximately 137 nm/min, approximately 155 nm/min, and approximately 355 nm/min, respectively. The total etching time for all the films 120bf1 to 120bf4 was adjusted to include approximately 50% over-etch time.

Although the oxalic acid aqueous solution was used for Sample S2 as the etchant of the films 120bf1 to 120bf4, for Sample S3, the films 120bf1 and 120bf2 and part of the film 120bf3 were etched using an oxalic acid aqueous solution and then, the remaining part of the film 120bf3 and the film 120bf4 were etched using a mixed aqueous solution containing phosphoric acid, acetic acid, and nitric acid. With the oxalic acid aqueous solution, the etching rates of the films 120bf1 to 120bf3 were particularly high, making it difficult to maintain in-plane shape uniformity; thus, the mixed aqueous solution offering a lower etching rate was used. For the mixed aqueous solution, phosphoric acid, acetic acid, nitric acid, and water can be mixed at a volume ratio of 53.3:67:3.3:36.7 or in the neighborhood thereof.

For each of Sample S1 and Sample S2, the film 120af (aluminum oxide film) was etched using, as an etchant, an aqueous solution containing approximately 2.38% of tetramethyl ammonium hydroxide (abbreviation: TMAH) at a temperature of approximately 23.5 °C. The etching rate of the film 120af (aluminum oxide film) using the TMAH aqueous solution was approximately 6 nm/min. The etching time for the film 120af was adjusted to include approximately 50% over-etch time.

By using the above methods, Sample S1 having a structure illustrated in FIG. 36D, Sample S2 having a structure illustrated in FIG. 36E, and Sample S3 having a structure illustrated in FIG. 36F were fabricated.

### Cross-Sectional Observation

The fabricated samples were thinned by a focused ion beam (FIB) and the cross sections were observed by scanning transmission electron microscopy (STEM). The STEM observation was performed at an acceleration voltage of 200 kV using a scanning transmission electron microscope HD-2300 manufactured by Hitachi High-Technologies Corporation.

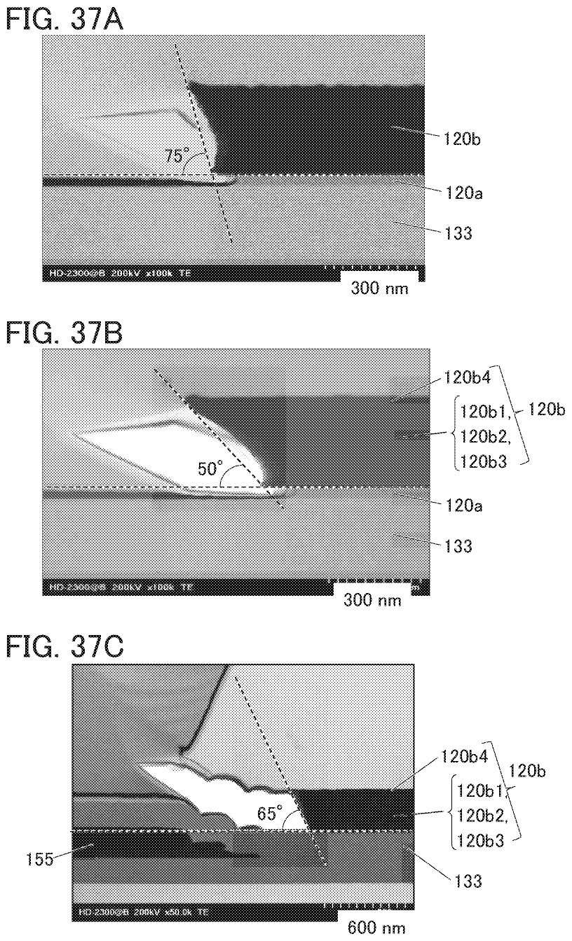

FIGS. 37A and 37B are cross-sectional transmission electron images (TE images) of Samples S1 and S2 at a magnification of 100000 times. FIG. 37C is a cross-sectional TE image of Sample S3 at a magnification of 50000 times.

In Sample S1, a region having an inverse tapered shape was observed on the side surface of the layer 120b. The supplement θb′ of the taper angle of the layer 120b was measured to be 75°. Since the side surface of the partition 120 was curved in Sample S1, a straight line connecting the upper end and the lower end of the side surface of the layer 120b was drawn in a cross-sectional view, and the angle between the straight line and the extended line of the bottom surface of the layer 120b was referred to as the supplement θb′ of the taper angle. The supplement θb′ of the taper angle in Sample S1 was able to fall within a suitable range because molybdenum was used for the layer 120b. This is probably because the upper portion of the molybdenum film might have higher crystallinity than the lower portion in the vicinity of the layer 120a, or the adhesion between the molybdenum film and the resist mask might be higher than that between the molybdenum film and the layer 120a, for example. The layer 120a was able to be positioned inward from the end portion of the bottom surface of the layer 120b. Such a structure can inhibit the first EL layers 112 from overlapping onto the top surface of the layer 120a and thus can inhibit the first EL layers 112 from being in contact with the layer 120b having conductivity. In other words, the first EL layers 112 can be in contact with only the layer 120a having an insulating property in the partition 120; thus, generation of leakage current can be inhibited. Although a region where the taper angle θa is smaller than 90° (i.e., the angle θa′ is 90° or larger) was observed in the layer 120a, there is little concern that the EL layer is difficult to disconnect because the region is thin. Hence, the partition 120 in Sample S1 is regarded as having a preferable shape.

Also in Sample S2, a region having an inverse tapered shape was observed on the side surface of the layer 120b. The supplement θb′ of the taper angle of the layer 120b was measured to be 50°. Since the side surface of the partition 120 was curved also in Sample S2, a straight line connecting the upper end and the lower end of the side surface of the layer 120b was drawn in a cross-sectional view, and the angle between the straight line and the extended line of the bottom surface of the layer 120b was referred to as the supplement θb′ of the taper angle. The supplement θb′ of the taper angle in Sample S2 was able to fall within a suitable range because the In—Sn—Zn oxide films and the ITSO film were used for the layer 120b. This is probably because the ITSO film having a lower wet etching rate than the In—Sn—Zn oxide films was provided over the In—Sn—Zn oxide films, and because three In—Sn—Zn oxide films were formed under different conditions to have a stacked-layer structure and the wet etching rate of the upper layer became lower than that of the lower layer by making the density of the upper layer higher than the lower layer, for example. The layer 120a was able to be positioned inward from the end portion of the bottom surface of the layer 120b also in Sample S2. Such a structure can inhibit generation of leakage current between EL layers. Although a region where the taper angle θa is smaller than 90° (i.e., the angle θa′ is 90° or larger) was observed in the layer 120a also in Sample S2, there is little concern that the EL layer is difficult to disconnect because the region is thin. Hence, the partition 120 in Sample S2 is regarded as having a preferable shape.

Also in Sample S3, a region having an inverse tapered shape was observed on the side surface of the layer 120b. The supplement θb′ of the taper angle of the layer 120b was measured to be 65°. Since the side surface of the layer 120b (especially the layer 120b3) was slightly curved in Sample S3, a straight line connecting the upper end and the lower end of the side surface of the layer 120b was drawn in a cross-sectional view, and the angle between the straight line and the extended line of the bottom surface of the layer 120b was referred to as the supplement θb′ of the taper angle. The supplement θb′ of the taper angle in Sample S3 was able to fall within a suitable range because the In—Sn—Zn oxide films and the ITSO film were used for the layer 120b. The taper angle was different from that in Sample S2 probably because the formation surface of the layer 120b in Sample S3 was different from that in Sample S2 and the etchant used was different from that for Sample S2. The partition 120 in Sample S3 has a relatively good linearity in the cross-sectional shape of the side surface and is regarded as having a preferable shape.

At least part of this example can be implemented as appropriate in combination with any of the other embodiments described in this specification.

This application is based on Japanese Patent Application Serial No. 2025-078913 filed with Japan Patent Office on May 9, 2025 and Japanese Patent Application Serial No. 2026-020545 filed with Japan Patent Office on Feb. 11, 2026, the entire contents of which are hereby incorporated by reference.

What is claimed is:

1. A display device comprising:
a pixel electrode;
an organic compound layer over the pixel electrode;
an upper electrode over the organic compound layer;
a first insulating layer covering an end portion of the pixel electrode; and
a partition over the first insulating layer,
wherein the organic compound layer comprises a light-emitting compound,
wherein the partition has an inverse tapered shape in a cross-sectional view,
wherein the partition comprises a second insulating layer in contact with the first insulating layer and a first conductive layer over the second insulating layer, and
wherein the upper electrode is in contact with a side surface of the first conductive layer and a top surface of the organic compound layer.

2. The display device according to claim 1, comprising a first film over the partition,
wherein the first film comprises the light-emitting compound.

3. The display device according to claim 1,
wherein the first insulating layer comprises an inorganic insulating film, and
wherein the second insulating layer comprises aluminum and oxygen.

4. The display device according to claim 1, wherein the first conductive layer comprises molybdenum.

5. The display device according to claim 1, wherein an angle between a bottom surface of the first conductive layer and the side surface of the first conductive layer is greater than or equal to 100° and less than or equal to 135°.

6. The display device according to claim 1, wherein the organic compound layer is in contact with the second insulating layer and is not in contact with the first conductive layer.

7. The display device according to claim 1, wherein the organic compound layer is not in contact with the partition.

8. The display device according to claim 1, wherein the upper electrode is in contact with a top surface of the partition.

9. The display device according to claim 1, wherein the upper electrode is not in contact with a top surface of the partition.

10. The display device according to claim 1, wherein the partition surrounds the pixel electrode.

11. A display device comprising:
a first light-emitting element comprising:
a first pixel electrode;
a first organic compound layer over the first pixel electrode; and
an upper electrode over the first organic compound layer;
a second light-emitting element comprising:
a second pixel electrode;
a second organic compound layer over the second pixel electrode; and
the upper electrode over the second organic compound layer;
a first insulating layer covering an end portion of the first pixel electrode and an end portion of the second pixel electrode; and
a partition between the first light-emitting element and the second light-emitting element,
wherein the first organic compound layer comprises a first light-emitting compound,
wherein the second organic compound layer comprises a second light-emitting compound,
wherein the partition has an inverse tapered shape in a cross-sectional view,
wherein the partition comprises a second insulating layer in contact with the first insulating layer and a first conductive layer over the second insulating layer, and
wherein the upper electrode is in contact with a side surface of the first conductive layer and a top surface of the first organic compound layer.

12. The display device according to claim 11, comprising a first film over the partition,
wherein the first film comprises the first light-emitting compound.

13. The display device according to claim 11,
wherein the first insulating layer comprises an inorganic insulating film, and
wherein the second insulating layer comprises aluminum and oxygen.

14. The display device according to claim 11, wherein the first conductive layer comprises molybdenum.

15. The display device according to claim 11, wherein an angle between a bottom surface of the first conductive layer and the side surface of the first conductive layer is greater than or equal to 100° and less than or equal to 135°.

16. The display device according to claim 11, wherein the first organic compound layer is in contact with the second insulating layer and is not in contact with the first conductive layer.

17. The display device according to claim 11, wherein the first organic compound layer is not in contact with the partition.

18. The display device according to claim 11, wherein the upper electrode is in contact with a top surface of the partition.

19. The display device according to claim 11, wherein the upper electrode is not in contact with a top surface of the partition.

20. The display device according to claim 11, wherein the partition surrounds the first pixel electrode.
